(19) United States
(12) Patent Application Publication
(10) Pub. No.: US 2025/0015195 A1
(43) Pub. Date: Jan. 9, 2025

(54) OXIDE SEMICONDUCTOR LAYER, SEMICONDUCTOR DEVICE, AND METHOD FOR MANUFACTURING THE SEMICONDUCTOR DEVICE

(71) Applicant: SEMICONDUCTOR ENERGY LABORATORY CO., LTD., Atsugi-shi (JP)

(72) Inventors: Shunpei YAMAZAKI, Tokyo (JP); Fumito ISAKA, Zama (JP); Yuichi SATO, Isehara (JP); Toshikazu OHNO, Atsugi (JP); Hitoshi KUNITAKE, Tokyo (JP); Tsutomu MURAKAWA, Isehara (JP)

(21) Appl. No.: 18/763,192

(22) Filed: Jul. 3, 2024

(30) Foreign Application Priority Data
Jul. 6, 2023 (JP) 2023-111667

(51) Int. Cl. H01L 29/786; H01L 29/66

(52) U.S. Cl. CPC H01L 29/7869; H01L 29/6675

(57) ABSTRACT

A semiconductor device including an oxide semiconductor layer which is formed over a substrate and includes indium is provided. The oxide semiconductor layer is formed in parallel or substantially in parallel with a surface of the substrate. The oxide semiconductor layer includes a first region, a second region over the first region, and a third region over the second region. The first region is located in a range from a formation surface of the oxide semiconductor layer to greater than or equal to 0 nm to less than or equal to 3 nm in a direction substantially perpendicular to the formation surface. In cross-sectional observation of the oxide semiconductor layer using a transmission electron microscope, bright spots arranged in a layered manner in a direction parallel to the formation surface are observed in each of the first region, the second region, and the third region.

### BACKGROUND OF THE INVENTION

### 1. Field of the Invention

One embodiment of the present invention relates to a semiconductor device, a memory device, and an electronic device each including an oxide semiconductor. One embodiment of the present invention relates to a method of manufacturing the semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), driving methods thereof, and manufacturing methods thereof.

In this specification and the like, a semiconductor device generally means a device that can function by utilizing semiconductor characteristics. A semiconductor element such as a transistor, a semiconductor circuit, an arithmetic device, and a memory device are each one mode of a semiconductor device. A display device (e.g., a liquid crystal display device and a light-emitting display device), a projection device, a lighting device, an electro-optical device, a power storage device, a memory device, a semiconductor circuit, an imaging device, an electronic device, and the like may include a semiconductor device.

### 2. Description of the Related Art

In recent years, semiconductor devices have been developed, and large scale integrations (LSIs), central processing unit (CPUs), memories, and the like are used in semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an IC and an image display device (also simply referred to as a display device). A silicon-based semiconductor material is widely known as a material of a semiconductor thin film that can be used in a transistor. As another material, an oxide semiconductor has been attracting attention.

It is known that a transistor including an oxide semiconductor has an extremely low leakage current in an off state. For example, Patent Document 1 discloses a low-power CPU utilizing a characteristic of a low leakage current of the transistor including an oxide semiconductor. Furthermore, for example, Patent Document 2 discloses a memory device that can retain stored data for a long time by utilizing a characteristic of a low leakage current of the transistor including an oxide semiconductor.

Patent Document 3 discloses a transistor with a minute structure in which a source electrode layer and a drain electrode layer are provided in contact with a top surface of an oxide semiconductor].

Non-patent Document 1 discloses a CAAC-IGZO as a crystalline oxide semiconductor. Non-patent Document 1 also discloses a growth mechanism and the like of CAAC-IGZO.

### REFERENCE

### Patent Document

[Patent Document 1] Japanese Published Patent Application No. 2012-257187
[Patent Document 2] Japanese Published Patent Application No. 2011-151383
[Patent Document 3] PCT International Publication No. WO2016/125052

### Non-Patent Document

[Non-Patent Document 1] Noboru Kimizuka and Shunpei Yamazaki, “PHYSICS AND TECHNOLOGY OF CRYSTALLINE OXIDE SEMICONDUCTOR CAAC-IGZO” FUNDAMENTALS (the United States), Wiley-SID Series in Display Technology, 2017, pp. 50-150.

### SUMMARY OF THE INVENTION

An object of one embodiment of the present invention is to provide an oxide semiconductor layer that can be used as a semiconductor device such as a transistor. Another object of one embodiment of the present invention is to provide an oxide semiconductor layer that can be used for a semiconductor device with favorable electrical characteristics. Another object of one embodiment of the present invention is to provide an oxide semiconductor layer that can be used for a highly reliable semiconductor device. Another object of one embodiment of the present invention is to provide a novel oxide semiconductor layer. Another object of one embodiment of the present invention is to provide a method of manufacturing of a novel oxide semiconductor layer.

An object of one embodiment of the present invention is to provide a semiconductor device having excellent electrical characteristics. Another object of one embodiment of the present invention is to provide a highly reliable semiconductor device. Another object of one embodiment of the present invention is to provide a semiconductor device that can be miniaturized or highly integrated. Another object of one embodiment of the present invention is to provide a semiconductor device that operates at high speed. Another object of one embodiment of the present invention is to provide a semiconductor device with low power consumption. Another object of one embodiment of the present invention is to provide a semiconductor device with a small variation in electrical characteristics of transistors. Another object of one embodiment of the present invention is to provide a novel semiconductor device. Another object of one embodiment of the present invention is to provide a method of manufacturing a semiconductor device with high productivity. Another object of one embodiment of the present invention is to provide a method of manufacturing of a novel semiconductor device.

Note that the description of these objects does not preclude the presence of other objects. One embodiment of the present invention does not necessarily achieve all of these objects. Other objects can be derived from the description of the specification, the drawings, and the claims.

An embodiment of the present invention is an oxide semiconductor layer that is formed over a substrate and includes indium. The oxide semiconductor layer is formed in parallel or substantially in parallel with a surface of the substrate. The oxide semiconductor layer includes a first region, a second region over the first region, and a third region over the second region. The first region is located in a range from a formation surface of the oxide semiconductor layer to greater than or equal to 0 nm to less than or equal to 3 nm in a direction substantially perpendicular to the formation surface. In cross-sectional observation of the oxide semiconductor layer using a transmission electron microscope, bright spots arranged in a layered manner in a direction parallel to the formation surface are observed in each of the first region, the second region, and the third region.

In a preferred mode of the oxide semiconductor layer, the second region includes zinc, the second region includes a crystal, and the c-axis of the crystal is substantially parallel to a normal direction of the formation surface of the oxide semiconductor layer.

In a preferred mode of the oxide semiconductor layer, the c-axis alignment proportion of the second region is higher than that of the first region.

In a preferred mode of the oxide semiconductor layer, the c-axis alignment proportion of the third region is higher than that of the first region.

In a preferred mode of the oxide semiconductor layer, the content of indium in the first region is higher than that in the second region, and the content of indium in the third region is higher than that in the second region.

In a preferred mode of the oxide semiconductor layer, the oxide semiconductor layer is formed over an insulator, and the insulator is amorphous.

Another embodiment of the present invention is a semiconductor device including: a first insulator over a substrate; an oxide semiconductor layer over the first insulator; a second insulator over the oxide semiconductor; and a conductor over the second insulator. The first insulator and the oxide semiconductor layer are formed in parallel or substantially in parallel with a surface of the substrate, the oxide semiconductor layer includes indium, the oxide semiconductor layer includes a first region, a second region over the first region, and a third region over the second region. The first region is located in a range from a formation surface of the oxide semiconductor layer to greater than or equal to 0 nm to less than or equal to 3 nm in a direction substantially perpendicular to the formation surface. In cross-sectional observation of the oxide semiconductor layer using a transmission electron microscope, bright spots arranged in a layered manner in a direction parallel to the formation surface are observed in each of the first region, the second region, and the third region.

In a preferred mode of the semiconductor device, the second region includes zinc, the second region includes a crystal, and the c-axis of the crystal is substantially parallel to a normal direction of the formation surface of the oxide semiconductor layer.

In a preferred mode of the semiconductor device, the c-axis alignment proportion of the second region is higher than that of the first region.

In a preferred mode of the semiconductor device, the c-axis alignment proportion of the third region is higher than that of the first region.

In a preferred mode of the semiconductor device, the content of indium in the first region is higher than that in the second region, and the content of indium in the third region is higher than that in the second region.

In a preferred mode of the semiconductor device, the first insulator is amorphous.

The semiconductor device preferably further includes a third insulator covering the first insulator and the oxide semiconductor layer. An opening reaching the oxide semiconductor layer is preferably formed in the third insulator, and the second insulator and the conductor are preferably provided in the opening.

In a preferred mode of the semiconductor device, the second insulator is in contact with the third region.

Another embodiment of the present invention is a method for manufacturing a semiconductor device including an oxide semiconductor layer including a first metal oxide, a second metal oxide, a third metal oxide; a first insulator; a second insulator; a third insulator; and a conductor. The method includes forming the first insulator over a substrate; forming the oxide semiconductor layer over the first insulator; performing heat treatment on the oxide semiconductor layer; processing the first insulator and the oxide semiconductor layer into island shapes; forming the third insulator to cover the first insulator and the oxide semiconductor layer; forming an opening reaching the oxide semiconductor layer in the third insulator; forming the second insulator in the opening; and forming the conductor over the second insulator in the opening. The step of forming the oxide semiconductor layer includes forming the first metal oxide; forming the second metal oxide over the first metal oxide; and forming the third metal oxide over the second metal oxide. Each of the first metal oxide and the third metal oxide is formed by an ALD method using a precursor including indium and an oxidizer, and the second metal oxide is formed by a sputtering method using a sputtering target including indium.

In a preferred mode of the method for manufacturing a semiconductor device, the sputtering target includes zinc, and the sputtering method is performed in an atmosphere containing oxygen.

In a preferred mode of the method for manufacturing a semiconductor device, the temperature of substrate heating in the ALD method is higher than or equal to 100° C. and lower than or equal to 350° C.

In a preferred mode of the method for manufacturing a semiconductor device, in cross-sectional observation of the oxide semiconductor layer using a transmission electron microscope, bright spots arranged in a layered manner in a direction parallel to the formation surface are observed in each of the first metal oxide, the second metal oxide, and the third metal oxide.

In a preferred mode of the method for manufacturing a semiconductor device, a clear boundary is not observed between the first metal oxide and the second metal oxide, and a clear boundary is not observed between the second metal oxide and the third metal oxide.

In a preferred mode of the method for manufacturing a semiconductor device, the temperature of the heat treatment is higher than or equal to 350° C. and lower than or equal to 550° C.

An embodiment of the present invention can provide an oxide semiconductor layer that can be used as a semiconductor device such as a transistor. An embodiment of the present invention can provide an oxide semiconductor layer that can be used for a semiconductor device with favorable electrical characteristics. An embodiment of the present invention can provide an oxide semiconductor layer that can be used for a highly reliable semiconductor device. An embodiment of the present invention can provide a novel oxide semiconductor layer. An embodiment of the present invention can provide a method of manufacturing of a novel oxide semiconductor layer.

An embodiment of the present invention can provide a semiconductor device having excellent electrical characteristics. An embodiment of the present invention can provide a highly reliable semiconductor device. An embodiment of the present invention can provide a semiconductor device that can be miniaturized or highly integrated. An embodiment of the present invention can provide a semiconductor device that operates at high speed. An embodiment of the present invention can provide a semiconductor device with low power consumption. An embodiment of the present invention can provide a semiconductor device with a small variation in electrical characteristics of transistors. An embodiment of the present invention can provide a novel semiconductor device. An embodiment of the present invention can provide a method of manufacturing a semiconductor device with high productivity. An embodiment of the present invention can provide a method of manufacturing of a novel semiconductor device.

Note that the description of these effects does not preclude the presence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIGS. 1A to 1D are cross-sectional views illustrating a method for forming a metal oxide according to an embodiment of the present invention;

FIGS. 2A to 2D are cross-sectional views illustrating a method for forming a metal oxide according to an embodiment of the present invention;

FIGS. 3A to 3E are cross-sectional views illustrating a method for forming a metal oxide according to an embodiment of the present invention;

FIGS. 4A to 4D are cross-sectional views of a metal oxide according to an embodiment of the present invention;

FIGS. 5A to 5D are cross-sectional views illustrating a method for forming a metal oxide according to an embodiment of the present invention;

FIGS. 6A to 6C are cross-sectional views illustrating a method for forming a metal oxide according to an embodiment of the present invention;

FIG. 7A is a plan view illustrating an example of a semiconductor device, and FIGS. 7B to 7D are cross-sectional views illustrating the example of the semiconductor device;

FIGS. 8A and 8B are cross-sectional views illustrating an example of a semiconductor device;

FIG. 9A is a plan view illustrating an example of a semiconductor device, and FIGS. 9B to 9D are cross-sectional views illustrating the example of the semiconductor device;

FIG. 10A is a plan view illustrating an example of a semiconductor device, and FIGS. 10B to 10D are cross-sectional views illustrating the example of the semiconductor device;

FIGS. 11A and 11B are cross-sectional views each illustrating an example of a semiconductor device;

FIG. 12A and FIGS. 12B to 12D are, respectively, a plan view and cross-sectional views that illustrate an example of a method for manufacturing a semiconductor device;

FIG. 13A and FIGS. 13B to 13D are, respectively, a plan view and cross-sectional views that illustrate an example of a method for manufacturing a semiconductor device;

FIG. 14A and FIGS. 14B to 14D are, respectively, a plan view and cross-sectional views that illustrate an example of a method for manufacturing a semiconductor device;

FIG. 15A and FIGS. 15B to 15D are, respectively, a plan view and cross-sectional views that illustrate an example of a method for manufacturing a semiconductor device;

FIGS. 16A1 to 16D2 are cross-sectional views illustrating examples of methods for manufacturing a semiconductor device;

FIG. 17A and FIGS. 17B to 17D are, respectively, a plan view and cross-sectional views that illustrate an example of a method for manufacturing a semiconductor device;

FIG. 18A and FIGS. 18B to 18D are, respectively, a plan view and cross-sectional views that illustrate an example of a method for manufacturing a semiconductor device;

FIG. 19A and FIGS. 19B to 19D are, respectively, a plan view and cross-sectional views that illustrate an example of a method for manufacturing a semiconductor device;

FIG. 20 is a block diagram illustrating a structure example of a semiconductor device;

FIGS. 21A to 21H illustrate examples of circuit structures of memory cells;

FIG. 22 is a cross-sectional view illustrating an example of a semiconductor device;

FIGS. 23A and 23B are perspective views each illustrating a structure example of a semiconductor device;

FIG. 24 is a cross-sectional view illustrating an example of a semiconductor device;

FIG. 25 is a block diagram illustrating a CPU;

FIGS. 26A and 26B are perspective views of a semiconductor device;

FIGS. 27A and 27B are perspective views of a semiconductor device;

FIGS. 28A and 28B each illustrate a hierarchy of various kinds of memory devices;

FIGS. 29A and 29B illustrate examples of electronic devices, and FIGS. 29C to 29E illustrate an example of a large computer;

FIG. 30 illustrates an example of space equipment; and

FIG. 31 illustrates an example of a storage system that can be used in a data center.

### DETAILED DESCRIPTION OF THE INVENTION

Embodiments will be described in detail with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the present invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

Note that the terms “film” and “layer” can be used interchangeably depending on the case or the circumstances. For example, the term “conductive layer” can be replaced with the term “conductive film”. As another example, the term “insulating film” can be replaced with the term “insulating layer”. Moreover, the term “oxide semiconductor film” can be replaced with the term “oxide semiconductor layer”. The term “conductor” can be replaced with the term “conductive layer” or “conductive film” depending on the case or the circumstances. The term “insulator” can be replaced with the term “insulating layer” or “insulating film” depending on the case or the circumstances. The term “oxide semiconductor” can be replaced with the term “oxide semiconductor layer” or “oxide semiconductor film” depending on the case or the circumstances.

In this specification and the like, the term “parallel” indicates that the angle formed between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −20° and less than or equal to 20°. The term “perpendicular” indicates that the angle formed between two straight lines is greater than or equal to 80° and less than or equal to 100°. Thus, the case where the angle is greater than or equal to 85° and less than or equal to 95° is also included. In addition, the term “substantially perpendicular” indicates that the angle formed between two straight lines is greater than or equal to 70° and less than or equal to 110°.

Examples of an opening include a groove and a slit. A region where the opening is formed may be referred to as an opening portion.

In the drawings used in this specification and the like, a sidewall of an insulator in an opening is perpendicular or substantially perpendicular to a substrate surface or a formation surface, but the sidewall may have a tapered shape.

In this specification and the like, the tapered shape refers to a shape such that at least part of a side surface of a component is inclined with respect to a substrate surface or a formation surface. For example, a tapered shape preferably includes a region where the angle between the inclined side surface and the substrate surface or the formation surface (hereinafter, such an angle is referred to as a taper angle in some cases) is less than 90°. Note that the side surface of the component and the substrate surface are not necessarily completely flat and may be substantially flat with a slight curvature or with slight unevenness.

### Embodiment 1

In this embodiment, an oxide semiconductor layer of one embodiment of the present invention is described. The oxide semiconductor layer of one embodiment of the present invention is preferably used as a semiconductor layer of a transistor. In the case where the oxide semiconductor layer of one embodiment of the present invention is used as a semiconductor layer of a transistor, the oxide semiconductor layer includes a channel formation region. The oxide semiconductor layer preferably includes a source region and a drain region.

### [Oxide Semiconductor Layer]

The oxide semiconductor layer of one embodiment of the present invention preferably includes a metal oxide layer having crystallinity. Examples of the structure of a metal oxide having crystallinity include a c-axis aligned crystalline (CAAC) structure, a polycrystalline structure, and a nano-crystal (nc) structure. By using a metal oxide layer having crystallinity as the oxide semiconductor layer, the density of defect states in the oxide semiconductor layer can be reduced. Thus, the reliability of a transistor including the oxide semiconductor layer of one embodiment of the present invention can be enhanced, and the reliability of a semiconductor device including the transistor can be enhanced.

The oxide semiconductor layer of one embodiment of the present invention preferably includes a metal oxide having a CAAC structure, in particular. Note that the CAAC structure is a crystal structure in which a plurality of microcrystals (typically, a plurality of microcrystals having a hexagonal crystal structure) have c-axis alignment and are connected on the a-b plane without alignment. In cross-sectional observation of an oxide semiconductor layer having a CAAC structure with use of a high-resolution transmission electron microscope (TEM) image, metal atoms are observed to be arranged in a layered manner in a crystal part. Thus, the oxide semiconductor layer having the CAAC structure can also be regarded as having a structure including the layered crystal part.

The polycrystalline structure includes a crystal grain boundary (grain boundary). When an oxide semiconductor layer having a polycrystalline structure is formed and then subjected to heat treatment, a minute gap (also referred to as a nano crack or a micro crack) or a minute space (also referred to as a nano space or a micro space) can be formed between crystal parts. When a minute gap or a minute space is formed in the oxide semiconductor layer, the electric resistance of the oxide semiconductor layer is increased. This is because the electric resistance of the minute gap or the minute space is extremely high, for example, infinite. In the case where an oxide semiconductor layer including a minute gap or a minute space is used for a channel formation region of a transistor, the contact resistance between the oxide semiconductor layer and one or both of a source electrode and a drain electrode becomes high. This adversely affects initial characteristics or reliability of the transistor. In the CAAC structure, grain boundaries (grain boundaries) in the a-b plane are not observed clearly; thus, a highly reliable semiconductor device can be achieved. Furthermore, because the CAAC structure has a small number of crystal grain boundaries, an energy barrier for carrier conduction in a channel of a transistor is low, and an on-state current is expected to be increased.

The crystallinity of the oxide semiconductor layer can be analyzed by X-ray diffraction (XRD), TEM, or electron diffraction (ED), for example. Alternatively, these methods may be combined as appropriate for analysis.

Note that there is no particular limitation on the crystallinity of a semiconductor material included in the oxide semiconductor layer. For example, at least one of an amorphous semiconductor (a semiconductor having an amorphous structure), a single crystal semiconductor (a semiconductor having a single crystal structure), and a semiconductor having other crystallinity than single crystal (a microcrystalline semiconductor, a polycrystalline semiconductor, or a semiconductor partly including crystal regions) may be included. The oxide semiconductor layer having crystallinity can inhibit deterioration of the transistor characteristics in some cases.

Examples of the metal oxide included in the oxide semiconductor layer of one embodiment of the present invention include indium oxide, gallium oxide, and zinc oxide. The metal oxide of one embodiment of the present invention preferably contains at least indium (In) or zinc (Zn). The metal oxide preferably contains two or three selected from indium, an element M, and zinc. The element M is a metal element or metalloid element that has a high bonding energy with oxygen, such as a metal element or metalloid element whose bonding energy with oxygen is higher than that of In. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more of the above elements, further preferably one or more selected from aluminum, gallium, tin, and yttrium, still further preferably gallium. When the element M included in the metal oxide is gallium, the metal oxide of one embodiment of the present invention preferably includes one or more selected from indium, gallium, and zinc. In this specification and the like, a metal element and a metalloid element may be collectively referred to as a “metal element”, and a “metal element” in this specification and the like may refer to a metalloid element.

Examples of the metal oxide of one embodiment of the present invention include indium zinc oxide (also referred to as In—Zn oxide or IZO (registered trademark)), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (also referred to as In—Ga—Sn oxide, IGTO), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (also referred to as In—Sn—Zn oxide or ITZO (registered trademark)), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, or IAGZO). Alternatively, indium tin oxide containing silicon (also referred to as ITSO), gallium tin oxide (Ga—Sn oxide), aluminum tin oxide (Al—Sn oxide), or the like can be given.

By increasing the proportion of the number of indium atoms in the total number of atoms of all the metal elements included in the metal oxide, a high on-state current and high frequency characteristics of the transistor can be achieved.

Instead of indium, the metal oxide may contain one or more kinds of metal elements whose period number in the periodic table is large. Alternatively, in addition to indium, the metal oxide may contain one or more kinds of metal elements whose period number in the periodic table is large. The larger the overlap between orbits of metal elements is, the more likely it is that the metal oxide will have high carrier conductivity. Thus, when a metal element with a large period number in the periodic table is contained in the metal oxide, the field-effect mobility of the transistor can be increased in some cases. Examples of the metal element with a large period number in the periodic table include Period 5 metal elements and Period 6 metal elements. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds selected from nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor is suppressed and the transistor can have high reliability.

By increasing the proportion of the element M atoms in the sum of atoms of all metal elements included in the metal oxide, oxygen vacancies can be prevented from being formed in the metal oxide. Accordingly, generation of carriers due to oxygen vacancies is inhibited, which reduces the off-state current of the transistor. Furthermore, a change in electrical characteristics of the transistor is suppressed and the transistor can have high reliability.

In the description of this embodiment, In—Ga—Zn oxide is sometimes given as an example of the metal oxide.

The oxide semiconductor layer of one embodiment of the present invention can be obtained by forming metal oxides by two kinds of formation methods. For example, the oxide semiconductor layer of one embodiment of the present invention can be obtained by forming metal oxides by a first formation method and a second formation method. The oxide semiconductor layer obtained by the two kinds of formation methods may be referred to as a hybrid OS.

The oxide semiconductor layer of one embodiment of the present invention has crystallinity. The oxide semiconductor layer of one embodiment of the present invention preferably has a CAAC structure.

In the formation of the oxide semiconductor layer of one embodiment of the present invention, a metal oxide having crystallinity is deposited by a first formation method. The metal oxide deposited at this time particularly preferably has a CAAC structure. A metal oxide film deposited by, for example, a sputtering method is likely to have crystallinity.

In the case where a metal oxide is formed by the first formation method, a mixed layer is sometimes formed at the interface between the metal oxide and a layer (formation surface) on which the metal oxide is deposited. For example, in the case where a sputtering method is used as the first formation method, the mixed layer is sometimes formed by e.g., particles ejected from a target or the like (also referred to as sputtered particles), or energy applied to the substrate side by the sputtered particles or the like. There is a concern that the mixed layer may hinder crystallization of the metal oxide.

For example, in the case where an insulating layer containing silicon, e.g., silicon oxide, is used as the formation surface and a metal oxide is formed over the silicon oxide by the first formation method, silicon is liable to enter the metal oxide. There is a concern that the entry of impurities such as silicon into the metal oxide may hinder crystallization of the metal oxide.

In view of the above, in one embodiment of the present invention, a metal oxide is formed by the second formation method before a metal oxide is formed by the first formation method. In other words, a metal oxide is formed by the second formation method as a first layer, and then a metal oxide is formed by the first formation method as a second layer over the first layer. In that case, the second formation method preferably causes less damage to a formation surface than the first formation method. When a formation method that causes less damage to a formation surface is used as the second formation method, formation of a mixed layer at an interface between the oxide semiconductor layer and a layer that is the formation surface of the oxide semiconductor layer can be inhibited. Moreover, entry of impurities such as silicon can be inhibited in the second layer, which can increase the crystallinity. For example, an atomic layer deposition (ALD) method and a chemical vapor deposition (CVD) method are suitable as the second formation method because they can reduce damages to a formation surface as compared with a sputtering method.

In addition, for example, a metal oxide having a microcrystalline structure or an amorphous structure that has lower crystallinity than the CAAC structure is sometimes formed as the first layer. Formation of the second layer having high crystallinity on the first layer having low crystallinity or the formation of the second layer followed by heat treatment can increase the crystallinity of the first layer with the second layer as a nucleus in some cases. Accordingly, the crystallinity can be increased in the whole oxide semiconductor layer including the vicinity of the interface with the formation surface in some cases.

In a preferred mode of the oxide semiconductor layer of one embodiment of the present invention, a metal oxide is formed over a formation surface by the second formation method, and then a metal oxide is formed thereover by the first formation method.

Examples of the first formation method include a sputtering method and a pulsed laser deposition (PLD) method.

Examples of the second formation method include an ALD method, a plasma enhanced CVD (PECVD) method, a thermal CVD method, a photo CVD method, a metal organic CVD (MOCVD) method, and a molecular beam epitaxy (MBE) method. The MBE method is a formation method in which a thin film having a crystal structure reflecting a crystal system of a substrate is grown, and is one of formation methods that causes less damage to a formation surface. A wet method can be used as the second formation method. The wet method is one of formation methods that cause less damage to a formation surface. An example of the wet method is a spray coating method.

For example, the oxide semiconductor layer of one embodiment of the present invention can be formed in the following manner: a metal oxide is formed as a first layer by the second formation method, and then a metal oxide is formed as a second layer by the first formation method. Specifically, an ALD method can be employed as the second formation method, and a sputtering method can be employed as the first formation method. The metal oxide formed by the first formation method preferably has a CAAC structure.

Furthermore, a third layer can be formed over the second layer. Because the second layer has high crystallinity, the third layer can grow with a crystal of the second layer as a nucleus or a seed. Thus, the third layer can be crystallized even when a formation method that easily gives crystallinity is not employed as the formation method of the third layer. Here, for example, when a formation method that gives higher coverage than that of the second layer is employed for formation of the third layer, the whole oxide semiconductor layer can have both high crystallinity and high coverage. For example, when a formation method that causes less damage than damage to the second layer is employed for formation of the third layer, damage to the second layer can be reduced and high crystallinity can be obtained in the whole oxide semiconductor layer.

Furthermore, when the second layer is less affected by the formation surface of the oxide semiconductor layer owing to the formation of the first layer, the second layer has improved crystallinity and extremely excellent crystallinity. Thus, the third layer grown with the second layer as a nucleus or a seed is also expected to have extremely excellent crystallinity.

Note that the third layer is the uppermost layer of the oxide semiconductor layer. In the case where the oxide semiconductor layer is used as a semiconductor layer of a transistor described later, the third layer is, for example, a layer in contact with a gate insulating layer. Increasing the crystallinity of the layer in contact with the gate insulating layer can increase the carrier mobility in an on state of the transistor.

In an example, the oxide semiconductor layer of one embodiment of the present invention can be formed in the following manner: a metal oxide is formed as the first layer by the second formation method, a metal oxide is formed as the second layer by the first formation method, and a metal oxide is formed as the third layer by the second formation method. Specifically, an ALD method can be employed for the second formation method, and a sputtering method can be employed for the first formation method. The metal oxide formed by the first formation method preferably has a CAAC structure. The ALD method is a formation method that achieves higher coverage than a sputtering method, and when the ALD method is employed for the formation methods of the first layer and the third layer, the coverage with the oxide semiconductor layer can be improved. Thus, the oxide semiconductor layer can be formed to favorably cover a step, an opening portion, or the like with a high aspect ratio.

Examples of the sputtering method include an RF sputtering method using a high-frequency power source for a sputtering power source, a DC sputtering method using a DC power source, and a pulsed DC sputtering method in which a voltage applied to an electrode is changed in a pulsed manner. The RF sputtering method is mainly employed in the case where an insulating film is formed, and the DC sputtering method is mainly employed in the case where a metal conductive film is formed. The pulsed DC sputtering method is mainly employed in the case where a compound such as an oxide, a nitride, or a carbide is deposited by a reactive sputtering method.

Examples of the ALD method include a thermal ALD method, in which a precursor and a reactant react with each other only by a thermal energy, and a plasma-enhanced ALD (PEALD) method, in which a reactant excited by plasma is used.

The ALD method enables deposition of one-by-one atomic layer, and has various advantages such as formation of an extremely thin film, deposition on a component with a high aspect ratio, deposition on a surface having a large step, formation of a film with few defects such as pinholes, deposition with excellent coverage, and low-temperature deposition. The PEALD method utilizing plasma may be preferred because deposition at lower temperature is possible. Note that some precursors used in the ALD method contain an element such as carbon or chlorine. Thus, a film formed by the ALD method sometimes contains an element such as carbon or chlorine in a larger quantity than a film formed by another formation method. Note that element quantification can be performed by X-ray photoelectron spectroscopy (XPS) or secondary ion mass spectrometry (SIMS). The formation method of a metal oxide of one embodiment of the present invention, which employs an ALD method and one or both of a deposition condition with a high substrate temperature and impurity removal treatment, can sometimes form a film with smaller amounts of carbon and chlorine than a method employing an ALD method without the deposition condition with a high substrate temperature or the impurity removal treatment.

Unlike in a formation method in which particles ejected from a target or the like are deposited, the ALD method is a formation method in which a film is formed by reaction at a surface of an object to be processed. Thus, the ALD method can provide good step coverage, almost regardless of the shape of an object. In particular, the ALD method allows excellent step coverage and excellent thickness uniformity and is suitable for covering a surface of an opening portion with a high aspect ratio, for example.

A high-quality film can be obtained at a relatively low temperature by a PECVD method. A thermal CVD method does not use plasma and thus can cause less plasma damage to an object. The thermal CVD method yields a film with few defects because of no plasma damage during deposition.

By a CVD method, a film with a certain composition can be deposited by adjusting the flow rate ratio of source gases. For example, a CVD method enables a film with a gradually-changed composition to be deposited by changing the flow rate ratio of source gases during deposition. In the case where a film is deposited while the flow rate ratio of source gases is changed, as compared to the case where a film is deposited using a plurality of deposition chambers, the time taken for the deposition can be shortened because the time taken for transfer and pressure adjustment is removed. Hence, the productivity of the semiconductor device can be improved in some cases.

### [Formation Method of Oxide Semiconductor Layer]

For example, an oxide semiconductor 30 that is an oxide semiconductor layer can be formed in the following manner: an oxide semiconductor 30a is formed over a layer 29 that is a formation surface of the oxide semiconductor by an ALD method, an oxide semiconductor 30b is formed over the oxide semiconductor 30a by a sputtering method, and an oxide semiconductor 30c is formed over the oxide semiconductor 30b by an ALD method. Here, in the case where the layer 29 is formed over a substrate, the layer 29 and the oxide semiconductor 30 can be formed in parallel or substantially in parallel with a surface of the substrate.

Moreover, heat treatment is preferably performed after the formation of the oxide semiconductor 30. By performing the heat treatment, the crystallinity of the oxide semiconductor 30 can be increased. Here, the heat treatment is not limited to heating. For example, the heat treatment may be performed with heat applied in the manufacturing process.

The layer 29 is an insulating film, and examples of the insulating film include silicon oxide, silicon oxynitride, silicon nitride, silicon nitride oxide, aluminum oxide, and hafnium oxide. As the layer 29, a film that is described later as an insulator included in the semiconductor device can be used.

Alternatively, the layer 29 may be a conductive film. For example, the oxide semiconductor 30 can also be formed over a conductive film functioning as an electrode of the semiconductor device.

The layer 29 does not need to have crystallinity. In other words, the layer 29 may have an amorphous structure. In the case where the layer 29 has crystallinity, the layer 29 may have a crystal structure with low lattice matching with the metal oxide included in the oxide semiconductor 30.

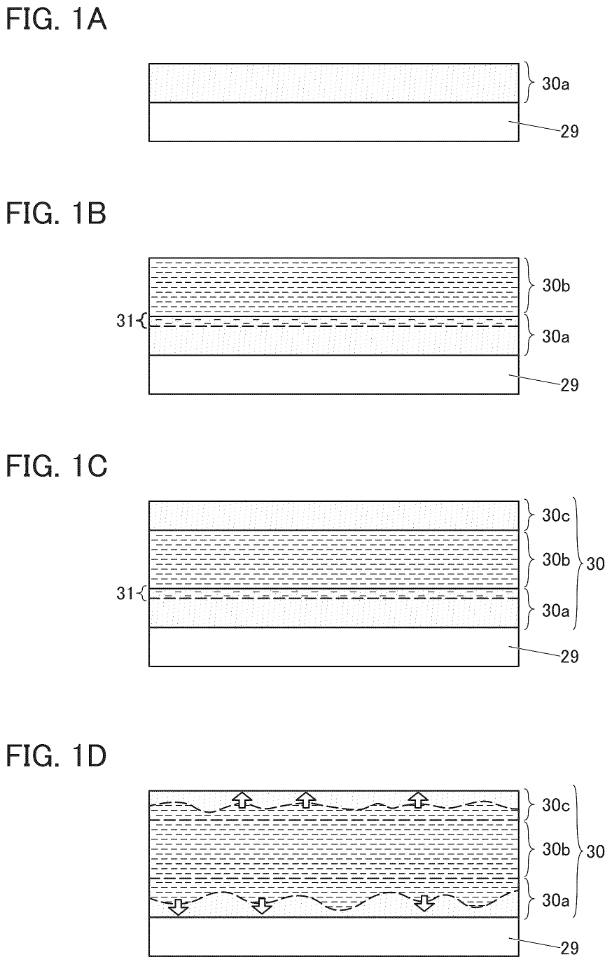

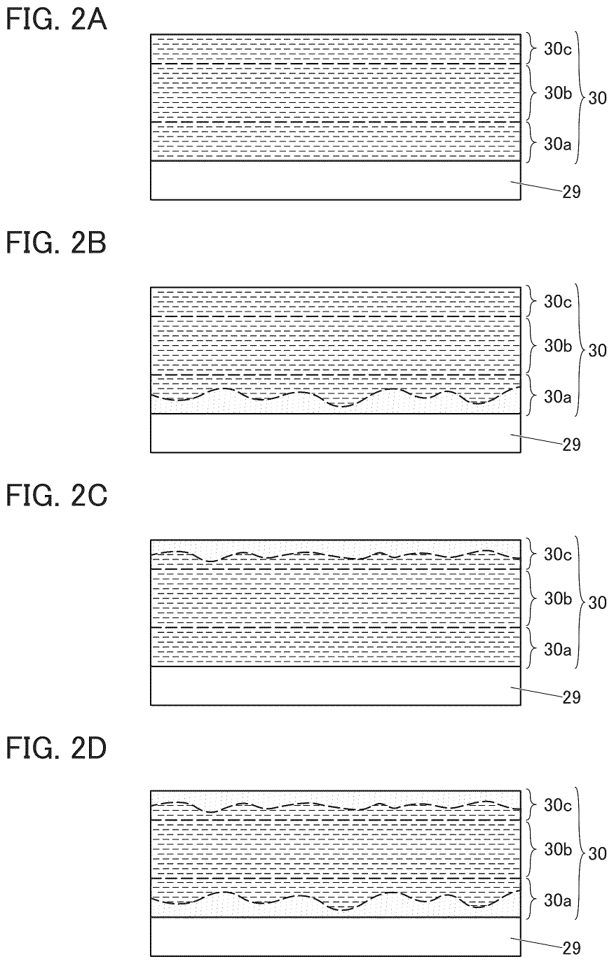

An example of a method for forming the oxide semiconductor 30 is described with reference to FIGS. 1A to 1D and FIGS. 2A to 2D.

First, the oxide semiconductor 30a is formed over the layer 29 (FIG. 1A). Next, the oxide semiconductor 30b is formed over the oxide semiconductor 30a (FIG. 1B).

The oxide semiconductor 30b is preferably formed by a sputtering method. The oxide semiconductor 30b preferably has a composition suitable for forming the CAAC structure.

The oxide semiconductor 30a is preferably formed by a formation method that causes less damage to a formation surface than a formation method of the oxide semiconductor 30b. Here, the oxide semiconductor 30a is formed by an ALD method.

In the case where the metal oxide film is deposited by a sputtering method, damage to the formation surface may cause alloying of a component contained in the metal oxide film with a component contained in the layer serving as the formation surface. In the case where alloying occurs, it is difficult to increase the crystallinity of the alloyed region even when heat treatment described later is performed. When an oxide semiconductor layer including the alloyed region is used for a transistor, the initial characteristics or reliability of the transistor may be adversely affected. Therefore, it is preferable to inhibit alloying of the component contained in the metal oxide film with the component contained in the layer serving as the formation surface.

In the method for forming the oxide semiconductor layer of one embodiment of the present invention, the oxide semiconductor 30a is formed over the layer 29, and then the oxide semiconductor 30b is formed by a sputtering method. In this case, the oxide semiconductor 30a is preferably formed by a formation method that causes less damage to the formation surface. When the oxide semiconductor 30a is formed between the oxide semiconductor 30b and the layer 29 by a formation method that causes less damage to the formation surface, the alloying of the component contained in the oxide semiconductor 30 with the component contained in the layer 29 can be inhibited, so that the crystallinity of the oxide semiconductor 30 can be further increased.

The above structure can reduce the thickness of the alloyed region or reduce the thickness of the alloyed region to the extent that the alloyed region cannot be observed. For example, the thickness of the alloyed region can be greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm. Note that FIGS. 1A and 1B illustrate an example in which an alloyed region is not formed between the layer 29 and the oxide semiconductor 30a.

Furthermore, the thickness of the alloyed region can sometimes be obtained by composition analysis of the region and its vicinity with SIMS or energy dispersive X-ray spectroscopy (EDX) line analysis.

For example, EDX line analysis is performed on the region and its vicinity with the direction perpendicular to the formation surface of the oxide semiconductor 30a as the depth direction. Next, in profiles of quantitative values of elements in the depth direction obtained by the analysis, the depth at which the quantitative value of a metal that is the main component of the oxide semiconductor 30a and is not the main component of a layer (here, the layer 29) serving as a formation surface (the metal is In when the oxide semiconductor 30a contains In) becomes half is defined as a depth (position) of the interface between the region and the oxide semiconductor 30a. Furthermore, the depth at which the quantitative value of an element (e.g., Si) that is the main component of the layer serving as the formation surface and that is not the main component of the oxide semiconductor 30a becomes half is defined as a depth (position) of the interface between the region and the layer serving as the formation surface. In the above manner, the thickness of the alloyed region can be calculated.

When the thickness of the alloyed region in the oxide semiconductor layer of one embodiment of the present invention is observed by EDX analysis, the thickness is greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm, for example.

For example, in the case where SIMS analysis of the oxide semiconductor 30 formed over the layer 29 that is formed using a silicon oxide layer is performed, the depth at which the silicon concentration is 50% of the maximum value of the silicon concentration of the layer 29 is defined as an interface, and the distance between the interface and the depth at which the silicon concentration decreases to 1.0×10²¹ atoms/cm³, preferably 5.0×10²⁰ atoms/cm³, further preferably 1.0×10²⁰ atoms/cm³ is defined as a thickness t_s2. The thickness t_s2 is preferably less than or equal to 3 nm, further preferably less than or equal to 2 nm.

When the thickness of the alloyed region is reduced, the thickness t_s2 can be a value within the above range.

Note that when the thickness of the alloyed region is reduced, the CAAC structure can be formed in the vicinity of the formation surface. Here, the vicinity of the formation surface refers to, for example, a region ranging from the formation surface of the oxide semiconductor 30 to greater than 0 nm and less than or equal to 3 nm, preferably greater than 0 nm and less than or equal to 2 nm, further preferably greater than or equal to 1 nm and less than or equal to 2 nm in a direction substantially perpendicular to the formation surface of the oxide semiconductor 30.

Note that the CAAC structure in the vicinity of the formation surface can be confirmed in TEM observation in some cases. For example, in high-resolution TEM cross-sectional observation of the oxide semiconductor 30, bright spots arranged in a layered manner in a direction parallel to the formation surface are observed in the vicinity of the formation surface.

Alternatively, the CAAC structure in the vicinity of the formation surface can be evaluated from a map showing crystal orientation in some cases. The map showing crystal orientation can be obtained by, for example, obtaining a cross-sectional TEM image, performing fast Fourier transform (FFT) processing on each region in the cross-sectional TEM image to create an FFT pattern, and calculating the direction of the crystal axis of each region. The FFT pattern reflects reciprocal lattice space information like an electron diffraction pattern. For example, a region where the directions of the crystal axes in the calculated regions are greater than or equal to 70° and less than or equal to 100° with respect to the formation surface can be regarded as a CAAC structure.

Note that when the oxide semiconductor 30a is formed by an ALD method, an oxide semiconductor layer having a microcrystalline structure or an amorphous structure that has lower crystallinity than the CAAC structure may be formed. That is, in the formation step illustrated in FIG. 1A, the oxide semiconductor 30a sometimes includes a region having lower crystallinity than the oxide semiconductor 30b.

Here, a method for forming an In-M-Zn oxide as the oxide semiconductor 30a by an ALD method is described. Note that the details of the formation of the metal oxide by an ALD method will be described later.

First, a source gas that contains a precursor containing indium is introduced into a chamber so that the precursor is adsorbed on the surface of the layer 29. Here, the substrate heating temperature is preferably a temperature corresponding to the decomposition temperature of the precursor.

Next, introduction of the source gas is stopped and the chamber is purged so that an excess precursor, a reaction product, and the like are removed from the chamber. Then, an oxidizer is introduced as a reactant into the chamber to react with the adsorbed precursor, and components other than indium are released while indium is adsorbed on the substrate, whereby a layer in which indium and oxygen are bonded to each other is formed (hereinafter, the layer is referred to as a first layer). Ozone, oxygen, water, or the like can be used as the oxidizer. After that, introduction of the oxidizer is stopped and the chamber is purged so that an excess reactant, a reaction product, and the like are removed from the chamber.

Subsequently, a source gas that contains a precursor containing the element M is introduced into the chamber, so that the precursor is adsorbed on the first layer. Here, the substrate heating temperature is preferably a temperature corresponding to the decomposition temperature of the precursor.

Next, introduction of the source gas is stopped and the chamber is purged so that an excess precursor, a reaction product, and the like are removed from the chamber. Then, an oxidizer is introduced as a reactant into the chamber to react with the adsorbed precursor, and components other than the element M are released while the element M is adsorbed on the substrate, whereby a layer in which the element M and oxygen are bonded to each other is formed (hereinafter, the layer is referred to as a second layer). After that, introduction of the oxidizer is stopped and the chamber is purged so that an excess reactant, a reaction product, and the like are removed from the chamber.

Next, a source gas that contains a precursor containing zinc is introduced into the chamber and adsorbed on the second layer. Here, the substrate heating temperature is preferably a temperature corresponding to the decomposition temperature of the precursor.

Here, in the case of a thermal ALD method in which triethylindium is used as the precursor containing indium, triethylgallium is used as a precursor containing gallium, and diethylzinc is used as the precursor containing zinc, the substrate heating temperature is higher than or equal to 100° C. and lower than or equal to 350° C., preferably higher than or equal to 150° C. and lower than or equal to 300° C., for example.

Next, introduction of the source gas is stopped and the chamber is purged so that an excess precursor, a reaction product, and the like are removed from the chamber. Then, an oxidizer is introduced as a reactant into the chamber to react with the adsorbed precursor, and components other than zinc are released while zinc is adsorbed on the substrate, whereby a layer in which zinc and oxygen are bonded to each other is formed (hereinafter, the layer is referred to as a third layer). After that, introduction of the oxidizer is stopped and the chamber is purged so that an excess reactant, a reaction product, and the like are removed from the chamber.

Next, the first layer is formed again over the third layer by the above-described method. By repeating the above steps, an In-M-Zn oxide can be formed as the oxide semiconductor 30a over the layer 29 by an ALD method.

When an ALD method is used, the composition of a film to be formed can be controlled with the amount of introduced source gases. For example, a film with a certain composition can be formed by adjusting the amount of introduced source gases, the number of times of introduction (also referred to as the number of pulses), and the time required for one pulse (also referred to as the pulse time) in an ALD method. Moreover, for example, when the source gas is changed during the deposition in an ALD method, a film whose composition is continuously changed can be formed. In the case where a film is formed while the source gas is changed, as compared with the case where a film is formed using a plurality of deposition chambers, the time taken for the film formation can be shortened because the time taken for transfer and pressure adjustment is omitted. Hence, the productivity of the semiconductor device can be improved in some cases.

After the oxide semiconductor 30a is formed by an ALD method, an In-M-Zn oxide is formed over the oxide semiconductor 30a by a sputtering method as the oxide semiconductor 30b.

When the oxide semiconductor 30b is formed by a sputtering method, a mixed layer 31 is formed on the surface of the oxide semiconductor 30a or in the vicinity of the surface. A fine crystal region is sometimes formed in the mixed layer 31 by, for example, sputtered particles or energy or the like applied to the substrate side by sputtered particles or the like at the time of forming the oxide semiconductor 30b. In the subsequent heat treatment step, the mixed layer 31 or the fine crystal region formed in the mixed layer 31 serves as a nucleus, and at least part of the oxide semiconductor 30a is crystallized in some cases.

As a target used in a sputtering method, an In-M-Zn oxide can be used. In the case where a metal oxide is formed by a sputtering method, oxygen or a mixed gas of oxygen and a noble gas can be used as a sputtering gas. In addition, an increase in the proportion of oxygen in the sputtering gas can increase the amount of excess oxygen contained in the oxide film to be deposited.

A higher proportion of the flow rate of an oxygen gas to the flow rate of the whole formation gas (also referred to as oxygen flow rate ratio) used at the time of forming the metal oxide enables the formed metal oxide to have higher crystallinity in some cases.

When the metal oxide is formed by a sputtering method and the oxygen proportion of oxygen in the sputtering gas is higher than 30% and lower than or equal to 100%, preferably higher than or equal to 70% and lower than or equal to 100%, an oxygen-excess metal oxide is formed in some cases. A transistor including an oxygen-excess metal oxide in a channel formation region can have relatively high reliability. However, one embodiment of the present invention is not limited thereto. When the proportion of oxygen in the sputtering gas is higher than or equal to 1% and lower than or equal to 30%, preferably higher than or equal to 5% and lower than or equal to 20%, oxygen-deficient metal oxide is formed. A transistor including the oxygen-deficient metal oxide in a channel formation region can have relatively high field-effect mobility.

Note that in the case where the metal oxide is formed by a sputtering method, the atomic ratio of the deposited metal oxide may be different from the atomic ratio of the sputtering target. In particular, the zinc content of the deposited metal oxide may be reduced to approximately 50% of that of the sputtering target.

In the deposition of the oxide semiconductor 30b by a sputtering method, substrate heating is preferably performed. In forming a metal oxide, the substrate temperature (stage temperature) at the time of forming the metal oxide is increased, whereby a metal oxide with high crystallinity can be formed in some cases. In the deposition of the oxide semiconductor 30b by a sputtering method, the substrate heating temperature is preferably higher than or equal to 100° C. and lower than or equal to 400° C., further preferably higher than or equal to 200° C. and lower than or equal to 300° C., for example.

As described above, as illustrated in FIG. 1B, the oxide semiconductor 30a and the oxide semiconductor 30b over the oxide semiconductor 30a can be formed over the layer 29.

Next, the oxide semiconductor 30c is formed over the oxide semiconductor 30b (FIG. 1C). Here, the oxide semiconductor 30c is formed by an ALD method. For the formation of the oxide semiconductor 30c by an ALD method, the method for forming the oxide semiconductor 30a can be referred to.

When the oxide semiconductor 30c having lower crystallinity than the CAAC structure is formed over the oxide semiconductor 30b having the CAAC structure by an ALD method, the oxide semiconductor 30c may epitaxially grow with the oxide semiconductor 30b as a nucleus. Thus, at the time of forming the oxide semiconductor 30c, the oxide semiconductor 30c may include a region having a CAAC structure. The region having the CAAC structure is preferably formed throughout the oxide semiconductor 30c.

Next, heat treatment may be performed.

The heat treatment temperature can be higher than or equal to 100° C. and lower than or equal to 800° C., preferably higher than or equal to 250° C. and lower than or equal to 650° C., further preferably higher than or equal to 350° C. and lower than or equal to 550° C., for example. Typically, the temperature can be set to 400° C.±25° C. (higher than or equal to 375° C. and lower than or equal to 425° C.). The treatment time can be shorter than or equal to 10 hours, longer than or equal to 1 minute and shorter than or equal to 5 hours, or longer than or equal to 1 minute and shorter than or equal to 2 hours. In the case of using an RTA apparatus, the processing time can be longer than or equal to 1 second and shorter than or equal to 5 minutes, for example. By the heat treatment, the oxide semiconductor 30c (in other words, crystal molecules formed by an ALD method) is expected to fill the atomic-level space between crystal parts of the CAAC structure of the oxide semiconductor 30b.

The heating apparatus used for the heat treatment is not limited to a particular apparatus, and may be an apparatus for heating an object to be processed by heat conduction or heat radiation from a heating element such as a resistance heating element. For example, an electric furnace, or a rapid thermal annealing (RTA) apparatus such as a lamp rapid thermal annealing (LRTA) apparatus or a gas rapid thermal annealing (GRTA) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high-temperature gas.

By the heat treatment step, the crystallinity of the region having the CAAC structure in the oxide semiconductor 30c is increased in some cases. In the case where the region is formed only below the oxide semiconductor 30c after deposition by an ALD method, the region may be extended upward by the heat treatment step (FIG. 1D). That is, by the heat treatment, the region having a CAAC structure is sometimes formed in the whole layer of the oxide semiconductor 30c.

Through the heat treatment step, the oxide semiconductor 30b is further repaired by the oxide semiconductor 30c (in other words, crystal molecules formed by an ALD method) that fills the atomic-level space between crystal parts of the CAAC structure of the oxide semiconductor 30b in some cases.

At least part of the oxide semiconductor 30a preferably has a CAAC structure by the heat treatment step (FIG. 1D). The CAAC structure is expected to be easily generated when the mixed layer 31 formed in the oxide semiconductor 30a in the formation of the oxide semiconductor 30b becomes a nucleus or a seed. The oxide semiconductor 30a preferably has a large CAAC region, and the CAAC region preferably extends to the vicinity of the layer 29.

Since the CAAC region extends from the upper portion to the lower portion of the oxide semiconductor 30a, the CAAC region can extend to the vicinity of the layer 29, regardless of the material and crystallinity of the layer 29. For example, even when the layer 29 has an amorphous structure, the oxide semiconductor 30a having high crystallinity can be formed. Thus, the method for forming the oxide semiconductor layer of one embodiment of the present invention is suitable for the case where a layer serving as the formation surface has an amorphous structure, in particular.

FIGS. 1A to 1D are cross-sectional views illustrating the formation method of a metal oxide of one embodiment of the present invention. FIGS. 1A to 1D can also be regarded as conceptual diagrams illustrating a deposition model of the metal oxide of one embodiment of the present invention. As illustrated in FIGS. 1A to 1D, the crystallinity of each of the oxide semiconductors 30a and 30c is increased with the oxide semiconductor 30b as a nucleus or a seed. Specifically, the crystallinity of the oxide semiconductor 30a may be increased at the time of depositing the oxide semiconductor 30b or by heat treatment after the deposition of the oxide semiconductor 30c. In addition, the crystallinity of the oxide semiconductor 30c may be increased at the time of depositing the oxide semiconductor 30c or by heat treatment after the deposition of the oxide semiconductor 30c. Note that the heat treatment has an assisting function of increasing the crystallinity.

As described above, in the method for forming a metal oxide of one embodiment of the present invention, the crystallinity of the oxide semiconductors (here, the oxide semiconductors 30a and 30c) above and below the oxide semiconductor 30b can be increased by using the oxide semiconductor 30b (i.e., CAAC) having high crystallinity as a nucleus or a seed. This can increase the crystallinity of the whole oxide semiconductor layer. In other words, the oxide semiconductor 30b serves as a nucleus or a seed to cause solid-phase growths of the oxide semiconductors above and below the oxide semiconductor 30b, so that the oxide semiconductor with high crystallinity can be formed. An oxide semiconductor formed by such a formation method, here, a CAAC film, may be referred to as an axial growth CAAC (Axial Growth CAAC or AG CAAC).

The region having a CAAC structure preferably spreads in the whole layer of the oxide semiconductor 30 including the oxide semiconductors 30a and 30c. FIG. 2A illustrates a state where the oxide semiconductors 30a, 30b, and 30c are each crystallized. Crystals in the region having a CAAC structure in the oxide semiconductor 30a are connected to crystals in the region having a CAAC structure in the oxide semiconductor 30b. Crystals in the region having a CAAC structure in the oxide semiconductor 30c are connected to the crystals in the region having a CAAC structure in the oxide semiconductor 30b. As a result, a boundary between the oxide semiconductor 30a and the oxide semiconductor 30b is not observed in some cases. In addition, a boundary between the oxide semiconductor 30b and the oxide semiconductor 30c is not observed in some cases. The oxide semiconductor 30 may be expressed as one layer where the interfaces are not clearly observed. The oxide semiconductor 30 may be expressed as a single layer in some cases.

Part of the oxide semiconductor 30a or part of the oxide semiconductor 30c is not crystallized in some cases. In addition, a region having crystallinity lower than that of the CAAC structure may be present in part of the oxide semiconductor 30a or part of the oxide semiconductor 30c. An example illustrated in FIG. 2B illustrates a state of the oxide semiconductor 30a where the vicinity of the interface between the oxide semiconductor 30a and the layer 29 is not crystallized or a region having crystallinity lower than that of the CAAC structure is present in the vicinity of the interface between the oxide semiconductor 30a and the layer 29. FIG. 2C illustrates a state where the vicinity of the surface of the oxide semiconductor 30c is not crystallized or a region having crystallinity lower than that of the CAAC structure is present in the vicinity of the surface of the oxide semiconductor 30c. FIG. 2D illustrates a state where the vicinity of the interface between the oxide semiconductor 30a and the layer 29 and the vicinity of the surface of the oxide semiconductor 30c are not crystallized or regions having crystallinity lower than that of the CAAC structure are present in the vicinity of the interface between the oxide semiconductor 30a and the layer 29 and in the vicinity of the surface of the oxide semiconductor 30c.

Increasing the crystallinity of the oxide semiconductor layer can inhibit an increase in the electric resistance of the semiconductor layer of a transistor including the oxide semiconductor layer or increase the initial characteristics (in particular, the on-state current) of the transistor, and thus a transistor suitable for high-speed operation can be expected. In addition, the reliability and the on current of the transistor can be improved.

By the method for forming the oxide semiconductor layer of one embodiment of the present invention, the crystallinities of the metal oxides positioned above and below can be improved with the metal oxide having the CAAC structure as the starting point, and the whole oxide semiconductor layer can have high crystallinity.

The oxide semiconductor layer of one embodiment of the present invention has high crystallinity throughout the whole layer. Thus, in the oxide semiconductor 30, the boundaries between the stacked films of the oxide semiconductors 30a, 30b, and 30c are not observed in some cases. In particular, after heat treatment is performed, the boundaries between the stacked films are difficult to observe in some cases. Whether the boundaries between the stacked films are present can be checked with a cross-sectional TEM or a cross-sectional STEM, for example.

As described above, when a metal oxide with a high In content is used for a transistor, the field-effect mobility of the transistor can be increased. On the other hand, an oxide semiconductor with a high In content tends to be polycrystallized. The use of a metal oxide having a polycrystalline structure for a transistor adversely affects the initial characteristics or reliability of the transistor. Thus, when an oxide semiconductor with a high In content is used for one or both of the oxide semiconductors 30a and 30c, crystals reflecting crystal orientations included in the oxide semiconductor 30b are formed, so that one or both of the oxide semiconductors 30a and 30c can be inhibited from being polycrystallized.

It is preferable that crystals included in the oxide semiconductor 30b and crystals included in the oxide semiconductor 30a or 30c have a small lattice mismatch. Thus, the oxide semiconductor 30a or 30c can form crystals reflecting the orientation of crystals included in the oxide semiconductor 30b. In this case, for example, in high-resolution TEM cross-sectional observation of the oxide semiconductor 30, bright spots arranged in a layered manner in a direction parallel to the formation surface are observed in the oxide semiconductor 30a or 30c.

As long as crystals included in the oxide semiconductor 30b and crystals included in the oxide semiconductor 30a or 30c have a small lattice mismatch, there is no particular limitation on the crystal structure of the oxide semiconductor 30a or 30c. The crystal structure of the oxide semiconductor 30a or 30c may be any of a cubic crystal structure, a tetragonal crystal structure, an orthorhombic crystal structure, a hexagonal crystal structure, a monoclinic crystal structure, and a trigonal crystal structure.

### [Composition of Oxide Semiconductor Layer]

As described above, the oxide semiconductor 30b preferably has a composition suitable for forming the CAAC structure. The oxide semiconductor 30b can be formed by a sputtering method, for example. In addition, the oxide semiconductor 30b preferably contains zinc, for example. The oxide semiconductor 30b containing zinc can be a metal oxide having high crystallinity. The oxide semiconductor 30b preferably contains an element M in addition to zinc. When the oxide semiconductor 30b contains the element M, formation of oxygen vacancies in the metal oxide can be inhibited, for example. Thus, the reliability of the transistor including an oxide semiconductor layer can be improved. As the oxide semiconductor 30b, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a composition of In:M:Zn=1:1:0.5 [atomic ratio] or in the neighborhood thereof, a metal oxide with a composition of In:M:Zn=1:1:2 [atomic ratio] or in the neighborhood thereof, a metal oxide with a composition of In:M:Zn=4:2:3 [atomic ratio] or in the neighborhood thereof, a metal oxide with a composition of In:M:Zn=1:3:2 [atomic ratio] or in the neighborhood thereof, or a metal oxide with a composition of In:M:Zn=1:3:4 [atomic ratio] or in the neighborhood thereof may be specifically used. Note that the neighborhood of the atomic ratio includes ±30% of an intended atomic ratio. In this case, it is preferable to use one or more of gallium, aluminum, and tin as the element M.

The oxide semiconductor 30b may have a structure not containing the element M. For example, an In—Zn oxide may be used. Specifically, a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be used. Alternatively, indium oxide may be used. A structure containing a slight amount of the element M may be employed. Examples of the composition include a composition of In:Ga:Zn=4:0.1:1 [atomic ratio] or in the neighborhood thereof and a composition of In:Ga:Zn=2:0.1:1 [atomic ratio] or in the neighborhood thereof. Other examples include a composition of In:Sn:Zn=4:0.1:1 [atomic ratio] or in the neighborhood thereof and a composition of In:Sn:Zn=2:0.1:1 [atomic ratio] or in the neighborhood thereof.

The oxide semiconductors 30a and 30c can be metal oxides with a high proportion of In. The oxide semiconductors 30a and 30c can each be formed by an ALD method, for example. In particular, a metal oxide in which the proportion of In is higher than that of the element M is preferably used. With the use of a metal oxide having a high proportion of In, the on-state current can be increased and the frequency characteristics can be enhanced in a transistor using an oxide semiconductor layer.

Alternatively, the oxide semiconductors 30a and 30c may each have a structure not containing the element M. For example, an In—Zn oxide may be used. Specifically, a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be used. Alternatively, indium oxide may be used. A structure containing a slight amount of the element M may be employed for the oxide semiconductors 30a and 30c. Examples of the composition include a composition of In:Ga:Zn=4:0.1:1 [atomic ratio] or in the neighborhood thereof, a composition of In:Ga:Zn=2:0.1:1 [atomic ratio] or in the neighborhood thereof, a composition of In:Sn:Zn=4:0.1:1 [atomic ratio] or in the neighborhood thereof, and a composition of In:Sn:Zn=2:0.1:1 [atomic ratio] or in the neighborhood thereof.

The oxide semiconductors 30a and 30c can each be a metal oxide having a higher proportion of In than that of the oxide semiconductor 30b.

For example, as the oxide semiconductors 30a and 30c, a metal oxide having a Ga proportion higher than that of the oxide semiconductor 30b can be used. For the oxide semiconductors 30a and 30c, it is preferable to use a metal oxide with a composition of In:Ga:Zn=1:1:1 [atomic ratio] or in the neighborhood thereof, a metal oxide with a composition of In:Ga:Zn=1:3:2 [atomic ratio] or in the neighborhood thereof, or a metal oxide with a composition of In:Ga:Zn=1:3:4 [atomic ratio] or in the neighborhood thereof. When the proportion of Ga is increased, the band gap of each of the oxide semiconductors 30a and 30c can be larger than that of the oxide semiconductor 30b in some cases, for example. Thus, the oxide semiconductor 30b is sandwiched between the oxide semiconductors 30a and 30c each having a wide band gap, and the oxide semiconductor 30b mainly functions as a current path (channel). When the oxide semiconductor 30b is sandwiched between the oxide semiconductors 30a and 30c, trap states at the interfaces with the oxide semiconductor 30b and the vicinity thereof can be reduced. Accordingly, a buried-channel transistor where a channel is away from the interface with an insulating layer can be achieved, whereby the field-effect mobility can be increased. Furthermore, the influence of interface states that may be formed on the back channel side is reduced, so that light deterioration (e.g., light negative bias deterioration) of the transistor can be inhibited and the reliability of the transistor can be increased.

In the oxide semiconductor layer of one embodiment of the present invention, even in the case where a composition in which the CAAC structure is less likely to be formed in the formation of a single layer is used for the oxide semiconductors 30a and 30c, crystal growth occurs with the oxide semiconductor 30b as a nucleus, so that the whole oxide semiconductor layer including the oxide semiconductors 30a and 30c can have a CAAC structure. Alternatively, a CAAC structure can be formed in a region that includes the oxide semiconductor 30b and at least part of each of the oxide semiconductors 30a and 30c.

In particular, even in a composition where the proportion of In in the oxide semiconductors 30a and 30c is high, crystallinity suitable for a semiconductor layer of a transistor can be obtained. For the oxide semiconductor layer of one embodiment of the present invention, it is possible to attain higher on-state characteristics of the transistor by increasing the proportion of In and a higher reliability by employing a CAAC structure with high crystallinity at the same time.

Note that the composition of the oxide semiconductor 30a may be different from that of the oxide semiconductor 30c.

A metal oxide having the same composition as the oxide semiconductor 30b may be used for the oxide semiconductors 30a and 30c. By using the same composition, the oxide semiconductors each have easily a CAAC structure after heat treatment in some cases.

The oxide semiconductor layer having a CAAC structure formed by the two kinds of formation methods sometimes has one or more of a higher dielectric constant, higher film density, and higher film hardness than the oxide semiconductor layer having a CAAC structure formed by one kind of formation method.

With the use of the oxide semiconductor layer having a CAAC structure formed by the above two kinds of formation methods for a channel formation region of a transistor, the transistor can have excellent characteristics (e.g., a high on-state current, high field-effect mobility, a low S value, high frequency characteristics (also referred to as f characteristics), or high reliability).

Analysis of the composition of the metal oxide used for the oxide semiconductor 30 can be performed by energy dispersive X-ray spectrometry (EDX), XPS, inductively coupled plasma-mass spectrometry (ICP-MS), or inductively coupled plasma-atomic emission spectrometry (ICP-AES). Alternatively, these methods may be combined as appropriate for the analysis. As for an element whose content is low, the actual content may be different from the content obtained by analysis because of the influence of the analysis accuracy. In the case where the content of the element M is low, for example, the content of the element M obtained by analysis may be lower than the actual content.

### [Oxide Semiconductor Layer of Transistor]

The oxide semiconductor layer of one embodiment of the present invention can be used for a semiconductor layer of a transistor, for example.

In the case where the oxide semiconductor 30 is used for a semiconductor layer of a transistor, the thickness of the oxide semiconductor 30 is preferably, e.g., greater than or equal to 3 nm and less than or equal to 200 nm, preferably greater than or equal to 3 nm and less than or equal to 100 nm, further preferably greater than or equal to 5 nm and less than or equal to 100 nm, further preferably greater than or equal to 10 nm and less than or equal to 100 nm, yet still further preferably greater than or equal to 10 nm and less than or equal to 70 nm, yet still further preferably greater than or equal to 15 nm and less than or equal to 70 nm, yet still further preferably greater than or equal to 15 nm and less than or equal to 50 nm, or yet still further preferably greater than or equal to 20 nm and less than or equal to 50 nm. In a transistor used for a miniaturized semiconductor device, the thickness of the oxide semiconductor 30 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm.

The thickness of the oxide semiconductor 30b is preferably less than or equal to 200 nm, for example. In the case where the oxide semiconductor 30b is in a form of layer, the thickness of the oxide semiconductor 30b is preferably, for example, greater than or equal to 1 nm and less than or equal to 200 nm, further preferably greater than or equal to 1 nm and less than or equal to 100 nm, yet further preferably greater than or equal to 2 nm and less than or equal to 100 nm.

Alternatively, when the oxide semiconductor 30b can function as a crystal nucleus, the oxide semiconductor 30b is not in a form of layer and may be an aggregate of island-shaped regions. For example, such island-shaped regions included in the oxide semiconductor 30b are discretely located.

The thickness of each of the oxide semiconductors 30a and 30c is preferably greater than or equal to 1 nm and less than or equal to 50 nm, further preferably greater than or equal to 1 nm and less than or equal to 30 nm, further preferably greater than or equal to 1 nm and less than or equal to 20 nm, still further preferably greater than or equal to 2 nm and less than or equal to 20 nm, for example.

An oxide semiconductor layer of one embodiment of the present invention includes a metal oxide.

A metal oxide has a lattice defect in some cases. Examples of the lattice defect include point defects such as an atomic vacancy and an exotic atom, linear defects such as transition, plane defects such as a grain boundary, and volume defects such as a cavity. Examples of a factor in generating a lattice defect include the deviation of the proportion of the number of atoms in constituent elements (excess or deficiency of constituent atoms) and an impurity.

When a metal oxide is used for a semiconductor layer of a transistor, a lattice defect in the metal oxide may cause generation, capture, or the like of a carrier. Thus, when a metal oxide with a large number of lattice defects is used for a semiconductor layer of a transistor, the electrical characteristics of the transistor may be unstable. Therefore, a metal oxide used for a semiconductor layer of a transistor preferably has a small number of lattice defects.

The kind of a lattice defect that is likely to be present in a metal oxide and the number of lattice defects vary depending on the structure of the metal oxide, a method for forming the metal oxide, or the like.

Therefore, a metal oxide with high crystallinity is preferably used for a semiconductor layer of a transistor. For example, a metal oxide having a CAAC structure or a metal oxide having a single crystal structure is preferably used. The use of the metal oxide for a transistor enables the transistor to have favorable electrical characteristics. In addition, the transistor can have high reliability.

For the channel formation region of a transistor, a metal oxide that can increase the on-state current of the transistor is preferably used. To increase the on-state current of the transistor, the mobility of the metal oxide used for the transistor is preferably increased. To increase the mobility of the metal oxide, the transfer of carriers (electrons in the case of an n-channel transistor) needs to be facilitated or scattering factors that affect the carrier transfer need to be reduced. Note that the carriers flow from the source to the drain through the channel formation region. Hence, the on-state current of the transistor can be increased by providing a channel formation region through which carriers can easily flow in the channel length direction.

### [Impurities in Oxide Semiconductor]

The influence of impurities in the oxide semiconductor will be described.

It is preferable that the channel formation region of the transistor including an oxide semiconductor in the semiconductor layer contain less oxygen vacancies or have a lower concentration of impurities such as hydrogen, nitrogen, or a metal element than the source region and the drain region. When oxygen vacancies (V_{O}) and impurities are in a channel formation region of an oxide semiconductor in a transistor, electrical characteristics of the transistor may easily vary and the reliability thereof may worsen. In some cases, hydrogen in the vicinity of oxygen vacancies forms V_{O}H and generates an electron serving as a carrier. Thus, if the channel formation region of the oxide semiconductor includes oxygen vacancies, the transistor tends to have normally-on characteristics. Therefore, V_{O}H in the channel formation region is also preferably reduced. Thus, the channel formation region of the transistor is a high-resistance region having a low carrier concentration. Accordingly, the channel formation region of the transistor can be regarded as an i-type (intrinsic) or substantially i-type region.

In order to obtain stable electrical characteristics of the transistor, reducing the impurity concentration in the oxide semiconductor is effective. Examples of the impurity include hydrogen, carbon, and nitrogen. Note that an impurity in an oxide semiconductor refers to, for example, elements other than the main components of the oxide semiconductor. For example, an element with a concentration of lower than 0.1 atomic % is an impurity.

When an oxide semiconductor contains silicon or carbon, which is a Group 14 element, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor including, as a semiconductor, an oxide semiconductor that contains nitrogen tends to have normally-on characteristics. When nitrogen is contained in the oxide semiconductor, a trap state is sometimes formed. This may make the electrical characteristics of the transistor unstable. Thus, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, still further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom generates an electron serving as a carrier. Thus, a transistor including an oxide semiconductor that contains hydrogen tends to have normally-on characteristics. For this reason, hydrogen in the channel formation region using the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, still further preferably lower than 1×10¹⁸ atoms/cm³, or yet still further preferably lower than 1×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the channel formation region of the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for a channel formation region in a transistor, the transistor can have stable electrical characteristics.

[c-Axis Alignment Proportion]

The oxide semiconductor layer of one embodiment of the present invention has a CAAC structure. The crystallinity degree of the oxide semiconductor layer of one embodiment of the present invention can be evaluated with the use of crystal orientation, for example.

The crystal orientation can be obtained from an FFT pattern obtained by performing FFT processing on a TEM image. Specifically, the directions of the crystal axes can be obtained using an FFT pattern. The FFT pattern obtained by the FFT processing reflects reciprocal lattice space information like an electron diffraction pattern.

When FFT processing is performed on each region in the TEM image of the oxide semiconductor layer, crystal orientation in each region can be obtained. For example, crystal orientation is obtained in each region in a certain area range, so that a map indicating crystal orientation can be formed. Specifically, two spots with high intensity are observed in the FFT pattern of the region including a layered crystal part. The direction of the crystal axis of the region can be obtained from the angle of the line segment connecting the two spots.

In the map showing crystal orientation, the proportion of regions having c-axis alignment is calculated to obtain a c-axis alignment proportion. Here, the region having c-axis alignment represents a region where the orientation is aligned with the c-axis and a region where a difference between the orientation and the c-axis is less than or equal to 20°.

In the oxide semiconductor layer of one embodiment of the present invention, the c-axis orientation rate can be calculated with use of, for example, cross-sectional or plan-view TEM observation of the oxide semiconductor layer. The region where the FFT is performed (also referred to as an FFT window) can be a circle with a diameter of 1.0 nm, for example. Note that the region where the FFT is performed is not limited to a circle.

In the oxide semiconductor layer of one embodiment of the present invention, the c-axis orientation rate is higher than or equal to 60%, preferably higher than or equal to 70%, further preferably higher than or equal to 80%, still further preferably higher than or equal to 90%, yet still further preferably higher than or equal to 95%.

Furthermore, the c-axis orientation rates of a deposition region of the oxide semiconductor 30a, a deposition region of the oxide semiconductor 30b, and a deposition region of the oxide semiconductor 30c are Rc1, Rc2, and Rc3, respectively. Rc2 is higher than or equal to 60%, preferably higher than or equal to 70%, further preferably higher than or equal to 80%, still further preferably higher than or equal to 90%, yet still further preferably higher than or equal to 95%. Furthermore, Rc3 is higher than or equal to 60%, preferably higher than or equal to 70%, further preferably higher than or equal to 80%, still further preferably higher than or equal to 90%, yet still further preferably higher than or equal to 95%. Rc3/Rcl is preferably greater than 1. In addition, Rc2/Rc1 is preferably greater than 1.

Note that after the formation of the oxide semiconductor 30, the boundaries between the oxide semiconductors 30a, 30b, and 30c are not clearly observed in some cases.

The oxide semiconductor 30 of one embodiment of the present invention can be divided into three regions: a first region, a second region, and a third region in this order from the top of the layer 29. Each of the regions is a layered region.

The first region, the second region, and the third region each have a CAAC structure. In addition, the c-axis orientation rate of the third region is preferably higher than that of the first region. The c-axis orientation rate of the second region is preferably higher than that of the first region. In addition, the c-axis orientation rate of the third region is 80% or higher, preferably 90% or higher, further preferably 95% or higher. The c-axis orientation rate of the second region is 80% or higher, preferably 90% or higher, further preferably 95% or higher.

The first region is positioned in a range of 0 nm to 3 nm, both inclusive, from the top surface of the layer 29, and the third region is positioned in a range of 0 nm to 3 nm, both inclusive, from the top surface of the oxide semiconductor 30.

Alternatively, the thicknesses of the layers in the regions are substantially equal, for example.

### [Method for Forming Metal Oxide by ALD Method]

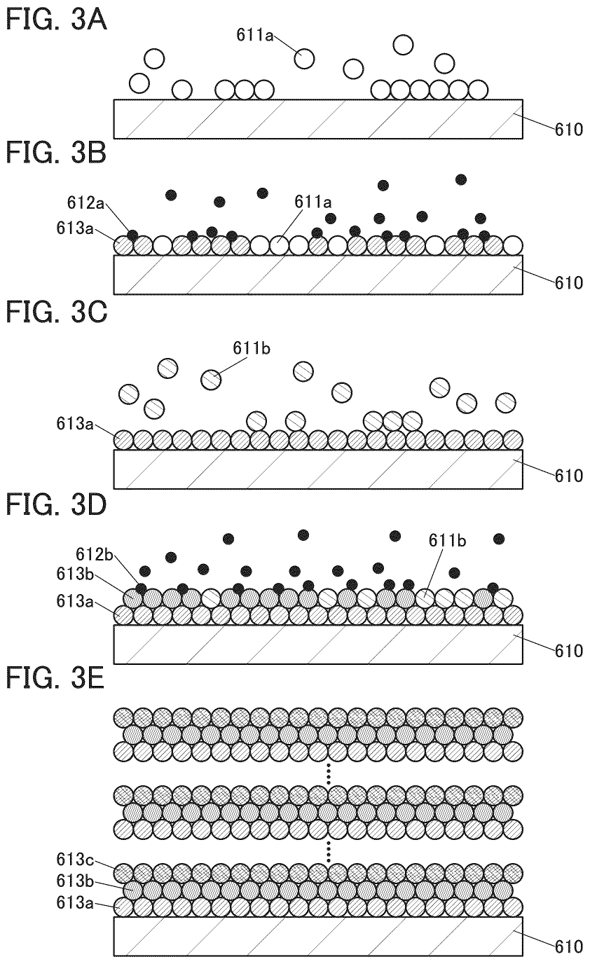

An example of a method employing an ALD method for forming a metal oxide having a layered crystal structure of three layers is described here with reference to FIGS. 3A to 3E. First, a precursor 611a is introduced into a chamber, and the precursor 611a is adsorbed on a surface of a substrate 610 (see FIG. 3A, this step is referred to as a first step in some cases). Here, as illustrated in FIG. 3A, the precursor 611a is adsorbed on the surface of the substrate 610, whereby a self-limiting mechanism of surface chemical reaction works and no more precursor 611a is adsorbed on a layer of the precursor 611a over the substrate 610. Note that the proper range of substrate temperatures at which the self-limiting mechanism of surface chemical reaction works is also referred to as an

ALD window. The ALD Window is determined by the temperature characteristics, vapor pressure, decomposition temperature, and the like of a precursor and is set to higher than or equal to 100° C. and lower than or equal to 600° C., preferably higher than or equal to 200° C. and lower than or equal to 400° C., for example, in some cases.

Next, an inert gas (e.g., argon, helium, or nitrogen) or the like is introduced into the chamber, so that excess precursors 611a, a reaction product, and the like are removed from the chamber (hereinafter, the step is referred to as a second step in some cases). Instead of introduction of an inert gas into the chamber, vacuum evacuation can be performed to remove excessive precursors, a reaction product, and the like from the chamber. The second step is also called purge.

Next, a reactant 612a (e.g., an oxidizer (ozone (O₃), oxygen (O₂), water (H₂O), and plasma, a radical, and an ion thereof)) is introduced into the chamber to react with the precursor 611a adsorbed on the surface of the substrate 610, whereby part of components contained in the precursor 611a is released while the component molecules of the precursor 611a are kept adsorbed on the substrate 610 (see FIG. 3B; hereinafter, the step is referred to as a third step in some cases). Consequently, a layer of an oxide 613a, which is formed by oxidation of part of the precursor 611a, is formed over the surface of the substrate 610.

After that, introduction of an inert gas or vacuum evacuation is performed, whereby the excessive reactant 612a, a reaction product, and the like are removed from the chamber (hereinafter, the step is referred to as a fourth step in some cases).

Then, a precursor 611b containing a metal element different from that in the precursor 611a is introduced and a step similar to the first step is performed, so that the precursor 611b is adsorbed on a surface of the layer of the oxide 613a (see FIG. 3C). Here, as illustrated in FIG. 3C, the precursor 611b is adsorbed on the layer of the oxide 613a, whereby a self-limiting mechanism of surface chemical reaction works and no more precursor 611b is adsorbed on a layer of the precursor 611b over the substrate 610.

Next, as in the second step, introduction of an inert gas or vacuum evacuation is performed so that the excess precursor 611b, a reaction product, and the like are removed from the chamber.

Next, as in the third step, the reactant 612b is introduced into the chamber. Here, the reactant 612b that is the same as or different from the reactant 612a may be used (see FIG. 3D). Thus, a layer of the oxide 613b, which is formed by oxidation of part of the precursor 611b, is formed over the layer of the oxide 613a.

After that, as in the fourth step, introduction of an inert gas or vacuum evacuation is performed so that the excess reactant 612b, a reaction product, and the like are removed from the chamber.

Furthermore, the first to fourth steps are performed in a similar manner, whereby a layer of an oxide 613c can be formed over the layer of the oxide 613b. As described above, by performing the steps for forming the oxides 613a to 613c repeatedly, a metal oxide having a layered crystal structure where a stacked-layer structure including the oxides 613a to 613c is repeated can be formed (see FIG. 3E). That is, an oxide layer can be formed through the first to fourth steps, which are regarded as one set, and by repeating the set, a layered crystal structure where a plurality of oxide layers are stacked can be formed.

Note that the thickness of the metal oxide having a layered crystal structure can be greater than or equal to 1 nm and less than 100 nm, preferably greater than or equal to 3 nm and less than 20 nm.

The steps illustrated in FIGS. 3A to 3E are preferably performed while the substrate is heated to form the metal oxide having a layered crystal structure. For example, the substrate temperature can be set higher than or equal to 200° C. and lower than or equal to 600° C., preferably higher than or equal to 300° C. and lower than or equal to the decomposition temperature of the precursor. In the case where deposition is performed by an ALD method with use of different kinds of precursors, the substrate temperature is preferably lower than or equal to the lowest precursor decomposition temperature among the precursors. Accordingly, during deposition by an ALD method, a plurality of kinds of precursors that are used can be adsorbed on an object (e.g., a substrate) without being decomposed.

By performing the deposition while the substrate is heated within such a temperature range, an impurity such as hydrogen or carbon contained in the precursor, the reactant, and the like can be removed from the metal oxide in each of the first to fourth steps. For example, carbon in the metal oxide can be released as CO₂ and CO, and hydrogen in the metal oxide can be released as H₂O. Furthermore, metal atoms and oxygen atoms are rearranged concurrently with removal of the impurity, so that layers of oxides can be arranged orderly. Thus, a metal oxide having a layered crystal structure with high crystallinity can be formed.

In order to perform deposition while the substrate is heated within the above temperature range, the decomposition temperature of the precursor used for the deposition is preferably high. For example, the precursor decomposition temperature is preferably higher than or equal to 200° C. and lower than or equal to 700° C., further preferably higher than or equal to 300° C. and lower than or equal to 600° C. As such a precursor having a high decomposition temperature, a precursor formed of an inorganic material (hereinafter, referred to as an inorganic precursor) is preferably used. In general, an inorganic precursor tends to have a higher decomposition temperature than a precursor formed of an organic material (hereinafter, referred to as an organic precursor); thus, some inorganic precursors have the ALD Window in the above temperature range. Moreover, an inorganic precursor does not contain an impurity such as hydrogen or carbon, which can prevent an increase in the concentration of an impurity such as hydrogen or carbon in a metal oxide to be deposited.

After the metal oxide film is formed, heat treatment is preferably performed. In particular, the heat treatment is preferably performed without exposure to the air successively after the deposition by an ALD method. The heat treatment can be performed under the conditions described with reference to FIGS. 1A to 1D, for example.

By performing the heat treatment in such a manner, an impurity such as hydrogen or carbon contained in the metal oxide can be removed. For example, carbon in the metal oxide can be released as CO₂ and CO, and hydrogen in the metal oxide can be released as H₂O. Furthermore, metal atoms and oxygen atoms are rearranged concurrently with removal of the impurity, which improves crystallinity. Thus, a metal oxide having a layered crystal structure with high crystallinity can be formed.

After the deposition of the metal oxide, microwave treatment is preferably performed in an oxygen-containing atmosphere so that the impurity concentration in the metal oxide can be reduced. Specific examples of the impurity include hydrogen and carbon. Although the microwave treatment in an oxygen-containing atmosphere is performed on the metal oxide in the above example, one embodiment of the present invention is not limited thereto. For example, the microwave treatment in an oxygen-containing atmosphere may be performed on an insulating film, more specifically a silicon oxide film, which is positioned in the vicinity of the metal oxide.

Note that FIGS. 3A to 3E illustrate the structure where the stacked-layer structure including the oxides 613a to 613c is repeated; however, the present invention is not limited to the structure. For example, a single layer, two layers, or four or more layers of an oxide may be repeatedly formed in a metal oxide.

In the following description of this specification and the like, in the case of using ozone, oxygen, and water as a reactant or an oxidizer, they include not only those in gas or molecular states but also those in a plasma, radical, and ion states, unless otherwise specified. In the case where a film is formed using an oxidizer in a plasma state, a radical state, or an ion state, a plasma ALD apparatus, which will be described later, is used.

In order to remove an impurity such as carbon or hydrogen contained in a precursor, the precursor is preferably made to react with an oxidizer sufficiently. For example, pulse time for introducing an oxidizer can be elongated. Alternatively, an oxidizer can be introduced a plurality of times. In the case where an oxidizer is introduced a plurality of times, the same kind of oxidizer may be introduced or different kinds of oxidizers may be introduced. For example, water may be introduced as a first oxidizer into a chamber, vacuum evacuation may be performed, ozone or oxygen that does not contain hydrogen may be introduced as a second oxidizer into the chamber, and vacuum evacuation may be performed.

As described above, the introduction of an oxidizer and the introduction of an inert gas (or vacuum evacuation) in the chamber are repeated a plurality of times in a short time, whereby excess hydrogen atoms, carbon atoms, chlorine atoms, and the like can be more certainly removed from the precursor adsorbed on the substrate surface and eliminated from the chamber. In the case where two kinds of oxidizers are introduced, more excess hydrogen atoms and the like can be removed from the precursor adsorbed on the substrate surface. In this manner, hydrogen atoms are prevented from entering the film during the deposition, so that the amounts of water, hydrogen, and the like in the formed film can be reduced.

In an ALD method, a film is formed through reaction between a precursor and a reactant using thermal energy. A temperature required for the reaction between the precursor and the reactant is determined by the temperature characteristics, vapor pressure, decomposition temperature, and the like thereof and is set to higher than or equal to 100° C. and lower than or equal to 600° C., preferably higher than or equal to 200° C. and lower than or equal to 600° C., further preferably higher than or equal to 300° C. and lower than or equal to 600° C.

Moreover, an ALD method in which deposition is performed by introducing a plasma-excited reactant into the chamber as a third source gas in addition to the reaction between the precursor and the reactant is referred to as a plasma ALD method in some cases. In this case, a plasma generation apparatus is provided in the introduction portion of the third source gas. Inductively coupled plasma (ICP) can be used for plasma generation. An ALD method in which reaction between the precursor and the reactant is performed using thermal energy is sometimes called a thermal ALD method.

In a plasma ALD method, deposition is performed by introducing a plasma-excited reactant in the third step. Alternatively, deposition is performed as follows: the first to fourth steps are repeated while a plasma-excited reactant (a second reactant) is introduced, in which case the reactant introduced in the third step is referred to as a first reactant. In the plasma ALD method, a material similar to the above-described oxidizer can be used for the second reactant used as the third source gas. In other words, plasma-excited ozone, oxygen, and water can be used as the second reactant. Other than oxidizer, a nitriding agent may be used as the second reactant. As the nitriding agent, nitrogen (N₂) or ammonia (NH₃) can be used. A mixed gas of nitrogen (N₂) and hydrogen (H₂) can also be used as the nitriding agent. For example, a mixed gas of nitrogen (N₂) of 5% and hydrogen (H₂) of 95% can be used as the nitriding agent. Deposition is performed while plasma-excited nitrogen or ammonia is introduced, whereby a nitride film such as a metal nitride film can be formed.

Argon (Ar), helium (He), or nitrogen (N₂) may be used as a carrier gas for the second reactant. The use of a carrier gas such as argon, helium, or nitrogen is preferable because plasma is easily discharged and the plasma-excited second reactant is easily generated. Note that in the case where an oxide film such as a metal oxide film is formed by a plasma ALD method and nitrogen is used as a carrier gas, nitrogen enters the film and a desired film quality cannot be obtained in some cases. In this case, argon or helium is preferably used as the carrier gas.

With the ALD method, an extremely thin film with a uniform thickness can be formed. In addition, the coverage of an uneven surface with the film is high.

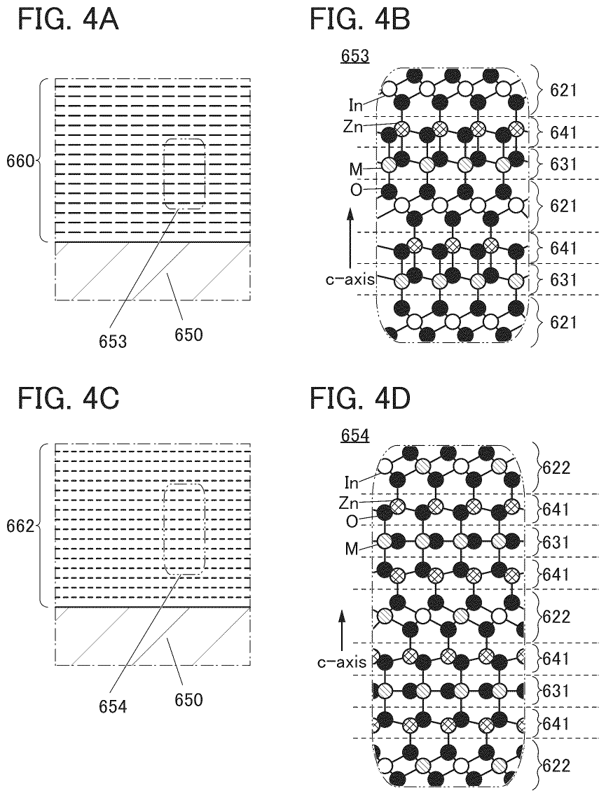

Here, atomic arrangement in the crystal when the metal oxide having a layered crystal structure is an In-M-Zn oxide is described with reference to FIGS. 4A to 4D. In FIGS. 4B and 4D, an atom is represented by a sphere (a circle) and a bond between a metal atom and an oxygen atom is represented by a line. In FIGS. 4B and 4D, the c-axis direction in the crystal structure of the In-M-Zn oxide is indicated by arrows in the drawings. The a-b plane direction in the crystal structure of the In-M-Zn oxide is the direction perpendicular to the c-axis direction indicated by the arrows in FIGS. 4B and 4D

FIG. 4A illustrates an oxide 660 including an In-M-Zn oxide formed over a structure body 650. Here, the structure body refers to a component included in a semiconductor device such as a transistor. The structure body 650 includes a substrate, conductors such as a gate electrode, a source electrode, and a drain electrode, an insulator such as a gate insulating film, an interlayer insulating film, and a base insulating film, a semiconductor such as a metal oxide or silicon, and the like. In FIG. 4A, a formation surface of the structure body 650 is positioned parallel to a substrate (or a base not illustrated in the drawing).

FIG. 4B is an enlarged view illustrating the atomic arrangement in the crystal in a region 653, which is part of the oxide 660 in FIG. 4A. Note that the oxide 660 illustrated in FIGS. 4A and 4B has a composition of In:M:Zn=1:1:1 [atomic ratio] and a YbFe₂O₄ crystal structure. The element M is a metal element having a valence of +3.

As illustrated in FIG. 4B, the crystal included in the oxide 660 has repetitive stacking of a layer 621 containing indium (In) and oxygen, a layer 631 containing the element M and oxygen, and a layer 641 containing zinc (Zn) and oxygen in this order. The layers 621, 631, and 641 are placed in parallel or substantially in parallel with the formation surface of the structure body 650. That is, the a-b plane of the oxide 660 is substantially parallel to the formation surface of the structure body 650, and the c-axis of the oxide 660 is substantially parallel to the normal direction of the formation surface of the structure body 650.

When the layers 621, 631, and 641 included in the above crystal are each composed of one metal element and oxygen as illustrated in FIG. 4B, arrangement with favorable crystallinity is achieved to increase the mobility of the metal oxide.

Note that the In-M-Zn oxide with an atomic ratio of In:M:Zn=1:1:1 is not limited to having the structure illustrated in FIG. 4B. The stacking order of the layers 621, 631, and 641 may be changed. For example, the layers may be stacked repeatedly in the order of the layers 621, 641, and 631. Alternatively, the layers may be stacked repeatedly in the order of the layers 621, 631, 641, 621, 641, and 631. Part of the element M in the layer 631 may be replaced with zinc and part of zinc in the layer 641 may be replaced with the element M.

Although an example of forming the In-M-Zn oxide with an atomic ratio of In:M:Zn=1:1:1 is described above, a crystalline In-M-Zn oxide whose composition formula is represented by In_{(1+α)}M_{(1-α)}O₃(ZnO)ₘ (α is a real number greater than 0 and less than 1 and m is a positive number) can have a layered crystal structure in a similar manner. As an example, an In-M-Zn oxide with an atomic ratio of In:M:Zn=1:3:4 is described with reference to FIGS. 4C and 4D.

FIG. 4C illustrates an oxide 662 including an In-M-Zn oxide formed over the structure body 650. FIG. 4D is an enlarged view illustrating the atomic arrangement in the crystal in a region 654, which is part of the oxide 662 in FIG. 4C.

As illustrated in FIG. 4D, the crystal included in the oxide 662 includes a layer 622 containing indium (In), the element M, and oxygen, the layer 641 containing zinc (Zn) and oxygen, and the layer 631 containing the element M and oxygen. In the oxide 662, the plurality of layers are stacked repeatedly in the order of the layers 622, 641, 631, and 641. The layers 622, 631, and 641 are placed substantially in parallel with the formation surface of the structure body 650. That is, the a-b plane of the oxide 662 is substantially parallel to the formation surface of the structure body 650, and the c-axis of the oxide 662 is substantially parallel to the normal direction of the formation surface of the structure body 650.

Note that the In-M-Zn oxide with an atomic ratio of In:M:Zn=1:3:4 is not limited to having the structure illustrated in FIG. 4D, and the structure may change within a range where the atomic ratio of In:M:Zn=1:3:4 is maintained. For example, the stacking order of the layers 622, 631, and 641 may be changed. Part of the element M in the layer 631 may be replaced with zinc and part of zinc in the layer 641 may be replaced with the element M. The layer 621 or the layer 631 may be formed instead of the layer 622.

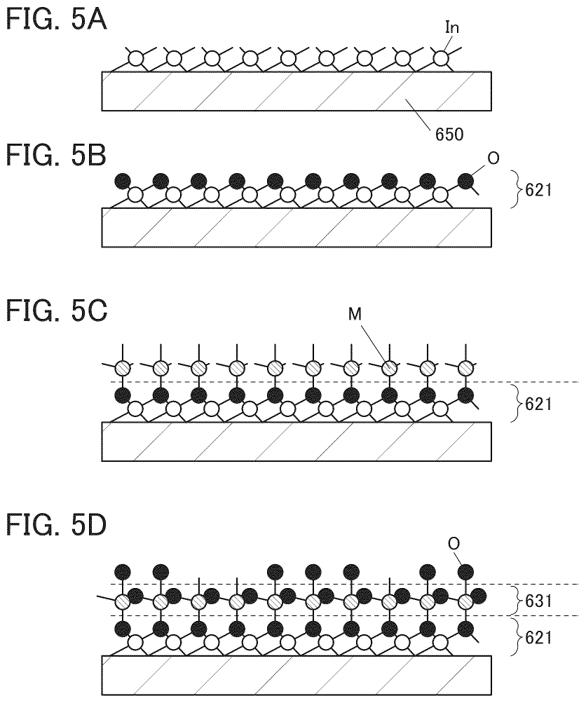

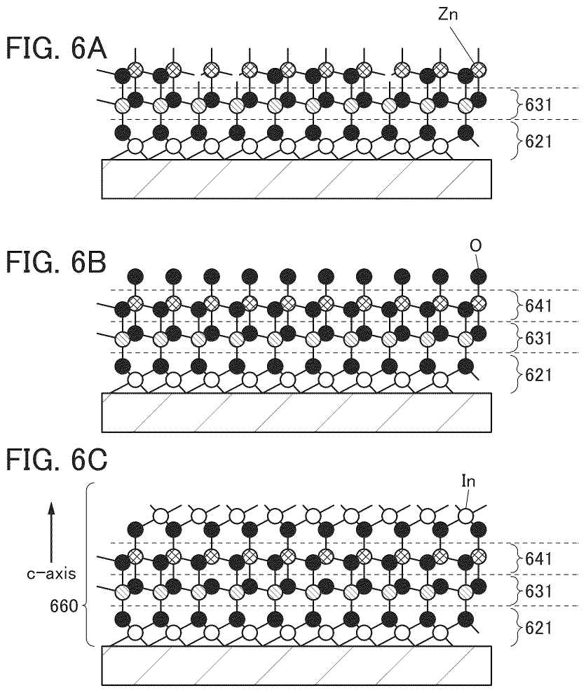

Next, details of a method for forming the oxide 660 including the In-M-Zn oxide illustrated in FIGS. 4A and 4B are described with reference to FIGS. 5A to 5D and FIGS. 6A to 6C.

First, a source gas containing a precursor containing indium is introduced into a chamber so that the precursor is adsorbed on the surface of the structure body 650 (see FIG. 5A). Here, the source gas contains a carrier gas such as argon, helium, or nitrogen in addition to the precursor. As the precursor containing indium, trimethylindium, triethylindium, tris(2,2,6,6-tetramethyl-3,5-heptanedionato)indium, cyclopentadienylindium, indium (III) acetylacetonate, (3-(dimethylamino) propyl)dimethylindium, or the like can be used.

As the precursor containing indium, an inorganic precursor not containing hydrocarbon may be used. As the inorganic precursor containing indium, a halogen-based indium compound such as indium trichloride, indium tribromide, or indium triiodide can be used. The decomposition temperature of indium trichloride is approximately 500° C. to 700° C. Thus, with use of indium trichloride, deposition can be performed by an ALD method while a substrate is being heated at approximately 400° C. to 600° C., for example, at 500° C.

Next, introduction of the source gas is stopped and the chamber is purged so that an excess precursor, a reaction product, and the like are removed from the chamber.

Then, an oxidizer is introduced as a reactant into the chamber to react with the adsorbed precursor, and components other than indium are released while indium is adsorbed on the substrate, whereby the layer 621 in which indium and oxygen are bonded to each other is formed (see FIG. 5B). Ozone, oxygen, water, or the like can be used as the oxidizer. After that, introduction of the oxidizer is stopped and the chamber is purged so that an excess reactant, a reaction product, and the like are removed from the chamber.

Subsequently, a source gas containing a precursor containing the element M is introduced into the chamber so that the precursor is adsorbed on the layer 621 (see FIG. 5C). Here, the source gas contains a carrier gas such as argon, helium, or nitrogen in addition to the precursor. When gallium is used as the element M, as the precursor containing gallium, trimethylgallium, triethylgallium, tris(dimethylamide)gallium (III), gallium (III) acetylacetonate, tris(2,2,6,6-tetramethyl-3,5-heptanedionato)gallium, dimethylchlorogallium, diethylchlorogallium, dimethylgallium isopropoxide, or the like can be used.

As the precursor containing gallium, an inorganic precursor not containing hydrocarbon may be used. As the inorganic precursor containing gallium, a halogen-based gallium compound such as gallium trichloride, gallium tribromide, or gallium triiodide can be used. The decomposition temperature of gallium trichloride is approximately 550° C. to 700° C. Thus, with use of gallium trichloride, deposition can be performed by an ALD method while a substrate is being heated at approximately 450° C. to 650° C., for example, at 550° C.

Next, introduction of the source gas is stopped and the chamber is purged so that an excess precursor, a reaction product, and the like are removed from the chamber.

Then, an oxidizer is introduced as a reactant into the chamber to react with the adsorbed precursor, and components other than the element M are released while the element M is adsorbed on the substrate, whereby the layer 631 in which the element M and oxygen are bonded to each other is formed (see FIG. 5D). At this time, part of oxygen contained in the layer 641 is adsorbed on the layer 631 in some cases. After that, introduction of the oxidizer is stopped and the chamber is purged so that an excess reactant, a reaction product, and the like are removed from the chamber.

Subsequently, a source gas containing a precursor containing zinc is introduced into the chamber so that the precursor is adsorbed on the layer 631 (see FIG. 6A). At this time, part of the layer 641 in which zinc is bonded to oxygen is formed in some cases. Here, the source gas contains a carrier gas such as argon, helium, or nitrogen in addition to the precursor. As the precursor containing zinc, dimethylzinc, diethylzinc, bis(2,2,6,6-tetramethyl-3,5-heptanedionato)zinc, zinc acetate, or the like can be used.

As the precursor containing zinc, an inorganic precursor not containing hydrocarbon may be used. As the precursor containing zinc, a halogen-based zinc compound such as zinc dichloride, zinc dibromide, or zinc diiodide can be used. The decomposition temperature of zinc dichloride is approximately 450° C. to 700° C. Thus, with use of zinc dichloride, deposition can be performed by an ALD method while a substrate is being heated at approximately 350° C. to 550° C., for example, at 450° C.

Next, introduction of the source gas is stopped and the chamber is purged so that an excess precursor, a reaction product, and the like are removed from the chamber.

Then, an oxidizer is introduced as a reactant into the chamber to react with the adsorbed precursor, and components other than zinc are released while zinc is adsorbed on the substrate, whereby the layer 641 in which zinc and oxygen are bonded to each other is formed (see FIG. 6B). After that, introduction of the oxidizer is stopped and the chamber is purged so that an excess reactant, a reaction product, and the like are removed from the chamber.

Next, the layer 621 is formed again over the layer 641 by the above-described method (see FIG. 6C). By repeating the above-described method, the oxide 660 can be formed over the substrate or the structure body.

Some of the above-described precursors containing the metal elements further contain one or both of carbon and chlorine. A film formed using a precursor containing carbon may contain carbon. A film formed using a precursor containing halogen such as chlorine may contain halogen such as chlorine.

As described above, the oxide 660 is formed by an ALD method, whereby the metal oxide in which the c-axis is aligned substantially parallel to the normal direction of the formation surface can be obtained. With this structure, the layered crystals of the oxide semiconductor 30 are formed substantially in parallel with the channel length direction of the transistor 200, so that the on-state current of the transistor can be increased.

The steps illustrated in FIGS. 5A to 5D and FIGS. 6A to 6C are preferably performed while the substrate is being heated. For example, the substrate temperature can be set higher than or equal to 200° C. and lower than or equal to 600° C., preferably higher than or equal to 300° C. and lower than or equal to the decomposition temperature of the precursor.

In order to perform deposition while the substrate is heated within the above temperature range, the decomposition temperature of a precursor used for the deposition is preferably high. For example, the precursor decomposition temperature is preferably higher than or equal to 200° C. and lower than or equal to 700° C., further preferably higher than or equal to 300° C. and lower than or equal to 600° C. As such a precursor having a high decomposition temperature, an inorganic precursor is preferably used. In general, an inorganic precursor tends to have a higher decomposition temperature than an organic precursor. Thus, even when deposition is performed while the substrate is being heated as described above, the precursor is hardly decomposed.

As the inorganic precursor, for example, indium trichloride, gallium trichloride, or zinc dichloride described above can be used. As described above, the decomposition temperature of each of these precursors is approximately 350° C. to 700° C., which is much higher than the decomposition temperature of a common organic precursor. Note that as described above, the decomposition temperatures of indium trichloride, gallium trichloride, and zinc dichloride are different from each other. In the case where deposition is performed by an ALD method with use of different kinds of precursors, the substrate temperature is preferably lower than or equal to the lowest precursor decomposition temperature among the precursors. In the above example, the substrate temperature can be set within a range where zinc dichloride having the lowest precursor decomposition temperature is not decomposed. Accordingly, indium trichloride and gallium trichloride can also be adsorbed on an object (e.g., a substrate) without being decomposed.

Note that FIGS. 5A to 5D and FIGS. 6A to 6C illustrate an example where the layer 621 is formed as a layer containing indium, the layer 631 is formed thereover as a layer containing the element M, and further the layer 641 is formed thereover as a layer containing zinc; however, this embodiment is not limited to the example. One of the layers 631 and 641 may be formed, the layer 621 may be formed thereover, and further the other of the layers 631 and 641 may be formed thereover. Alternatively, one of the layers 631 and 641 may be formed, the other of the layers 631 and 641 may be formed thereover, and further the layer 621 may be formed thereover.

In the case of forming a metal oxide with an atomic ratio that is different from In:M:Zn=1:1:1, the layers 621, 631, and 641 can be formed as appropriate in accordance with the atomic ratio. For example, the formation of the layer 641 is repeated a plurality of times before and after the formation of the layer 631 illustrated in FIG. 6A so that a stack including the layer 631 and the layers 641 and having the desired number of atoms and layers and a desired thickness is formed between two layers 621.

This embodiment can be combined with any of the other embodiments as appropriate. In this specification, in the case where a plurality of structure examples are shown in one embodiment, the structure examples can be combined as appropriate.

### Embodiment 2

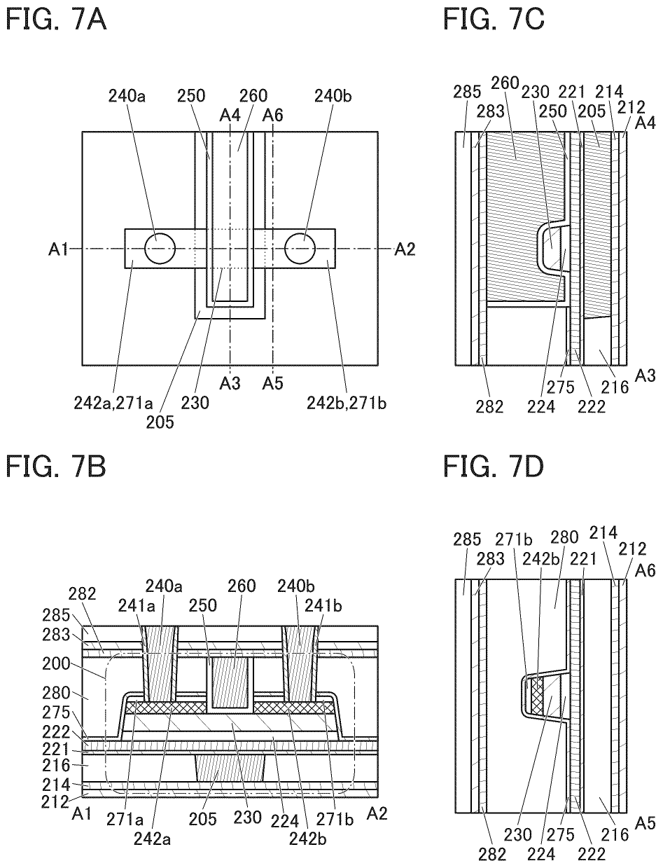

In this embodiment, a semiconductor device including an oxide semiconductor described in Embodiment 1 and a method of manufacturing the semiconductor device will be described with reference to FIGS. 7A to 7D to FIGS. 19A to 19D.

### <Structure Example of Semiconductor Device>

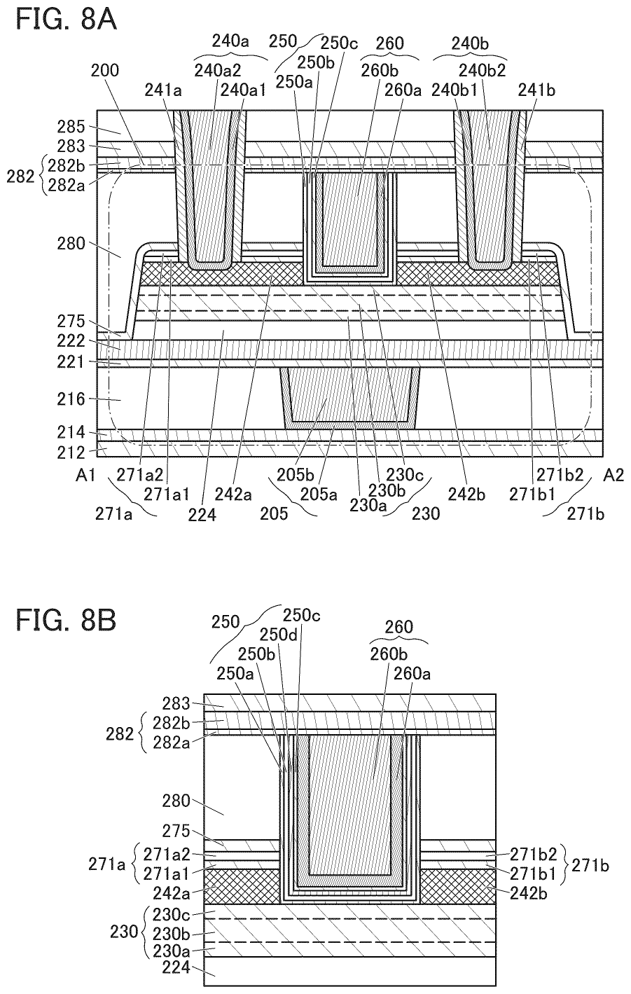

An example of a structure of a semiconductor device is described with reference to FIGS. 7A to 7D and FIGS. 8A and 8B. FIGS. 7A to 7D are a plan view and cross-sectional views of a semiconductor device (transistor 200). FIG. 7A is a plan view of the semiconductor device. FIGS. 7B to 7D are the cross-sectional views of the semiconductor device. FIG. 7B is a cross-sectional view taken along dashed-dotted line A1-A2 in FIG. 7A, which corresponds to a cross-sectional view in the channel length direction of the transistor 200. FIG. 7C is a cross-sectional view taken along dashed-dotted line A3-A4 in FIG. 7A, which corresponds to a cross-sectional view in the channel width direction of the transistor 200. FIG. 7D is a cross-sectional view taken along the dashed-dotted line A5-A6 in FIG. 7A, which corresponds to a cross-sectional view of the transistor 200 in the channel width direction. Note that some components are not illustrated in the plan view of FIG. 7A for clarity of the drawing. FIGS. 8A and 8B are enlarged cross-sectional views of the transistor 200 in the channel length direction.

The transistor 200 includes a conductor 205 embedded in an insulator 216, an insulator 221 over the insulator 216 and the conductor 205, an insulator 222 over the insulator 221, an insulator 224 over the insulator 222, an oxide semiconductor 230 over the insulator 224, conductors 242a and 242b over the oxide semiconductor 230, an insulator 271a over the conductor 242a, an insulator 271b over the conductor 242b, an insulator 250 over the oxide semiconductor 230, and a conductor 260 over the insulator 250.

The oxide semiconductor 230 includes a region that functions as a channel formation region of the transistor 200. The conductor 260 includes a region that functions as a first gate electrode (also referred to as an upper gate electrode or a top gate electrode) of the transistor 200. The insulator 250 includes a region that functions as a first gate insulator of the transistor 200. The conductor 205 includes a region that functions as a second gate electrode (also referred to as a lower gate electrode or a bottom gate electrode) of the transistor 200. Each of the insulators 224, 222, and 221 includes a region that functions as a second gate insulator of the transistor 200. The conductor 242a includes a region that functions as one of a source electrode and a drain electrode of the transistor 200. The conductor 242b includes a region that functions as the other of the source electrode and the drain electrode of the transistor 200.

An insulator 275 is provided over the insulators 271a and 271b, and an insulator 280 is provided over the insulator 275. An opening reaching the insulator 222 and the oxide semiconductor 230 is formed in the insulators 280 and 275, and the opening overlaps with a region between the conductor 242a and the conductor 242b. The insulator 250 and the conductor 260 are provided in the opening formed in the insulators 280 and 275. An insulator 282 is provided in contact with the top surface of the insulator 280, the upper end portion of the insulator 250, and the top surface of the conductor 260. An insulator 283 is provided over the insulator 282. An insulator 214 is provided under the insulator 216 and the conductor 205. An insulator 212 is provided under the insulator 214. The insulators 212, 214, 280, 282, 283, and 285 each function as an interlayer insulating film.

An opening reaching the conductor 242a is formed in the insulators 285, 283, 282, 280, 275, and 271a, and a conductor 240a and an insulator 241a are provided in the opening. The insulator 241a is provided in contact with a sidewall of the opening, and the conductor 240a is provided inward from the insulator 241a. An opening reaching the conductor 242b is formed in the insulators 285, 283, 282, 280, 275, and 271b, and the conductor 240b and the insulator 241b are provided in the opening. The insulator 241b is provided in contact with a sidewall of the opening, and the conductor 240b is provided inward from the insulator 241b. The conductors 240a and 240b function as vias that connect a wiring or the like provided over the transistor 200 to a source or a drain of the transistor 200.

Here, the oxide semiconductor 230 corresponds to the oxide semiconductor 30 described in Embodiment 1, and the insulator 224 corresponds to the layer 29 described in Embodiment 1. Therefore, the description in Embodiment 1 can be referred to for the details of the oxide semiconductor 230 and the insulator 224. With the use of the oxide semiconductor 230, which is an Axial Growth CAAC, in the channel formation region of the transistor 200 in this manner, the transistor can have favorable on-state current, field-effect mobility, S-value, frequency characteristics, and reliability.

As illustrated in FIG. 8A, the oxide semiconductor 230 can include an oxide semiconductor 230a over the insulator 224, an oxide semiconductor 230b over the oxide semiconductor 230a, and an oxide semiconductor 230c over the oxide semiconductor 230b. Here, the oxide semiconductors 230a, 230b, and 230c correspond to the oxide semiconductors 30a, 30b, and 30c described in Embodiment 1, respectively. Therefore, the description in Embodiment 1 can be referred to for the details of the oxide semiconductors 230a to 230c.

In the oxide semiconductor 230, a channel formation region and source and drain regions of the transistor 200 are formed. The channel formation region is sandwiched between the source and drain regions. At least a part of the channel formation region overlaps with the conductor 260. The source region overlaps with the conductor 242a, and the drain region overlaps with the conductor 242b. Note that the source region and the drain region can be interchanged with each other.

The channel formation region has a smaller amount of oxygen vacancies or a lower impurity concentration than the source and drain regions, and thus has a low carrier concentration and a high resistance. Thus, the channel formation region can be regarded as an i-type (intrinsic) or substantially i-type region.

The source and drain regions have a large amount of oxygen vacancies or a high concentration of impurities such as hydrogen, nitrogen, or a metal element, and thus are low-resistance regions with a high carrier concentration. In other words, the source and drain regions are n-type regions (low-resistance regions) having a higher carrier concentration than the channel formation region.

Note that the carrier concentration in the channel formation region is preferably lower than or equal to 1×10¹⁸ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration of the channel formation region is not particularly limited and can be, for example, 1× 10⁻⁹ cm⁻³.

In order to reduce the carrier concentration of the oxide semiconductor 230, the impurity concentration in the oxide semiconductor 230 is reduced so that the density of defect states is reduced. In this specification and the like, a state with a low impurity concentration and a low density of defect states is referred to as a highly purified intrinsic or substantially highly purified intrinsic state. Note that an oxide semiconductor (or metal oxide) having a low carrier concentration may be referred to as a highly purified intrinsic or substantially highly purified intrinsic oxide semiconductor (or metal oxide).

To obtain stable electrical characteristics of the transistor 200, it is effective to reduce the concentration of impurities in the channel formation region of the oxide semiconductor 230. In order to reduce the concentration of impurities in the oxide semiconductor 230, the concentration of impurities in a film adjacent to the oxide semiconductor 230 is preferably reduced. Examples of impurities include hydrogen, nitrogen, an alkali metal, an alkaline earth metal, iron, nickel, and silicon. Note that an impurity in an oxide semiconductor 230 refers to, for example, elements other than the main components of the oxide semiconductor 230. For example, an element with a concentration lower than 0.1 atomic % is regarded as an impurity.

In the oxide semiconductor 230, it is sometimes difficult to clearly observe the boundaries between the regions. The concentration of a metal element and an impurity element such as hydrogen or nitrogen, which is detected in each region, may be not only gradually changed between the regions but also continuously changed in each region. That is, the region closer to the channel formation region may have a lower concentration of a metal element and an impurity element such as hydrogen or nitrogen.

If impurities and oxygen vacancies are present in a channel formation region of an oxide semiconductor, a transistor including the oxide semiconductor may have variable electrical characteristics and poor reliability. In some cases, hydrogen in the vicinity of an oxygen vacancy forms a defect that is an oxygen vacancy into which hydrogen enters (hereinafter sometimes referred to as V_{O}H), which generates an electron serving as a carrier. Therefore, when the channel formation region in the oxide semiconductor includes oxygen vacancies, the transistor tends to have normally-on characteristics (the channel is generated even when no voltage is applied to the gate electrode, and current flows through the transistor). Therefore, the impurities, oxygen vacancies, and V_{O}H are preferably reduced as much as possible in the channel formation region in the oxide semiconductor. In other words, the channel formation region in the oxide semiconductor is an i-type (intrinsic) or substantially i-type region with a reduced carrier concentration.

By contrast, when an insulator containing oxygen that is released by heating (hereinafter sometimes referred to as excess oxygen) is provided in the vicinity of the oxide semiconductor and heat treatment is performed, oxygen can be supplied from the insulator to the oxide semiconductor so as to reduce oxygen vacancies and V_{O}H. Note that too much oxygen supplied to the source region or the drain region is likely to cause a decrease in the on-state current or the field-effect mobility of the transistor 200. Furthermore, a variation in the amount of oxygen supplied to the source region or the drain region on the substrate plane leads to variable characteristics of the semiconductor device including the transistor. Furthermore, an excessive amount of oxygen supplied from the insulator to the oxide semiconductor adversely affects the electrical characteristics and reliability of the transistor in some cases. Furthermore, oxygen is diffused into a conductor such as a gate electrode, a source electrode, or a drain electrode to oxidize the conductor, which might impair the conductivity.

First, an insulator having a barrier property against hydrogen is preferably formed in the vicinity of the transistor 200 to reduce VOH in the channel formation region of the oxide semiconductor 230 and the vicinity thereof.

At least one of the insulators 212, 214, 221, 222, 275, 282, and 283 preferably functions as a barrier insulator against hydrogen. At least one of the insulators 212, 214, 221, 222, 275, 282, and 283 preferably functions as a barrier insulator against impurities. At least one of the insulators 212, 214, 221, 222, 275, 282, and 283 preferably functions as a barrier insulator against oxygen. Note that not all of the insulators 212, 214, 221, 222, 275, 282, and 283 need to be provided. If the barrier property against hydrogen, impurities, oxygen, and the like is sufficient, any of the insulators 212, 214, 221, 222, 275, 282, and 283 can be selected as appropriate. For example, a structure may be employed in which the insulator 214 is not provided and the insulator 216 and the conductor 205 are formed over and in contact with the top surface of the insulator 212.

Note that in this specification and the like, a barrier insulator refers to an insulator having a barrier property. In this specification and the like, having a barrier property refers to having a property that does not easily allow diffusion of a target substance (also referred to as a property that does not easily allow passage of a target substance, a property with low permeability of a target substance, or a function of inhibiting diffusion of a target substance). As another example, having a barrier property has a function of capturing or fixing (also referred to as gettering) a target substance in the insulator. Note that hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule.

As the insulator having a function of inhibiting diffusion of hydrogen, silicon nitride or silicon nitride oxide is preferably used, for example. For another example, aluminum oxide, magnesium oxide, hafnium oxide, zirconium oxide, an oxide containing aluminum and hafnium (hafnium aluminate), an oxide containing hafnium and zirconium (hafnium zirconium oxide), gallium oxide, indium gallium zinc oxide, or the like can be used in some cases.

Insulators having a function of inhibiting diffusion of hydrogen are preferably used as the insulators 212, 221, 275, and 283. For example, silicon nitride or the like, which has a higher hydrogen barrier property, may be used for the insulators 212, 221, 275, and 283.

Preferred examples of a material for an insulator having a function of capturing or fixing hydrogen include metal oxides such as an oxide containing hafnium, an oxide containing aluminum, an oxide containing aluminum and hafnium (hafnium aluminate), and a metal oxide such as magnesium oxide. The insulator having a function of capturing or fixing hydrogen preferably has an amorphous structure. In such a metal oxide having an amorphous structure, an oxygen atom has a dangling bond with which hydrogen is trapped or fixed in some cases. In other words, the metal oxide having an amorphous structure has high capability of capturing or fixing hydrogen. When silicon is added to the above metal oxide, the metal oxide is inhibited from being polycrystallized and easily becomes amorphous. Thus, such a metal oxide to which silicon is added (e.g., hafnium silicate or aluminum silicate) is preferably used.

For example, an insulator having a function of capturing or fixing hydrogen is preferably used as the insulators 214, 222, and 282. For example, aluminum oxide is preferably used for the insulators 214 and 282. For example, for the insulator 222 functioning as the second gate insulator, hafnium oxide, which is a high permittivity (high-k) material, is preferably used.

Such inorganic insulators exemplified as an insulator having a function of inhibiting diffusion of hydrogen and an insulator having a function of capturing or fixing hydrogen also have a barrier property against oxygen.

As illustrated in FIG. 8A, the insulator 212 having a function of inhibiting diffusion of hydrogen and the insulator 214 having a function of capturing or fixing hydrogen are preferably provided under the transistor 200. When the insulator 212 is provided under the transistor 200, diffusion of hydrogen from a layer below the transistor 200 can be inhibited. When the insulator 214 is provided over the insulator 212, hydrogen contained in the insulator 216 or the like can be captured or fixed by the insulator 214. This reduces the hydrogen concentration in the oxide semiconductor 230 and in the vicinity thereof.

As illustrated in FIG. 8A, the insulator 221 having a function of inhibiting diffusion of hydrogen and the insulator 222 having a function of capturing or fixing hydrogen are preferably provided in a lower portion of the transistor 200. When the insulator 221 is provided in the lower portion of the transistor 200, diffusion of hydrogen from a lower layer in the transistor 200 can be inhibited. When the insulator 222 is provided over the insulator 221, hydrogen contained in the insulator 224 or the like can be captured or fixed by the insulator 222. This reduces the hydrogen concentration in the oxide semiconductor 230 and in the vicinity thereof.

As illustrated in FIG. 8A, the insulator 275 is preferably provided to cover the oxide semiconductor 230, the conductors 242a and 242b, and the like. Providing the insulator 275 can inhibit diffusion of hydrogen from the insulator 280 into the oxide semiconductor 230, the conductors 242a and 242b, and the like.

As illustrated in FIG. 8A, the insulator 282 having a function of capturing or fixing hydrogen and the insulator 283 having a function of inhibiting diffusion of hydrogen are preferably provided over the transistor 200. Providing the insulator 283 over the transistor 200 can inhibit diffusion of hydrogen from a layer above the transistor 200. When the insulator 282 is provided under the insulator 283, hydrogen contained in the insulator 280 or the like can be captured or fixed by the insulator 282. This reduces the hydrogen concentration in the oxide semiconductor 230 and in the vicinity thereof.

When the top and bottom of the transistor 200 are surrounded by barrier insulators against hydrogen in this manner, diffusion of hydrogen into the oxide semiconductor can be reduced and V_{O}H in the channel formation region can be reduced. Thus, the reliability and electrical characteristics of the transistor 200 can be improved.

Furthermore, oxygen released by heating is preferably contained in the insulator 280. When oxygen is supplied to the oxide semiconductor 230 through the insulator 250 by heat treatment, oxygen vacancies in the channel formation region can be reduced.

For example, as illustrated in FIG. 8A, the insulator 282 may have a stacked-layer structure of an insulator 282a and an insulator 282b over the insulator 282a.

In that case, the insulator 282b is deposited by a sputtering method in an atmosphere containing an oxygen gas, whereby oxygen can be added to the insulator 280. At this time, when the insulator 282b is deposited with the insulator 282a provided, oxygen is added through the insulator 282a; hence, the amount of oxygen added to the insulator 280 can be controlled. With a larger thickness of the insulator 282a, the addition of oxygen is more likely to be inhibited, and the amount of oxygen supplied into the insulator 280 is reduced. With a small thickness of the insulator 282a, the addition of oxygen is less likely to be inhibited and the amount of oxygen supplied into the insulator 280 is increased. For example, when the thickness of the insulator 282a is greater than or equal to 1 nm and less than or equal to 20 nm, preferably greater than or equal to 3 nm and less than or equal to 10 nm, an appropriate amount of oxygen can be supplied to the insulator 280.

In addition, the insulator 282a is preferably deposited by an ALD method to prevent oxygen from being added to the insulator 280 at the time of depositing the insulator 282a. To form the insulator 282a having a small thickness as the above, an ALD method is preferably used. As the ALD method, a thermal ALD method in which a precursor and a reactant react with each other only by a thermal energy, a plasma-enhanced ALD (PEALD) method in which a reactant excited by plasma is used, and the like can be given.

Note that a precursor used in the ALD method sometimes contains carbon or the like. Thus, a film formed by the ALD method may contain impurities such as carbon in a larger amount than a film formed by another film formation method. Thus, the insulator 282a has a higher carbon concentration than the insulator 282b in some cases. Note that impurities can be quantified by SIMS, XPS, or auger electron spectroscopy (AES).

For example, in the case where both the insulator 282a and the insulator 282b contain aluminum oxide, the carbon concentration of the insulator 282a is higher than that of the insulator 282b in some cases. In that case, the carbon concentration of the insulator 282a is preferably higher than or equal to 1×10¹⁸ atoms/cm³ and lower than or equal to 1×10²¹ atoms/cm³ in SIMS analysis. The insulator 282a may include a region where the carbon concentration is higher than or equal to 1×10¹⁹ atoms/cm³ and lower than or equal to 1×10²¹ atoms/cm³. The carbon concentration of the insulator 282b is preferably higher than or equal to the lower detection limit and lower than or equal to 1×10²⁰ atoms/cm³ in the SIMS analysis. The insulator 282b may include a region where the carbon concentration is higher than or equal to 4.46×10¹⁷ atoms/cm³ and lower than or equal to 1×10¹⁹ atoms/cm³.

As described above, heat treatment is performed on the insulator 280 in a state containing oxygen to be released by heating, whereby an appropriate amount of oxygen can be supplied to the oxide semiconductor 230 through the insulator 250. Since the insulators 282 and 283 each having a barrier property against oxygen are formed over the insulator 280 in the heat treatment, oxygen contained in the insulator 280 can be prevented from being excessively diffused from the insulator 280. Since the insulator 275 having a barrier property against oxygen is formed between the insulator 280 and each of the oxide semiconductor 230 and the conductors 242a and 242b, oxygen contained in the insulator 280 can be prevented from being excessively diffused from the insulator 280. The heat treatment is performed in a state in which the opening is formed in part of the insulators 280, 282, and 283, whereby part of oxygen contained in the insulator 280 can be diffused outwardly and the amount of oxygen supplied from the insulator 280 to the oxide semiconductor 230 can be adjusted.

Here, preferably, the insulator 250 enables oxygen diffusion from the insulator 280 into the oxide semiconductor 230 and inhibition of oxidation of the conductors 242a, 242b, and 260.

As illustrated in FIGS. 7B and 7C, the insulator 250 is provided in the opening formed in the insulators 280 and 275. The insulator 250 is formed in contact with the top surface of the insulator 222, the side surface of the insulator 224, the side and top surfaces of the oxide semiconductor 230, the side surface of the conductor 242a, the side surface of the conductor 242b, the side surface of the insulator 271a, the side surface of the insulator 271b, the side surface of the insulator 275, and the side surface of the insulator 280 in the opening. As illustrated in FIG. 8A, in the case where the oxide semiconductor 230 includes the oxide semiconductor 230a to the oxide semiconductor 230c, the insulator 250 is in contact with the side surface of the oxide semiconductor 230a, the side surface of the oxide semiconductor 230b, and the top and side surfaces of the oxide semiconductor 230c. Here, as described in Embodiment 1, the crystallinity of the oxide semiconductor 230c (the oxide semiconductor 30c illustrated in FIG. 2A) is preferably increased. Because the oxide semiconductor 230c has a large contact area with the insulator 250, the carrier mobility can be increased when the transistor 200 is in an on state.

Here, as illustrated in FIG. 8A, the insulator 250 preferably has a stacked-layer structure including an insulator 250a in contact with the oxide semiconductor 230, an insulator 250b over the insulator 250a, and an insulator 250c over the insulator 250b.

For the insulator 250b, silicon oxide, silicon oxynitride, or the like with a high withstand voltage is preferably used. In order to increase the withstand voltage, the insulator 250b may have a thickness larger than those of the insulators 250a and 250d. With the use of the above oxide insulator, oxygen can be diffused in the insulator 250b by high-temperature heat treatment. Thus, the heat treatment enables oxygen contained in the insulator 280 to be supplied to the oxide semiconductor 230 through the insulator 250b. Note that in this specification and the like, oxynitride refers to a material that contains more oxygen than nitrogen, and nitride oxide refers to a material that contains more nitrogen than oxygen. For example, silicon oxynitride refers to a material that contains more oxygen than nitrogen, and silicon nitride oxide refers to a material that contains more nitrogen than oxygen.

In order to inhibit oxidation of the conductors 242a, 242b, and 260, a barrier insulator against oxygen is preferably provided in the vicinity of each of the conductors 242a, 242b, and 260. For example, a barrier insulator against oxygen is preferably provided as the insulators 250a and 250c.

The insulator 250a preferably has a barrier property against oxygen. The insulator 250a is preferably less permeable to oxygen than at least the insulator 250b is. The insulator 250a includes a region in contact with the side surface of the conductor 242a and the side surface of the conductor 242b. When the insulator 250a has a barrier property against oxygen, oxidation of the side surfaces of the conductors 242a and 242b, which forms oxide films on the side surfaces, can be inhibited. Accordingly, a reduction in on-state current or field-effect mobility of the transistor 200 can be inhibited. Such a structure can inhibit oxygen contained in the insulator 250b from being absorbed into the conductors 242a and 242b. Thus, an appropriate amount of oxygen can be supplied from the insulator 250b to the oxide semiconductor 230, so that oxygen vacancies in the channel formation region of the oxide semiconductor 230 can be reduced.

When the insulator 250a is provided between the insulator 280 and the insulator 250b and between the insulator 250b and the oxide semiconductor 230, oxygen can be inhibited from being excessively supplied from the insulator 280 to the oxide semiconductor 230, and an appropriate amount of oxygen can be supplied to the oxide semiconductor 230. Thus, the amount of oxygen in the channel formation region of the oxide semiconductor 230 and the vicinity thereof can be controlled to be an appropriate amount; thus, the transistor 200 can be prevented from having excessively normally-off characteristics and can have high reliability. In addition, excessive oxidation of the source and drain regions can be prevented, and a reduction in on-state current or field-effect mobility of the transistor 200 can be inhibited.

Thus, the insulator 250a preferably has a thickness that does not excessively inhibit diffusion of oxygen from the insulator 280 to the insulator 250b and diffusion of oxygen from the insulator 250b to the oxide semiconductor 230. For example, the thickness of the insulator 250a is preferably greater than or equal to 0.1 nm and less than or equal to 5.0 nm, further preferably greater than or equal to 0.5 nm and less than or equal to 5.0 nm, still further preferably greater than or equal to 0.5 nm and less than 3.0 nm, yet still further preferably greater than or equal to 0.5 nm and less than or equal to 2.0 nm.

As described above, preferably, diffusion of oxygen from the insulator 280 to the insulator 250b and diffusion of oxygen from the insulator 250b to the oxide semiconductor 230 are performed appropriately, and diffusion of oxygen from the insulator 250b to the conductors 242a and 242b is inhibited as much as possible. Here, in the semiconductor device of this embodiment, the contact area between the insulator 250a and the conductor 242a and the contact area between the insulator 250a and the conductor 242b are much smaller than the contact area between the insulator 250a and the oxide semiconductor 230. That is, the amount of oxygen diffusing from the insulator 250b to the conductors 242a and 242b through the insulator 250a is presumed to be smaller than the amount of oxygen diffusing from the insulator 250b to the oxide semiconductor 230 through the insulator 250a. Thus, the amount of oxygen contained in the insulator 280 is controlled so that an appropriate amount of oxygen is supplied from the insulator 280 to the insulator 250b and the oxide semiconductor 230, whereby oxidation of the conductors 242a and 242b can be reduced.

The insulator 250a in contact with the channel formation region of the oxide semiconductor 230 preferably has a function of capturing or fixing hydrogen. Thus, the hydrogen concentration in the channel formation region of the oxide semiconductor 230 can be reduced. Accordingly, V_{O}H in the channel formation region can be reduced, so that the channel formation region can be an i-type or substantially i-type region.

Moreover, a high dielectric constant (high-k) material is preferably used for the insulator 250a. An example of the high-k material is an oxide containing one or both of aluminum and hafnium. With use of the high-k material for the insulator 250a, a gate potential applied in the operation of the transistor can be reduced while the physical thickness of the gate insulator is maintained. In addition, the equivalent oxide thickness (EOT) of the insulator functioning as the gate insulator can be reduced.

As described above, oxide containing aluminum and/or hafnium is preferably used for the insulator 250a, and further preferably, an oxide containing aluminum and/or hafnium and having an amorphous structure is used. Since aluminum oxide can be formed as an amorphous film relatively easily by an ALD method, use of aluminum oxide having an amorphous structure is preferred. In this embodiment, an aluminum oxide film is used as the insulator 250a. Aluminum oxide has a function of capturing or fixing hydrogen and has a barrier property against oxygen; thus, aluminum oxide can be suitably used for the insulator 250a.

The insulator 250c also preferably has a barrier property against oxygen. The insulator 250c is provided between the conductor 260 and the channel formation region of the oxide semiconductor 230 and between the insulator 280 and the conductor 260. Such a structure can prevent oxygen contained in the channel formation region of the oxide semiconductor 230 from diffusing into the conductor 260 and thus can prevent formation of oxygen vacancies in the channel formation region of the oxide semiconductor 230. Oxygen contained in the oxide semiconductor 230 and oxygen contained in the insulator 280 can be inhibited from diffusing into the conductor 260 and oxidizing the conductor 260. The insulator 250c is preferably less permeable to oxygen than at least the insulator 250b is. Thus, the insulator 250c preferably has a function of inhibiting hydrogen diffusion. This can prevent diffusion of impurities contained in the conductor 260, such as hydrogen, into the oxide semiconductor 230. For example, a silicon nitride film is preferably used for the insulator 250c.

As illustrated in FIG. 8B, the insulator 250d may be provided over the insulator 250b. In that case, an insulator that can be used as the insulator 250a can be provided as the insulator 250d. For example, hafnium oxide can be used as the insulator 250d. Here, when the insulator 250d is provided between the insulator 250c and the insulator 250b, hydrogen contained in the insulator 250b and the like can be captured or fixed more effectively. Alternatively, the insulators 250a, 250b, and 250d can be provided, excluding the insulator 250c.

With the above structure, the i-type or substantially i-type channel formation region and the n-type source and drain regions can be formed; therefore, a semiconductor device with favorable electrical characteristics can be provided. The semiconductor device with the above structure can have favorable electrical characteristics even when being miniaturized or highly integrated. Furthermore, miniaturization of the transistor 200 can improve the frequency characteristics. Specifically, the cutoff frequency can be improved.

The insulators 250a to 250d function as a part of the first gate insulator. The insulators 250a to 250d are provided together with the conductor 260 in the opening formed in the insulator 280 and the like. The thickness of each of the insulators 250a, 250c, and 250d is preferably small for miniaturization of the transistor 200. The thickness of each of the insulators 250a, 250c, and 250d is preferably greater than or equal to 0.1 nm and less than or equal to 20 nm, more preferably greater than or equal to 0.1 nm and less than or equal to 10 nm, further preferably greater than or equal to 0.5 nm and less than or equal to 5.0 nm, further preferably greater than or equal to 1.0 nm and less than 5.0 nm, further preferably greater than or equal to 1.0 nm and less than or equal to 3.0 nm. Note that each of the insulators 250a, 250c, and 250d at least partly includes a region with the above thickness.

To reduce the thicknesses of the insulators 250a to 250d as described above, an ALD method is preferably used for deposition. Furthermore, in the case where the insulators 250a to 250d having favorable coverage are provided in the opening in the insulator 280 and the like, an ALD method is preferably employed.

Although the case where the insulator 250 has a three-layer structure of the insulators 250a to 250c or a four-layer structure of the insulators 250a to 250d is described above, the present invention is not limited to these structures. The insulator 250 can have a structure including at least one of the insulators 250a to 250d. When the insulator 250 is formed of one, two, or three layer(s) of the insulators 250a to 250d, the manufacturing process of a semiconductor device can be simplified and the productivity can be improved.

In the transistor 200, the conductor 205 is provided to overlap with the oxide semiconductor 230 and the conductor 260. For the conductor 205, any of the conductive materials described in the section <<Conductor>> can be used. Here, the conductor 205 is preferably provided to be embedded in an opening formed in the insulator 216. The conductor 205 is preferably provided to extend in the channel width direction as illustrated in FIGS. 7A and 7C. With such a structure, the conductor 205 functions as a wiring when a plurality of transistors are provided.

As illustrated in FIG. 8A, the conductor 205 preferably includes the conductors 205a and 205b. The conductor 205a is provided in contact with a bottom surface and a sidewall of the opening. The conductor 205b is provided to fill a depressed portion defined by the conductor 205a formed along the opening. Here, the top surface of the conductor 205 is level or substantially level with the top surface of the insulator 216.

Here, the conductor 205a preferably includes a conductive material having a function of inhibiting diffusion of impurities such as hydrogen atoms, hydrogen molecules, water molecules, nitrogen atoms, nitrogen molecules, nitrogen oxide molecules (e.g., N₂O, NO, and NO₂), and copper atoms. Alternatively, the conductor 205a preferably includes a conductive material having a function of inhibiting diffusion of oxygen (e.g., at least one of oxygen atoms and oxygen molecules).

When the conductor 205a is formed using a conductive material having a function of inhibiting diffusion of hydrogen, impurities such as hydrogen contained in the conductor 205b can be prevented from diffusing into the oxide semiconductor 230 through the insulator 216 and the like. When a conductive material having a function of inhibiting oxygen diffusion is used for the conductor 205a, a reduction in conductivity of the conductor 205b due to oxidation of the conductor 205b can be inhibited. Examples of the conductive material having a function of inhibiting diffusion of oxygen include titanium, titanium nitride, tantalum, tantalum nitride, ruthenium, and ruthenium oxide. The conductor 205a can have a single-layer structure or a stacked-layer structure of the above conductive material. For example, the conductor 205a preferably contains titanium nitride.

A conductive material containing tungsten, copper, or aluminum as its main component is preferably used for the conductor 205b. For example, the conductor 205b preferably contains tungsten.

The conductor 205 can function as a second gate electrode. In that case, by changing a potential applied to the conductor 205 independently of a potential applied to the conductor 260, the threshold voltage (Vth) of the transistor 200 can be controlled. In particular, by applying a negative potential to the conductor 205, Vth of the transistor 200 can be higher, and its off-state current can be reduced. Thus, a drain current at the time when a potential applied to the conductor 260 is 0 V can be lower in the case where a negative potential is applied to the conductor 205 than in the case where the negative potential is not applied to the conductor 205.

The electric resistivity of the conductor 205 is designed in consideration of the potential applied to the conductor 205, and the thickness of the conductor 205 is determined in accordance with the electric resistivity. The thickness of the insulator 216 is substantially equal to that of the conductor 205. The conductor 205 and the insulator 216 are preferably as thin as possible in the allowable range of the design of the conductor 205. The insulator 216 with a reduced thickness contains a smaller absolute amount of impurities such as hydrogen, inhibiting the diffusion of the impurities into the oxide semiconductor 230.

Although the stacked-layer structure of the conductors 205a and 205b is described with reference to FIG. 8A, the present invention is not limited to this structure. The conductor 205 may have a single-layer structure or a stacked-layer structure of three or more layers. For example, the conductor 205a may have a two-layer structure of tantalum nitride and titanium nitride over the tantalum nitride, and the conductor 205b including tungsten may be provided over the conductor 205a. With such a structure, impurities such as hydrogen and metal impurities such as copper contained in the layer below the transistor 200 can be inhibited from diffusing into the conductor 205.

The insulator 224 corresponding to the layer 29 functions as the second gate insulator, together with the insulators 221 and 222.

For the insulator 224 in contact with the oxide semiconductor 230, any of the insulating materials described in the section <<Insulator> can be used. The insulator 224 preferably contains, for example, silicon oxide or silicon oxynitride. Accordingly, oxygen can be supplied from the insulator 224 to the oxide semiconductor 230, so that oxygen vacancies can be reduced. Note that the insulator 224 may have a stacked-layer structure of two or more layers. In those cases, without limitation to a stacked-layer structure formed of the same material, a stacked-layer structure formed of different materials may be employed.

The insulator 224 is preferably processed into an island shape like the oxide semiconductor 230. Thus, in the case where the plurality of transistors 200 are provided, the transistors 200 have the insulator 224 of substantially the same size. Accordingly, among the transistors 200, the amount of oxygen supplied from the insulator 224 to the oxide semiconductor 230 is substantially the same. Therefore, variations in electrical characteristics of the transistors 200 in the substrate plane can be reduced.

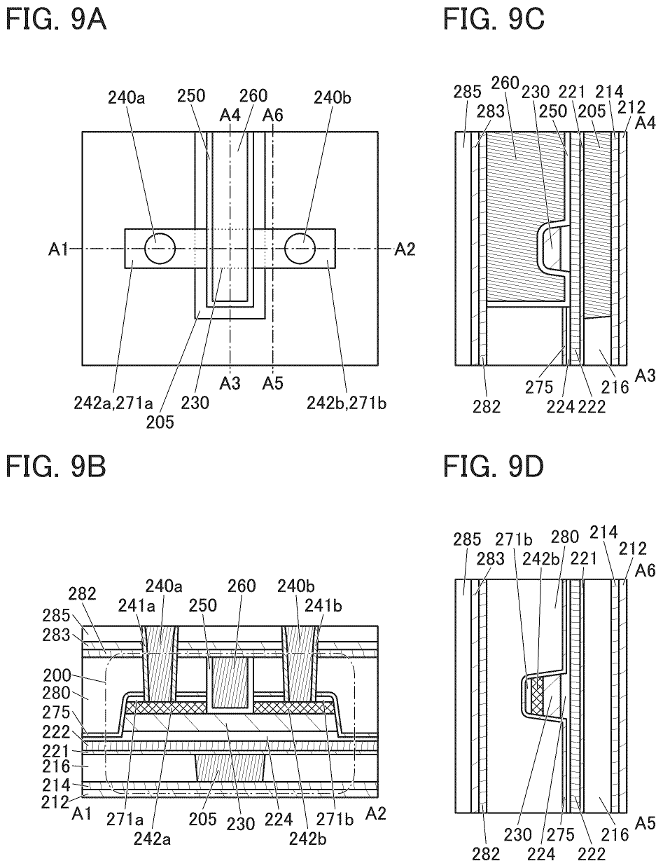

Note that the insulator 224 is not necessarily processed into an island shape. For example, as illustrated in FIGS. 9A to 9D, the insulator 224 may have a shape in which an opening is partly formed, instead of having an island shape. Here, FIGS. 9A to 9D correspond to FIGS. 7A to 7D, respectively, and are the same as FIGS. 7A to 7D except for the shape of the insulator 224.

The insulator 224 illustrated in FIGS. 9A to 9D has a smaller thickness in a region not overlapping with the oxide semiconductor 230 than in a region overlapping with the oxide semiconductor 230. An opening is formed in a region not overlapping with the oxide semiconductor 230 but overlapping with the insulator 250. In the case where a plurality of transistors are provided over one substrate, the oxide semiconductor 230 of each transistor is formed over the same insulator 224 by forming the insulator 224 in this manner. Accordingly, a variation in the amount of oxygen supplied from the insulator 224 to the oxide semiconductor 230 of each transistor can be reduced. Thus, a variation in electrical characteristics of the transistors can be reduced.

Note that in the insulator 224 illustrated in FIGS. 9A to 9D, an opening is formed in a region not overlapping with the oxide semiconductor 230 but overlapping with the insulator 250; however, a structure without the opening may be employed.

For the conductors 242a, 242b, and 260, any of the conductive materials described in the section <<Conductor>> can be used. In particular, a conductive material that is less likely to be oxidized or a conductive material having a function of inhibiting diffusion of oxygen is preferably used for the conductors 242a, 242b, and 260. Examples of the conductive material include a conductive material containing nitrogen and a conductive material containing oxygen. Thus, a decrease in conductivity of the conductors 242a, 242b, and 260 can be inhibited. In the case where a conductive material containing metal and nitrogen is used for each of the conductors 242a, 242b, and 260, the conductors 242a, 242b, and 260 contain at least metal and nitrogen.

For the conductors 242a and 242b, metal nitride is preferably used; for example, a nitride containing tantalum, a nitride containing titanium, a nitride containing molybdenum, a nitride containing tungsten, a nitride containing tantalum and aluminum, or a nitride containing titanium and aluminum is preferably used. For example, tantalum nitride can be used for the conductors 242a and 242b. For another example, ruthenium, ruthenium oxide, ruthenium nitride, an oxide containing strontium and ruthenium, or an oxide containing lanthanum and nickel may be used. These materials are preferable because they are conductive materials that are not easily oxidized or materials that maintain their conductivity even after absorbing oxygen.

Note that hydrogen contained in the oxide semiconductor 230 or the like diffuses into the conductor 242a or the conductor 242b in some cases. In particular, when a nitride containing tantalum is used for the conductors 242a and 242b, hydrogen contained in the oxide semiconductor 230 or the like is likely to diffuse into the conductor 242a or the conductor 242b, and the diffused hydrogen is bonded to nitrogen contained in the conductor 242a or the conductor 242b in some cases. That is, hydrogen contained in the oxide semiconductor 230 or the like is sometimes absorbed by the conductor 242a or 242b.

The conductors 240a and 240b may each have a stacked-layer structure. In that case, the above conductive material may be used for lower layers of the stacked-layer structures of the conductors 242a and 242b, and a conductive material having higher conductivity may be used for upper layers of the stacked-layer structures of the conductors 242a and 242b. For example, tantalum nitride can be used for the lower layers and tungsten can be used for the upper layers.

The insulators 271a and 271b function as an etching stopper at the time of processing the conductors 242a and 242b, and are inorganic insulators that protect the conductors 242a and 242b. Since the insulators 271a and 271b are respectively in contact with the conductors 242a and 242b, the insulators 271a and 271b are each preferably an inorganic insulator that is unlikely to oxidize the conductors 242a and 242b. Thus, as illustrated in FIG. 8A, the insulator 271a preferably has a stacked-layer structure of an insulator 271al and an insulator 271a2 over the insulator 271al, and the insulator 271b preferably has a stacked-layer structure of an insulator 271b1 and an insulator 271b2 over the insulator 271b1. Here, the nitride insulator that can be used as the insulator 250c is preferably used for the insulators 271al and 271b1, in which case the conductors 242a and 242b are less likely to be oxidized. The oxide insulator that can be used as the insulator 250b is preferably used as the insulators 271a2 and 271b2 so that the insulators 271a2 and 271b2 function as an etching stopper.

Here, the insulator 271al is in contact with a top surface of the conductor 242a and a part of the insulator 275, and the insulator 271b1 is in contact with a top surface of the conductor 242b and another part of the insulator 275. The insulator 271a2 is in contact with a top surface of the insulator 271al and a bottom surface of the insulator 275, and the insulator 271b2 is in contact with a top surface of the insulator 271b1 and the bottom surface of the insulator 275. For example, silicon nitride can be used for the insulators 271al and 271b1, and silicon oxide can be used for the insulators 271a2 and 271b2.

An insulator to be the insulators 271a and 271b functions as a mask for a conductor to be the conductors 242a and 242b, and thus the conductors 242a and 242b do not have a curved surface between the side surface and the top surface as illustrated in FIG. 7D. Accordingly, an end portion at the intersection of the side surface and the top surface of each of the conductors 242a and 242b is angular. The cross-sectional area of each of the conductors 242a and 242b is larger in the case where the end portion at the intersection of the side surface and the top surface of each of the conductors 242a and 242b is angular than in the case where the end portion is rounded. Furthermore, when nitride insulator that is less likely to oxidize metal is used for the insulators 271al and 271b1, excessive oxidation of the conductors 242a and 242b can be prevented. Accordingly, the resistances of the conductors 242a and 242b are reduced, so that the on-state current of the transistor can be increased.

As illustrated in FIGS. 7B and 7C, the conductor 260 is provided in the opening formed in the insulators 280 and 275. The conductor 260 is formed in the opening to cover the top surface of the insulator 222, the side surface of the insulator 224, and the side and top surfaces of the oxide semiconductor 230 with the insulator 250 therebetween. The top surface of the conductor 260 is positioned to be level or substantially level with the upper end portion of the insulator 250 and the top surface of the insulator 280.

Note that the sidewall of the opening in which the conductor 260 and the insulator 250 are formed may be perpendicular or substantially perpendicular to the top surface of the insulator 222 or may have a tapered shape. The sidewall with a tapered shape can improve the coverage with the insulator 250 formed in the opening in the insulator 280, so that the number of defects such as voids can be reduced.

The conductor 260 functions as the first gate electrode of the transistor 200. Here, the conductor 260 is preferably provided to extend in the channel width direction as illustrated in FIGS. 7A and 7C. With such a structure, the conductor 260 functions as a wiring when a plurality of transistors are provided.

In the case where the above structure is employed, a curved surface may be provided between the side and top surfaces of the oxide semiconductor 230 in a cross-sectional view in the channel width direction of the transistor 200, as illustrated in FIG. 7C. In other words, the end portion of the side surface and the end portion of the top surface may be curved (rounded).

The radius of curvature of the curved surface is preferably greater than 0 nm and less than the thickness of the oxide semiconductor 230 in a region overlapping with the conductors 242a and 242b, or less than half of the length of a region that does not have the curved surface. Specifically, the radius of curvature of the curved surface is greater than 0 nm and less than or equal to 20 nm, preferably greater than or equal to 1 nm and less than or equal to 15 nm, further preferably greater than or equal to 2 nm and less than or equal to 10 nm. Such a shape can improve the coverage of the oxide semiconductor 230 with the insulator 250 and the conductor 260.

Note that in this specification and the like, a transistor structure in which a channel formation region is electrically surrounded by at least the electric field of the first gate electrode is referred to as a surrounded channel (S-channel) structure. The S-channel structure disclosed in this specification and the like is different from a Fin structure or a planar structure. However, the S-channel structure disclosed in this specification and the like can be regarded as a kind of the Fin structure. In this specification and the like, the Fin structure refers to a structure in which at least two surfaces (specifically, two surfaces, three surfaces, four surfaces, or the like) of a channel are covered with a gate electrode. With the use of the Fin structure or the S-channel structure, a transistor with high resistance to a short-channel effect, i.e., a transistor in which a short-channel effect is unlikely to occur, can be obtained.

When the transistor 200 has the above-described S-channel structure, the channel formation region can be electrically surrounded. Since the S-channel structure is a structure with the electrically surrounded channel formation region, the S-channel structure is, in a sense, equivalent to a gate all around (GAA) structure or a lateral gate all around (LGAA) structure. When the transistor 200 has any of an S-channel structure, a GAA structure, and an LGAA structure, the channel formation region formed at the interface between the oxide semiconductor 230 and the gate insulator or in the vicinity thereof can correspond to the whole bulk of the oxide semiconductor 230. Consequently, the density of current flowing through the transistor can be improved, so that the on-state current or the field-effect mobility of the transistor can be increased.

In this embodiment, the insulator 224 is provided to have an island shape. Accordingly, as illustrated in FIG. 7C, at least a part of a bottom surface of the conductor 260 can be at a position lower than a bottom surface of the oxide semiconductor 230. Thus, the conductor 260 can be provided to face a top surface and a side surface of the oxide semiconductor 230, so that an electric field of the conductor 260 can act on the top surface and the side surface of the oxide semiconductor 230. When the insulator 224 with an island shape is provided in this manner, the transistor 200 can have an S-channel structure.

Note that although FIG. 7C illustrates a transistor with an S-channel structure as the transistor 200, the semiconductor device of one embodiment of the present invention is not limited to this. For example, a transistor structure that can be employed in one embodiment of the present invention is one or more selected from a planar structure, a Fin-type structure, and a GAA structure.

As illustrated in FIG. 8A, the conductor 260 preferably has a two-layer structure. Here, the conductor 260 preferably includes the conductor 260a and the conductor 260b over the conductor 260a. For example, the conductor 260a is preferably placed to cover the bottom and side surfaces of the conductor 260b. In that case, a conductive material that is less likely to be oxidized or a conductive material having a function of preventing diffusion of oxygen is preferably used for the conductor 260a.

The conductor 260a is preferably formed using a conductive material having a function of inhibiting diffusion of impurities such as hydrogen atoms, hydrogen molecules, water molecules, nitrogen atoms, nitrogen molecules, nitrogen oxide molecules, and copper atoms. Alternatively, the conductor 260a is preferably formed using a conductive material having a function of inhibiting diffusion of oxygen (e.g., at least one of oxygen atoms and oxygen molecules).

When the conductor 260a has a function of inhibiting diffusion of oxygen, the conductivity of the conductor 260b can be inhibited from being lowered because of oxidization of the conductor 260b due to oxygen in the insulator 280 and the like. As the conductive material having a function of inhibiting diffusion of oxygen, for example, titanium, titanium nitride, tantalum, tantalum nitride, ruthenium, or ruthenium oxide is preferably used.

The conductor 260b is preferably formed using a conductor having high conductivity. For example, a conductive material containing tungsten, copper, or aluminum as its main component can be used for the conductor 260b. The conductor 260b may have a stacked-layer structure, for example, a stacked-layer structure of titanium or titanium nitride and the above conductive material.

In the transistor 200, the conductor 260 is formed in a self-aligned manner to fill the opening formed in the insulator 280 and the like. In this manner, the conductor 260 can be provided to overlap with a region between the conductor 242a and the conductor 242b without alignment.

The insulators 216, 280, and 285 each preferably have a lower dielectric constant than the insulator 222. In the case where a material with a low dielectric constant is used for an interlayer film, the parasitic capacitance between wirings can be reduced.

For example, each of the insulators 216, 280, and 285 each preferably includes one or more of silicon oxide, silicon oxynitride, silicon oxide to which fluorine is added, silicon oxide to which carbon is added, silicon oxide to which carbon and nitrogen are added, and porous silicon oxide.

In particular, silicon oxide and silicon oxynitride are preferable because they are thermally stable. In particular, materials such as silicon oxide, silicon oxynitride, and porous silicon oxide are preferably used, in which case a region containing oxygen released by heating can be easily formed.

Each of the top surfaces of the insulator 216 and the insulator 280 may be planarized.

The concentration of an impurity such as water or hydrogen in the insulator 280 is preferably reduced. For example, the insulator 280 preferably includes an oxide containing silicon such as silicon oxide or silicon oxynitride.

For the conductors 240a and 240b, any of the conductive materials described in the section <<Conductor>> can be used. The conductors 240a and 240b are preferably formed using a conductive material containing tungsten, copper, or aluminum as its main component, for example. The conductors 240a and 240b may each have a stacked-layer structure.

For example, as illustrated in FIG. 8A, the conductors 240a and 240b may each have a two-layer structure. The conductor 240a includes a conductor 240al formed along the opening and a conductor 240a2 formed inside the conductor 240al. The conductor 240b includes a conductor 240b1 formed along the opening and a conductor 240b2 formed inside the conductor 240b1.

For the conductors 240a1 and 240b1 as well as the conductor 205a, a conductive material having a function of inhibiting passage of impurities such as water or hydrogen is preferably used. For example, tantalum, tantalum nitride, titanium, titanium nitride, ruthenium, or ruthenium oxide is preferably used. The conductive material having a function of inhibiting passage of impurities such as water and hydrogen can be used as a single layer or stacked layers. Providing the conductors 240al and 240b1 can inhibit entry of impurities such as water and hydrogen into the oxide semiconductor 230 through the conductors 240a2 and 240b2. Note that the conductors 240a2 and 240b2 can be formed using conductive materials that can be used for the conductors 240a and 240b.

As illustrated in FIG. 7B, the top surfaces of the conductors 240a and 240b can be formed to be level or substantially level with the top surface of the insulator 285. As illustrated in FIG. 8A, a lower portion of the conductor 240a is sometimes formed to be embedded in the conductor 242a. Similarly, a lower portion of the conductor 240b is sometimes formed to be embedded in the conductor 242b.

The insulators 241a and 241b can be formed using a barrier insulator that can be used for the insulator 275 or the like. For example, silicon nitride may be used for the insulators 241a and 241b. The insulators 241a and 241b are provided in contact with the insulators 285, 283, 282, 275, 271a, and 271b. Furthermore, impurities such as water and hydrogen contained in the insulator 280 or the like can be inhibited from entering the oxide semiconductor 230 through the conductors 240a and 240b. Silicon nitride is particularly preferable because of its high blocking property against hydrogen. Furthermore, oxygen contained in the insulator 280 can be prevented from being absorbed by the conductors 240a and 240b.

The insulators 241a and 241b may each have a stacked-layer structure. In this case, a first insulator in contact with a sidewall of the opening formed in the insulator 280 and the like and a second insulator on the inner side of the first insulator are preferably formed using a combination of a barrier insulator against oxygen and a barrier insulator against hydrogen.

### MODIFICATION EXAMPLE

In FIG. 7B and the like, the insulator 250 is in contact with the side surface of the insulator 280 in the opening portion provided in the insulator 280; however, the present invention is not limited to this structure. For example, an insulator may be provided between the insulator 250 and the insulator 280 in the opening portion.

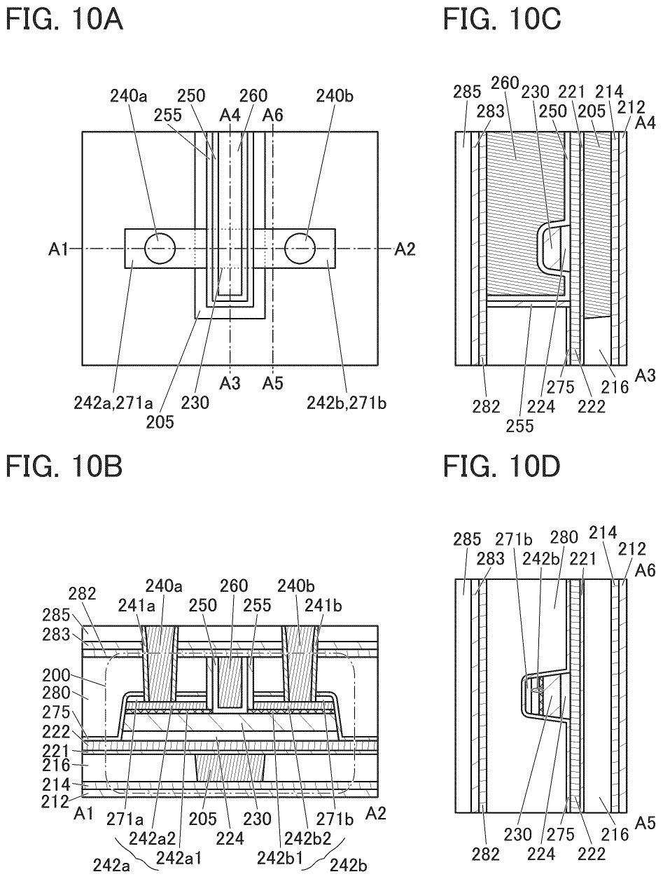

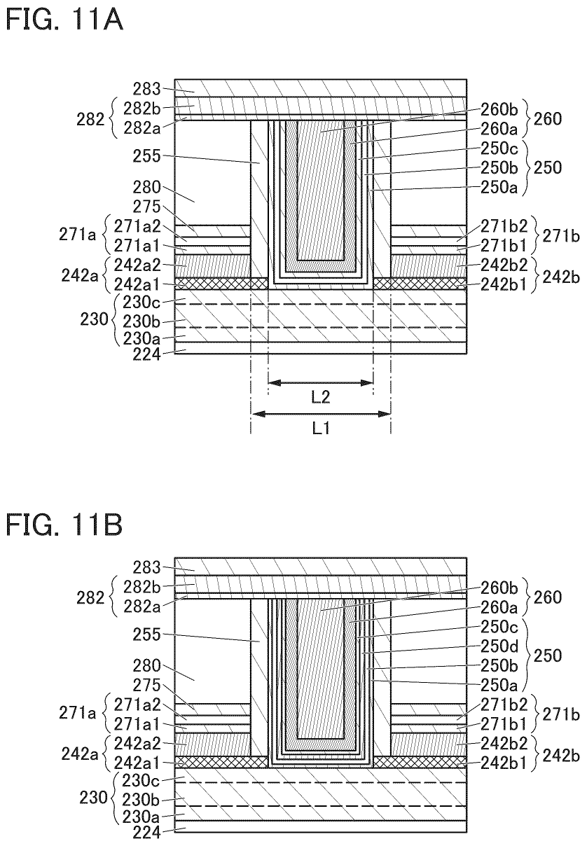

Modification examples of the semiconductor device described in <Structure example of semiconductor device> will be described with reference to FIGS. 10A to 10D and FIGS. 11A and 11B. FIGS. 10A to 10D are a plan view and cross-sectional views of the semiconductor device including the transistor 200 and correspond to the plan view and cross-sectional views illustrated in FIGS. 7A to 7D. FIGS. 11A and 11B are enlarged cross-sectional views of the transistor 200 in the channel length direction and correspond to part of FIG. 8A and the enlarged cross-sectional view in FIG. 8B, respectively.

The transistor 200 illustrated in FIGS. 10A to 10D is a modification example of the transistor 200 illustrated in FIGS. 7A to 7D. Specifically, the transistor 200 illustrated in FIGS. 10A to 10D is different from the transistor 200 illustrated in FIGS. 7A to 7D mainly in including an insulator 255. Differences from the above description of <Structure example of semiconductor device> are mainly described below, and the description of <Structure example of semiconductor device> is referred to for the same portions, and the description of the same portion is omitted in some cases.

Note that in FIGS. 10A to 10D, the conductors 242a and 242b each have a two-layer structure. Specifically, the conductor 242a has a stacked-layer structure of the conductor 242al and the conductor 242a2 over the conductor 242al. Similarly, the conductor 242b has a stacked-layer structure of the conductor 242b1 and the conductor 242b2 over the conductor 242b1. The conductors 242al and 242b1 correspond to the lower layers of the conductors 242a and 242b, and the conductors 242a2 and 242b2 correspond to the upper layers of the conductors 242a and 242b.

As illustrated in FIGS. 10B and 10C, the insulator 255 is provided inside the opening portion formed in the insulator 280, and in contact with the side surface of the insulator 280, the side surface of the conductor 242a2, the side surface of the conductor 242b2, the top surface of the conductor 242al, the top surface of the conductor 242b1, and the top surface of the insulator 222 in the opening portion. In other words, the insulator 255 is formed in a sidewall shape to be in contact with a sidewall of the opening portion formed in the insulator 280. Here, the sidewall of the opening portion corresponds to, for example, the side surface of the insulator 280 or the like in the opening portion.

The insulator 250 is in contact with the side surface of the insulator 255.

The insulator 255 preferably has a barrier property against oxygen. When the insulator 255 has a barrier property against oxygen, oxidation of the side surfaces of the conductors 242a and 242b, which forms oxide films on the side surfaces, can be inhibited. It is thus possible to inhibit a reduction in the on-state current or field-effect mobility of the transistor 200.

The opening portion formed in the insulator 280 overlap with a region between the conductors 242a2 and 242b2. In the top view, the side surfaces of the insulator 280 in the opening portion are aligned or substantially aligned with the side surfaces of the conductor 242a2 and the conductor 242b2. Parts of the conductors 242al and 242b1 are each formed to extend to the inside of the opening portion. In other words, a part of the conductor 242al having a top surface on which the insulator 255 is formed to extend from the conductor 242a2 toward the conductor 260 side. Similarly, a part of the conductor 242b1 having a top surface on which the insulator 255 is formed to extend from the conductor 242b2 toward the conductor 260 side.

A part of a top surface of the conductor 242al is in contact with the conductor 242a2, and a part of a top surface of the conductor 242b1 is in contact with the conductor 242b2. Accordingly, the insulator 255 is in contact with another part of the top surface of the conductor 242a1, another part of the top surface of the conductor 242b1, the side surface of the conductor 242a2, and the side surface of the conductor 242b2 inside the opening portion. The insulator 250 is in contact with the top surface of the oxide semiconductor 230, a side surface of the conductor 242a1, a side surface of the conductor 242b1, and a side surface of the insulator 255.

The insulator 255 is anisotropically etched to be formed in a sidewall shape to be in contact with a sidewall of an opening portion provided in the insulator 280. The insulator 255 is formed in contact with the side surfaces of the conductors 242a2 and 242b2 and has a function of protecting the conductors 242a2 and 242b2.

The insulator 255 functions as a mask at the time of dividing the conductor into the conductors 242al and 242b1. Thus, as illustrated in FIG. 11A, in the cross-sectional view of the transistor 200, a side end portion of the insulator 255 is preferably aligned with a side end portion of the conductor 242al or a side end portion of the conductor 242b1.

In addition, heat treatment in an atmosphere containing oxygen is preferably performed after the division of the conductor into the conductors 242al and 242b1 and before the formation of the insulator 250. At this time, since the insulator 255 is formed in contact with the side surfaces of the conductors 242a2 and 242b2, excessive oxidation of the conductors 242a2 and 242b2 can be prevented. Furthermore, even in the case where microwave treatment is performed after the division into the conductors 242al and 242b1, formation of an oxide film on the side surfaces of the conductors 242a and 242b can be inhibited.

Portions of the insulators 255 and 250, and the conductor 260 that are placed in an opening portion provided in the insulator 280 are provided to reflect the shape of the opening portion. Thus, the insulator 255 is provided to cover the sidewall of the opening portion, the insulator 250 is provided to cover the bottom portion of the opening portion and the insulator 255, and the conductor 260 is provided to fill a depressed portion defined by the insulator 250.

Note that the insulator 250 may have a stacked-layer structure as in <Structure example of the semiconductor device> described above. For example, as illustrated in FIG. 11A, the insulator 250 may have a three-layer structure including the insulators 250a, 250b, and 250c. As illustrated in FIG. 11B, for another example, the insulator 250 may have a four-layer structure of the insulators 250a, 250b, 250c, and 250d.

The thickness of the insulator 255 is preferably greater than or equal to 0.5 nm and less than or equal to 20 nm, further preferably greater than or equal to 0.5 nm and less than or equal to 10 nm, further preferably greater than or equal to 0.5 nm and less than or equal to 3 nm. When the insulator 255 has a thickness in the above range, excessive oxidation of the conductors 242a2 and 242b2 can be inhibited. Note that the insulator 255 may have at least partly a region with the above thickness. Since the insulator 255 is provided in contact with the sidewall of the opening formed in the insulator 280, the insulator 255 is preferably formed by a method capable of depositing a film with good coverage, such as an ALD method. When the thickness of the insulator 255 is set excessively large, the time for depositing the insulator 255 by an ALD method is long, which decreases the productivity; for this reason, the thickness of the insulator 255 is preferably in the above range. The insulator 255 preferably has a thickness that does not excessively inhibit diffusion of excess oxygen from the insulator 280 to the insulator 250b and diffusion of excess oxygen from the insulator 250b to the oxide semiconductor 230.

As illustrated in FIG. 11A, in the cross-sectional view of the transistor 200 in the channel length direction, the distance L2 between the conductors 242al and 242b1 is smaller than the distance L1 between the conductors 242a2 and 242b2. Specifically, the difference between the distance L1 and the distance L2 is twice the thickness of the insulator 255. In other words, the distance L1 is equal to the sum of the distance L2 and twice the thickness of the insulator 255. Here, the thickness of the insulator 255 corresponds to the width in the A1-A2 direction of at least a portion of the insulator 255. With such a structure, the distance between a source and a drain can be shortened, and the channel length can also be shortened in accordance with the distance. Thus, the frequency characteristics of the transistor 200 can be improved. In this manner, scaling down of the semiconductor device enables the semiconductor device to have a higher operation speed.

The insulator 255 may have a stacked-layer structure of two or more layers. In that case, at least one of the stacked layers is preferably the above-described inorganic insulator that is less likely to be oxidized. For example, an inorganic insulator that is less likely to be oxidized is used as a first insulator of the insulator 255, and an insulator (e.g., silicon oxide) that can be used as the insulator 250b is used as a second insulator over the first insulator of the insulator 255. The second insulator of the insulator 255 preferably has a lower permittivity than the first insulator of the insulator 255. In this manner, the insulator 255 has a two-layer structure to have a large thickness, so that the distance between the conductor 260 and the conductor 242a or 242b can be increased and thus the parasitic capacitance can be reduced.

### <Materials for Semiconductor Device>

Materials that can be used for the semiconductor device will be described below. Note that the layers included in the semiconductor device may have a single-layer structure or a stacked-layer structure.

### <<Substrate>>

As a substrate where a transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Another example includes a semiconductor substrate in which an insulator region is provided in the above semiconductor substrate, such as a silicon on insulator (SOI) substrate. Examples of the conductor substrate include a graphite substrate, a metal substrate, an alloy substrate, and a conductive resin substrate. Examples of the substrate include a substrate including a metal nitride, a substrate including a metal oxide, an insulator substrate provided with a conductor or a semiconductor, a semiconductor substrate provided with a conductor or an insulator, and a conductor substrate provided with a semiconductor or an insulator. Alternatively, these substrates provided with one or more kinds of elements may be used. Examples of the element provided over the substrate include a capacitor, a resistor, a switching element, a light-emitting element, and a memory element.

### <<Insulator>>

Examples of an insulator include an insulating oxide, an insulating nitride, an insulating oxynitride, an insulating nitride oxide, an insulating metal oxide, an insulating metal oxynitride, and an insulating metal nitride oxide.

With miniaturization and high integration of a transistor, for example, a problem such as generation of leakage current may arise because of a thin gate insulator. When a high-k material is used for the insulator functioning as a gate insulator, the voltage at the time of operation of the transistor can be reduced while the physical thickness is maintained. By contrast, when a low-dielectric-constant material is used for the insulator functioning as an interlayer film, parasitic capacitance generated between wirings can be reduced. Thus, a material is preferably selected depending on the function of an insulator.

Examples of the insulator having a high dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator having a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

A transistor including a metal oxide can have stable electrical characteristics when surrounded by an insulator having a function of inhibiting transmission of oxygen and impurities such as hydrogen. The insulator having a function of inhibiting transmission of oxygen and impurities such as hydrogen can have, for example, a single-layer structure or a stacked-layer structure of an insulator(s) including one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, as the insulator having a function of inhibiting transmission of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, silicon nitride oxide, or silicon nitride can be used.

The insulator functioning as a gate insulator preferably includes a region containing oxygen that is released by heating. For example, silicon oxide or silicon oxynitride that includes a region containing oxygen that is released by heating is provided in contact with the oxide semiconductor 230 to compensate for the oxygen vacancies in the oxide semiconductor 230.

### <<Conductor>>

For the conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. Examples of the conductor include tantalum nitride, titanium nitride, tungsten, a nitride containing titanium and aluminum, a nitride containing tantalum and aluminum, ruthenium oxide, ruthenium nitride, an oxide containing strontium and ruthenium, and an oxide containing lanthanum and nickel. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even when absorbing oxygen. Alternatively, a semiconductor having high electric conductivity, typified by polycrystalline silicon containing an impurity element such as phosphorus, or silicide such as nickel silicide may be used.

In the case where a stacked-layer structure of conductors is used, for example, a stacked-layer structure combining a material containing any of the metal elements and a conductive material containing oxygen, a stacked-layer structure combining a material containing any of the metal elements and a conductive material containing nitrogen, or a stacked-layer structure combining a material containing any of the metal elements, a conductive material containing oxygen, and a conductive material containing nitrogen may be employed.

When an oxide is used for the channel formation region of the transistor, the conductor functioning as the gate electrode preferably has a stacked-layer structure combining a material containing any of the above metal elements and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. An indium gallium zinc oxide containing nitrogen may be used. With the use of such a material, hydrogen contained in the metal oxide where a channel is formed can be captured in some cases. Hydrogen entering from an outer insulator or the like can also be captured in some cases.

### <Example of Method for Manufacturing Semiconductor Device>

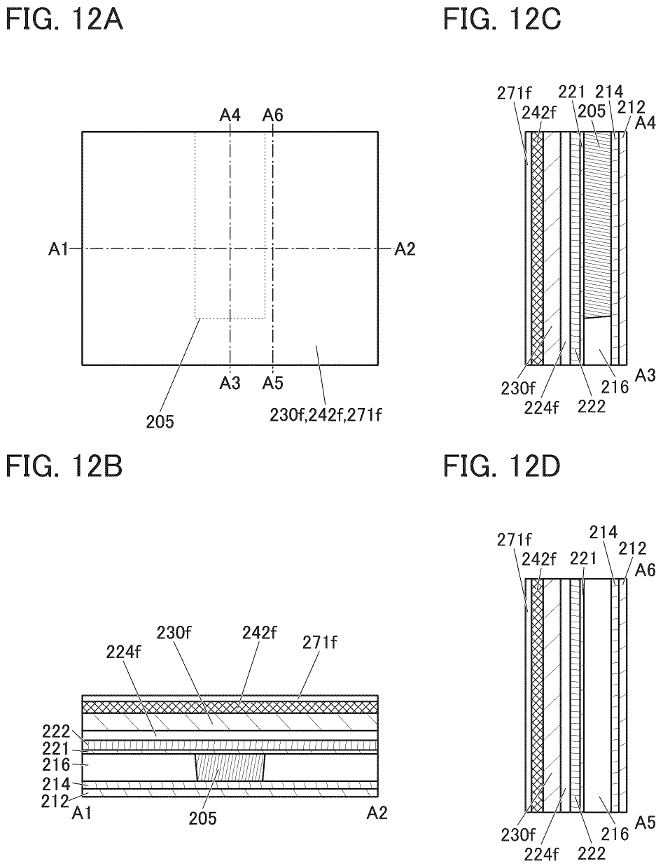

An example of a method of manufacturing the semiconductor device of one embodiment of the present invention is described with reference to FIGS. 12A to 12D to FIGS. 19A to 19D. Here, the case of manufacturing the semiconductor device illustrated in FIGS. 7A to 7D is described as an example.

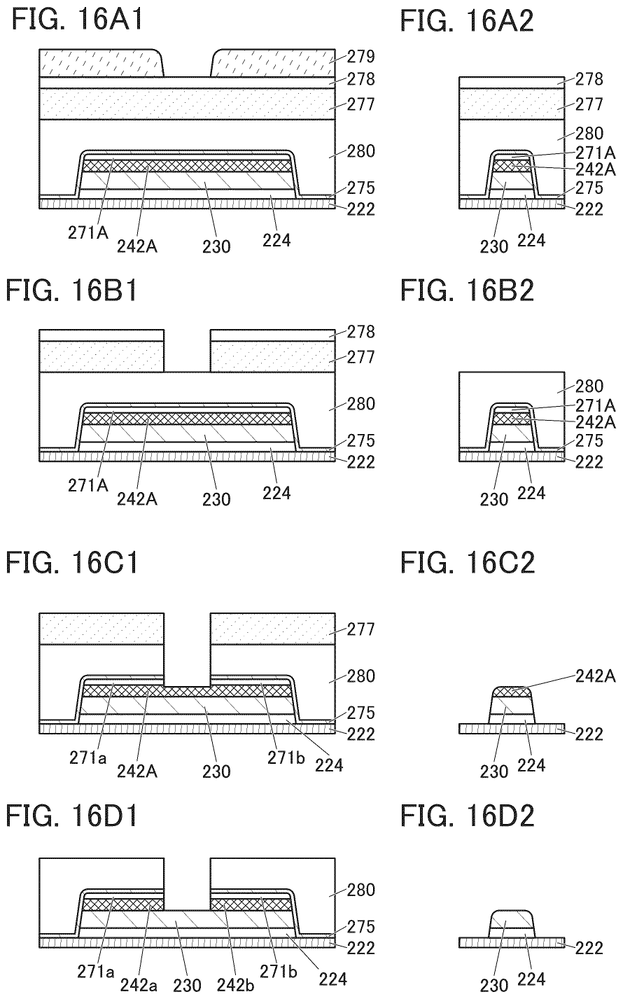

FIGS. 12A, 13A, 14A, 15A, 17A, 18A and 19A are plan views. FIGS. 12B, 13B, 14B, 15B, 17B, 18B and 19B are cross-sectional views taken along the dashed-dotted lines A1-A2 in FIGS. 12A, 13A, 14A, 15A, 17A, 18A and 19A, illustrating the transistor 200 in the channel length direction. FIGS. 12C, 13C, 14C, 15C, 17C, 18C and 19C are cross-sectional views taken along the dashed-dotted lines A3-A4 in FIGS. 12A, 13A, 14A, 15A, 17A, 18A and 19A, illustrating the transistor 200 in the channel width direction. FIGS. 12D, 13D, 14D, 15D, 17D, 18D and 19D are cross-sectional views taken along the dashed-dotted lines A5-A6 in FIGS. 12A, 13A, 14A, 15A, 17A, 18A and 19A, illustrating the transistor 200 in the channel width direction. Note that for simplification, some components are not illustrated in the plan views of FIGS. 12A, 13A, 14A, 15A, 17A, 18A and 19A. FIGS. 16A1, 16B1, 16C1, and 16D1 are cross-sectional views corresponding to part of FIG. 7B, illustrating the transistor 200 in the channel length direction. FIGS. 16A2, 16B2, 16C2, and 16D2 are cross-sectional views corresponding to part of FIG. 7C, illustrating the transistor 200 in the channel width direction.

In the following steps, an insulating material for forming an insulator, a conductive material for forming a conductor, or a semiconductor material for forming a semiconductor can be deposited as appropriate by a sputtering method, a CVD method, an MBE method, a PLD method, an ALD method, or the like.

First, a substrate (not illustrated) is prepared, the insulator 212 is formed over the substrate, and the insulator 214 is formed over the insulator 212 (see FIG. 12A to FIG. 12D). Any of the above insulating materials can be used for the insulators 212 and 214. The insulators 212 and 214 can be formed, for example, by a sputtering method, a CVD method, an MBE method, a PLD method, or an ALD method. A sputtering method which does not need to use a molecule containing hydrogen as a deposition gas is preferably used, in which case the hydrogen concentration in the insulators 212 and 214 can be reduced.

In this embodiment, silicon nitride is deposited by a sputtering method as the insulator 212, and aluminum oxide is deposited by a sputtering method as the insulator 214. When silicon nitride having a function of inhibiting diffusion of hydrogen is used for the insulator 212, diffusion of hydrogen from a layer below the transistor 200 can be inhibited. Furthermore, when aluminum oxide having a function of capturing or fixing hydrogen is used for the insulator 214, hydrogen contained in the insulator 216 or the like can be captured or fixed by the insulator 214. This reduces the hydrogen concentration in the oxide semiconductor 230 and in the vicinity thereof.

Before the insulator 212 is formed, heat treatment is preferably performed to reduce water and hydrogen adsorbed on a substrate (including a circuit element and an interlayer film formed over the substrate). In this embodiment, the temperature of the heat treatment is 400° C.

Next, the insulator 216 is formed over the insulator 214. The insulator 216 is preferably formed by a sputtering method. Since a molecule containing hydrogen is not used as a deposition gas in the sputtering method, the concentration of hydrogen in the insulator 216 can be reduced. Note that the insulator 216 can be formed by a CVD method, an MBE method, a PLD method, an ALD method, or the like as well as the sputtering method. In this embodiment, silicon oxide is deposited as the insulator 216 by a sputtering method.

The insulators 212, 214, and 216 are preferably formed successively without exposure to the air. For example, a multi-chamber deposition apparatus is used. As a result, the amount of hydrogen in the formed films of the insulators 212, 214, and 216 can be reduced, and furthermore, entry of hydrogen in the films between film formation steps can be inhibited.

Then, an opening reaching the insulator 214 is formed in the insulator 216. The opening is formed in a region where the conductor 205 is to be formed. Wet etching can be used for the formation of the opening; however, dry etching is preferable for microfabrication. The insulator 214 is preferably an insulator that functions as an etching stopper film at the time of etching of the insulator 216. For example, in the case where silicon oxide or silicon oxynitride is used as the insulator 216, the insulator 214 is preferably silicon nitride, aluminum oxide, hafnium oxide, or the like.

After the formation of the opening, a conductive film to be the conductor 205 is formed and subjected to CMP treatment until the insulator 216 is exposed, so that part of the conductive film to be the conductor 205 is removed. Thus, the conductor 205 embedded in the insulator 216 can be formed (see FIGS. 12A to 12D).

The conductive film to be the conductor 205 can be formed using any of the above conductive materials by a sputtering method, a CVD method, an MBE method, a PLD method, an ALD method, or the like. For example, a tantalum nitride film, a titanium nitride film, and a tungsten film can be stacked by a CVD method. Thus, as illustrated in FIG. 8A, the conductor 205 can have a stacked-layer structure of the conductor 205a in which titanium nitride is stacked over tantalum nitride and the conductor 205b of tungsten.

Next, the insulator 221 is formed over the insulator 216 and the conductor 205 (see FIGS. 12A to 12D).

An insulator having a barrier property against oxygen, hydrogen, and water is used as the insulator 221. The insulator 221 can be formed by a sputtering method, a CVD method, an MBE method, a PLD method, or an ALD method, for example. In this embodiment, silicon nitride is deposited as the insulator 221 by a PEALD method.

Next, the insulator 222 is formed over the insulator 221 (see FIGS. 12A to 12D).

The insulator 222 is preferably formed using an insulator containing an oxide of one or both of aluminum and hafnium. Note that as the insulator containing an oxide of one or both of aluminum and hafnium, aluminum oxide, hafnium oxide, or an oxide containing aluminum and hafnium (hafnium aluminate) is preferably used, for example. Alternatively, hafnium zirconium oxide is preferably used. The insulator containing an oxide of one or both of aluminum and hafnium has a barrier property against oxygen, hydrogen, and water. When the insulator 222 has a barrier property against hydrogen and water, diffusion of hydrogen and water contained in a structure body provided around the transistor into the transistor through the insulator 222 is inhibited, and accordingly oxygen vacancies can be inhibited from being generated in the oxide semiconductor 230.

The insulator 222 can be formed by, for example, a sputtering method, a CVD method, an MBE method, a PLD method, or an ALD method. In this embodiment, hafnium oxide is deposited as the insulator 222 by a thermal ALD method.

In this embodiment, silicon nitride is deposited as the insulator 221 by a PEALD method, and hafnium oxide is deposited as the insulator 222 by a thermal ALD method. When silicon nitride having a function of inhibiting diffusion of hydrogen is used for the insulator 221 in this manner, diffusion of hydrogen from a layer below the transistor 200 can be inhibited. Furthermore, when hafnium oxide having a function of capturing or fixing hydrogen is used for the insulator 222, hydrogen contained in the insulator 224 or the like can be captured or fixed by the insulator 222. This can reduce the hydrogen concentration in the metal oxide semiconductor 230 and in the vicinity thereof.

Next, an insulating film 224f is formed over the insulator 222 (see FIGS. 12A to 12D). For the insulating film 224f, an insulator corresponding to the insulator 224 may be used. By forming the insulating film 224f in this manner, the insulating film 224f is formed in parallel or substantially in parallel with the surface of the substrate.

The insulating film 224f can be formed by a sputtering method, a CVD method, an MBE method, a PLD method, or an ALD method, for example. In this embodiment, silicon oxide is deposited by a sputtering method as the insulating film 224f. Since a molecule containing hydrogen is not used as a deposition gas in the sputtering method, the hydrogen concentration in the insulating film 224f can be reduced. The hydrogen concentration in the insulating film 224f is preferably reduced in this manner because the insulating film 224f is in contact with the oxide semiconductor 230 in a later step.

Next, an oxide semiconductor film 230f is formed over the insulating film 224f (see FIGS. 12A to 12D). The oxide semiconductor film 230f may be formed by the same method as the oxide semiconductor 30 described in Embodiment 1. When the oxide semiconductor film 230f is formed in this manner, the oxide semiconductor film 230f is formed in parallel or substantially in parallel with the surface of the substrate.

For example, in the case where the oxide semiconductor 230 has a three-layer structure of the oxide semiconductors 230a to 230c as illustrated in FIG. 8A, films to be the oxide semiconductors 230a and 230c can be formed by an ALD method and a film to be the oxide semiconductor 230b can be formed by a sputtering method. Specifically, the film to be the oxide semiconductor 230a can be formed to a thickness of 5 nm to have a composition of In:Zn=2:1 [atomic ratio] or in the neighborhood thereof. Alternatively, indium oxide may be used for the film to be the oxide semiconductor 230a.

The film to be the oxide semiconductor 230b can be formed to a thickness of 5 nm using an oxide target with a composition of In:Ga:Zn=1:1:1.2 [atomic ratio] or in the neighborhood thereof. The film to be the oxide semiconductor 230c can be formed to a thickness of 10 nm to have a composition of In:Zn=2:1 [atomic ratio] or in the neighborhood thereof. Alternatively, indium oxide may be used for the film to be the oxide semiconductor 230c.

Next, heat treatment is preferably performed. The heat treatment is preferably performed in a temperature range where the oxide semiconductor film 230f does not become polycrystal. The heat treatment of the oxide semiconductor film 230f can be performed by the same method as the heat treatment of the oxide semiconductor 30 described in Embodiment 1.

For example, heat treatment can be performed at 450° C. for one hour at a flow rate ratio of a nitrogen gas to an oxygen gas of 4:1.

When the oxide semiconductor 230 is formed by the above-described method and heat treatment is performed, the oxide semiconductor 230 can have Axial Growth CAAC. Accordingly, the on-state current, the S value, the field-effect mobility, the frequency characteristics, and the like of the transistor 200 can be improved, so that a semiconductor device having favorable electrical characteristics can be provided. Moreover, a highly reliable semiconductor device can be provided.

Note that the heat treatment is preferably performed in a nitrogen gas atmosphere, an inert gas atmosphere, or an atmosphere containing an oxidizing gas at 10 ppm or more, 1% or more, or 10% or more. The heat treatment may be performed under a reduced pressure. Alternatively, the heat treatment may be performed as follows: heat treatment is performed in an atmosphere of a nitrogen gas or an inert gas, and then another heat treatment is performed in an atmosphere containing an oxidizing gas at 10 ppm or more, 1% or more, or 10% or more in order to compensate for released oxygen.

The gas used in the above heat treatment preferably has high purity. For example, the amount of moisture contained in the gas used in the above heat treatment is preferably 1 ppb or less, further preferably 0.1 ppb or less, still further preferably 0.05 ppb or less. The heat treatment using a highly purified gas can prevent the entry of moisture or the like into the oxide semiconductor film 230f or the like as much as possible. Note that a highly purified gas can also be used in heat treatment before this step and heat treatment after this step.

With the heat treatment using the above-described oxygen gas, impurities such as carbon, water, and hydrogen in the oxide semiconductor film 230f can be reduced. Impurities in the film are reduced in the above manner, whereby the crystallinity of the oxide semiconductor film 230f can be improved and a denser structure can be obtained. Accordingly, the crystal region in the oxide semiconductor film 230f can be increased, and an in-plane variation of a crystal region in the oxide semiconductor film 230f can be reduced. Thus, an in-plane variation in electrical characteristics of the transistor can be reduced.

The heat treatment can supply oxygen to the oxide semiconductor film 230f to reduce oxygen vacancies in the oxide semiconductor film 230f. Thus, the reliability of the transistor 200 can be improved.

By the heat treatment, hydrogen contained in the insulator 216, the insulating film 224f, and the oxide semiconductor film 230f is transferred to the insulator 222 and is absorbed by the insulator 222. In other words, hydrogen contained in the insulator 216, the insulating film 224f, and the oxide semiconductor film 230f diffuses into the insulator 222. Accordingly, the hydrogen concentration in the insulator 222 increases, whereas the hydrogen concentrations in the insulator 216, the insulating film 224f, and the oxide semiconductor film 230f decrease. Note that the insulator 221 is provided in contact with the bottom surface of the insulator 222, whereby entry of impurities such as moisture or hydrogen from below the insulator 221, which is caused by the heat treatment, can be prevented.

Specifically, the insulating film 224f (to be the insulator 224 later) functions as the second gate insulator of the transistor 200, and the oxide semiconductor film 230f (to be the oxide semiconductor 230 later) function as the channel formation region of the transistor 200. Thus, the transistor 200 including the insulating film 224f and the oxide semiconductor film 230f with reduced hydrogen concentrations is preferable because of its favorable reliability.

Next, a conductive film 242f is formed over the oxide semiconductor film 230f (see FIGS. 12A to 12D). As the conductive film 242f, a conductor corresponding to the conductors 242a and 242b is used. The conductive film 242f is formed over and in contact with the oxide semiconductor film 230f without an etching step or the like performed after the formation of the oxide semiconductor film 230f, so that the top surface of the oxide semiconductor film 230f can be protected by the conductive film 242f. Thus, diffusion of impurities into the oxide semiconductor 230 included in the transistor can be reduced, so that the electrical characteristics and reliability of the semiconductor device can be improved.

The conductive film 242f can be formed by a sputtering method, a CVD method, an MBE method, a PLD method, an ALD method, or the like.

In this embodiment, tantalum nitride is formed as the conductive film 242f by a sputtering method. Note that heat treatment may be performed before the formation of the conductive film 242f. The heat treatment may be performed under a reduced pressure, and the conductive film 242f may be successively deposited without exposure to the air. By such treatment, moisture and hydrogen adsorbed on the surface of the oxide semiconductor 230 can be removed, and the moisture concentration and the hydrogen concentration in the oxide semiconductor 230 can be reduced. The temperature of the heat treatment is preferably higher than or equal to 100° C. and lower than or equal to 400° C.

Next, an insulating film 271f is formed over the conductive film 242f (see FIGS. 12A to 12D). The insulating film 271f can be formed by a sputtering method, a CVD method, an MBE method, a PLD method, an ALD method, or the like. The insulating film 271f is preferably an insulating film having a function of inhibiting transmission of oxygen. For example, a stacked-layer film of a silicon nitride film and a silicon oxide film over the silicon nitride film can be formed as the insulating film 271f by a sputtering method. With such a structure, the insulator 271a (or the insulator 271b) can have a stacked-layer structure of the insulator 271al (or the insulator 271b1) of silicon nitride and the insulator 271a2 (or the insulator 271b2) of silicon oxide.

Here, in the case where the insulating film 271f is formed by stacking films, the films are preferably formed successively without exposure to the air. By the film formation without exposure to the air, an interface between the stacked films of the insulating film 271f or the vicinity thereof can be kept clean. It is further preferable to form the components from the conductive film 242f to the insulating film 271f successively without exposure to the air.

Note that heat treatment may be performed before the formation of the insulating film 271f. The heat treatment may be performed under a reduced pressure, and the insulating film 271f may be successively formed without exposure to the air. Such treatment can remove moisture and hydrogen adsorbed on the surface of the conductive film 242f and reduce the moisture concentration and the hydrogen concentration in the conductive film 242f. The temperature of the heat treatment is preferably higher than or equal to 100° C. and lower than or equal to 400° C.

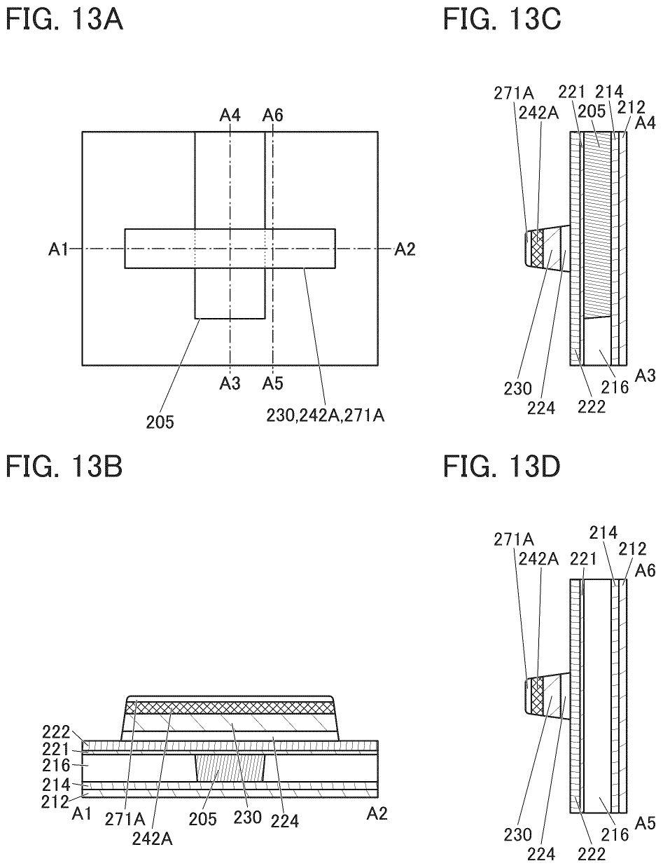

Next, the insulating film 224f, the oxide semiconductor film 230f, the conductive film 242f, and the insulating film 271f are processed into island shapes by a lithography method, so that the insulator 224, the oxide semiconductor 230, a conductor 242A, and an insulator 271A are formed (see FIGS. 13A to 13D).

The processing can be performed by a dry etching method or a wet etching method. A dry etching method is suitable for microfabrication. The insulating film 224f, the oxide semiconductor film 230f, the conductive film 242f, and the insulating film 271f may be processed under different conditions.

Here, the insulator 224, the oxide semiconductor 230, the conductor 242A, and the insulator 271A are preferably processed into an island shape at one time. In that case, the side end portion of the conductor 242A is preferably aligned or substantially aligned with the side end portion of the oxide semiconductor 230. Furthermore, the side end portion of the insulator 224 is preferably aligned or substantially aligned with the side end portion of the oxide semiconductor 230. The side end portion of the insulator 271A is preferably aligned or substantially aligned with the side end portion of the conductor 242A. With such a structure, the number of steps for the semiconductor device of one embodiment of the present invention can be reduced. Therefore, a method of manufacturing a semiconductor device with high productivity can be provided.

The insulator 224, the oxide semiconductor 230, the conductor 242A, and the insulator 271A are formed to at least partly overlap with the conductor 205. The insulator 222 is exposed in a region not overlapping with the insulator 224, the oxide semiconductor 230, the conductor 242A, or the insulator 271A. However, without limitation to this structure, the insulator 224 can remain over the insulator 222 in a region not overlapping with the oxide semiconductor 230. In this case, the insulator 224 a shape in which an opening is partly formed as in the transistor 200 in FIGS. 9A to 9D, instead of having an island shape.

As illustrated in FIGS. 13B to 13D, the side surfaces of the insulator 224, the oxide semiconductor 230, the conductor 242A, and the insulator 271A may be formed to have tapered shapes. The taper angle of the side surfaces of the insulator 224, the oxide semiconductor 230, the conductor 242A, and the insulator 271A may be, for example, greater than or equal to 60° and less than 90°. With such tapered side surfaces, the coverage with the insulator 275 and the like can be improved in a later step, so that the number of defects such as voids can be reduced.

Not being limited to the above, the insulator 224, the oxide semiconductor 230, the conductor 242A, and the insulator 271A may have side surfaces that are perpendicular or substantially perpendicular to the top surface of the insulator 222. This structure enables a plurality of transistors to be provided in a small area at high density.

In the lithography method, first, a resist is exposed to light through a mask. Next, a region exposed to light is removed or left using a developing solution, so that a resist mask is formed. Then, etching is conducted with the resist mask, whereby a conductor, a semiconductor, an insulator, or the like can be processed into a desired shape. For example, the resist mask can be formed by exposing the resist to e.g., KrF excimer laser light, ArF excimer laser light, or extreme ultraviolet (EUV) light. A liquid immersion technique may be employed in which a portion between a substrate and a projection lens is filled with a liquid (e.g., water) to perform light exposure. An electron beam or an ion beam may be used instead of the above-mentioned light. Note that a photomask may be unnecessary in the case of using an electron beam or an ion beam in some cases.

To remove the resist mask which is no longer needed after the processing, dry etching treatment such as ashing using oxygen plasma (hereinafter referred to as oxygen plasma treatment in some cases) or wet etching treatment may be used. Alternatively, wet etching treatment may be performed after dry etching treatment, or dry etching treatment may be performed after wet etching treatment.

A hard mask formed of an insulator or a conductor may be used under the resist mask. In the case of using a hard mask, a hard mask with a desired shape can be formed in the following manner: an insulating film or a conductive film that is the material of the hard mask is formed over the insulating film 271f, a resist mask is formed thereover, and then the hard mask material is etched. For example, tungsten may be used as the hard mask material. The etching of the insulating film 271f and the like may be performed after or without removal of the resist mask. In the latter case, the resist mask sometimes disappears during the etching. The hard mask may be removed by etching after the etching of the oxide semiconductor film 230f and the like. The hard mask does not need to be removed when the hard mask material does not affect the following process or can be utilized in the following process.

A spin on carbon (SOC) film and a spin on glass (SOG) film may be formed between an object to be processed and the resist mask. Using the SOC film and the SOG film as masks can improve the adhesion between the object to be processed and the resist mask and the durability of a mask pattern. For example, the SOC film, the SOG film, and the resist mask are formed in this order over the object to be processed and lithography can be performed.

An etching gas containing halogen can be used as a dry etching gas; specifically, an etching gas containing one or more of fluorine, chlorine, and bromine can be used. For example, as the etching gas, a C₄F₆ gas, a CsF₆ gas, a C₄F₈ gas, a CF₄ gas, a SF₆ gas, a CHF₃ gas, a CH₂F₂ gas, a Cl₂ gas, a BC₁₃ gas, a SiCl₄ gas, a BBr₃ gas, or the like can be used alone or in combination. To the above etching gas, an oxygen gas, a carbon dioxide gas, a nitrogen gas, a helium gas, an argon gas, a hydrogen gas, a hydrocarbon gas, or the like can be added as appropriate. Depending on an object to be subjected to the dry etching, a gas containing a hydrocarbon gas or a hydrogen gas and not containing a halogen gas can be used as the etching gas. As the hydrocarbon used for the etching gas, one or more of methane (CH₄), ethane (C₂H₆), propane (C₃H₈), butane (C₄H₁₀), ethylene (C₂H₄), propylene (C₃H₆), acetylene (C₂H₂), and propyne (C₃H₄) can be used. The etching conditions can be set as appropriate depending on an object to be etched.

As a dry etching apparatus, a capacitively coupled plasma (CCP) etching apparatus including parallel plate electrodes can be used. The capacitively coupled plasma etching apparatus including parallel plate electrodes can have a structure where a high-frequency voltage is applied to one of the parallel plate electrodes. Further alternatively, high-frequency voltages with the same frequency can be applied to the parallel plate electrodes. Alternatively, different high-frequency voltages can be applied to the parallel plate electrodes. Such a CCP etching apparatus is referred to as a dual frequency capacitively coupled plasma (DF-CCP) etching apparatus. In the DF-CCP etching apparatus, high-frequency voltages with different frequencies can be applied to the parallel plate electrodes. Alternatively, the capacitively coupled plasma apparatus can have a structure in which different high-frequency voltages are applied to one of the parallel plate type electrodes. A dry etching apparatus including a high-density plasma source can be used. As the dry etching apparatus including a high-density plasma source, an inductively coupled plasma (ICP) etching apparatus can be used, for example. The etching apparatus can be set as appropriate depending on an object to be etched. Note that in the above dry etching apparatus, a high-frequency voltage is applied to the electrode on the substrate side to generate a self-bias potential, whereby reactive ion etching can be performed. In reactive ion etching, ion species in plasma are accelerated to collide with an object to be processed, whereby etching with high anisotropy can be performed.

In the above etching process, the insulator 271A can function as an etching stopper that protects the conductor 242A. For example, a metallic hard mask over the insulator 271A in the above etching process makes it difficult to obtain the etching selectivity of the hard mask to the conductor 242A at the time of removing the hard mask in some cases. However, when the insulator 271A is formed over the conductor 242A, the insulator 271A can function as an etching stopper that protects the conductor 242A in the etching for removing the hard mask. This can prevent formation of a curved surface between the side surface and a top surface of the conductor 242A, and thus the end portion at the intersection of the side surface and the top surface of each of the conductors 242a and 242b to be formed later is angular as illustrated in FIG. 7D. The cross-sectional area of the conductor 242A is larger in the case where an end portion at the intersection of the side surface and the top surface of the conductor 242A is angular than in the case where the end portion is rounded. Furthermore, when nitride insulator that is less likely to oxidize metal is used for the insulator 271A, excessive oxidation of the conductor 242A can be prevented. Thus, the resistance of the conductors 242a and 242b is reduced, so that the on-state current of the transistor can be increased.

By processing the insulator 224 into an island shape, the insulator 275 can be provided in contact with the side surface of the insulator 224 and the top surface of the insulator 222 in a step to be described later. That is, the insulator 224 can be isolated from the insulator 280 by the insulator 275. Such a structure can prevent an excess amount oxygen and impurities such as hydrogen from entering the oxide semiconductor 230 from the insulator 280 through the insulator 224.

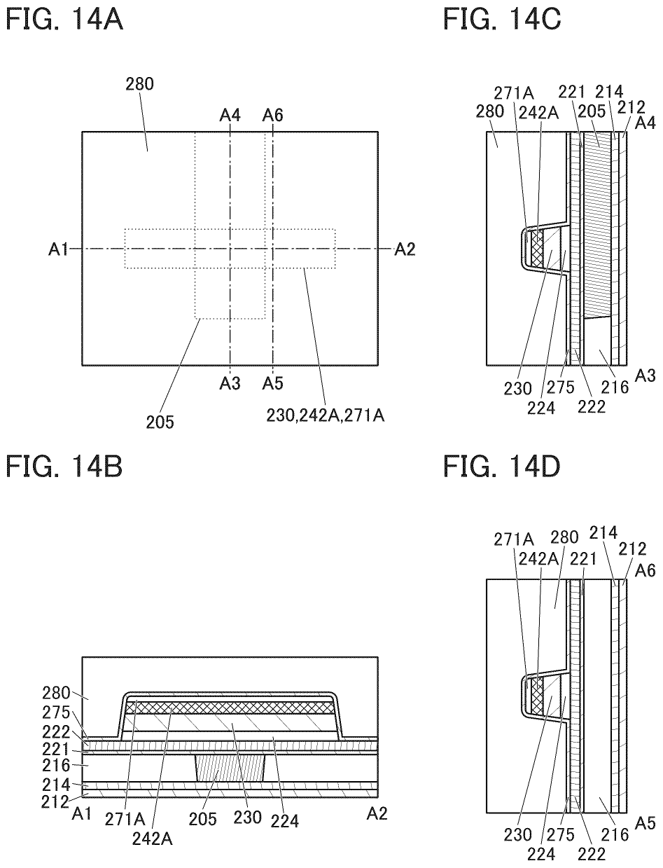

Next, the insulator 275 is formed to cover the insulator 224, the oxide semiconductor 230, the conductor 242A, and the insulator 271A, and the insulator 280 is formed over the insulator 275 (see FIGS. 14A to 14D). The above-described insulating materials can be used as the insulators 275 and 280.

Here, the insulator 275 is preferably in contact with the top surface of the insulator 222.

As the insulator 280, an insulator having a flat top surface is preferably formed in the following manner: an insulating film to be the insulator 280 is formed and then the insulating film is subjected to CMP treatment. Note that silicon nitride may be deposited over the insulator 280 by a sputtering method, for example, and then subjected to CMP treatment until the insulator 280 is exposed.

Each of the insulator 275 and the insulator 280 can be formed by a sputtering method, a CVD method, an MBE method, a PLD method, or an ALD method.

The insulator 275 is preferably formed using an insulator having a function of inhibiting transmission of oxygen. For example, silicon nitride is preferably deposited by a PEALD method as the insulator 275. Alternatively, as the insulator 275, aluminum oxide may be deposited by a sputtering method and silicon nitride may be deposited thereover by a PEALD method. When the insulator 275 has such a stacked-layer structure, the function of inhibiting diffusion of impurities such as water or hydrogen and oxygen can be improved.

In this manner, the oxide semiconductor 230 and the conductor 242A can be covered with the insulator 275 having a function of inhibiting diffusion of oxygen. This can inhibit direct diffusion of oxygen from the insulator 280 and the like into the oxide semiconductor 230 and the conductor 242A in a later step.

Silicon oxide is preferably deposited by a sputtering method as the insulator 280. When an insulating film to be the insulator 280 is deposited by a sputtering method in an oxygen-containing atmosphere, the insulator 280 containing excess oxygen can be formed. Since a molecule containing hydrogen is not used as a deposition gas in the sputtering method, the concentration of hydrogen in the insulator 280 can be reduced. Note that heat treatment may be performed before the formation of the insulating film. The heat treatment may be performed under a reduced pressure, and the insulating film may be successively formed without exposure to the air. Such treatment can remove moisture and hydrogen adsorbed on the surface of the insulator 275 and the like. The heat treatment can be performed under the above-described heat treatment conditions.

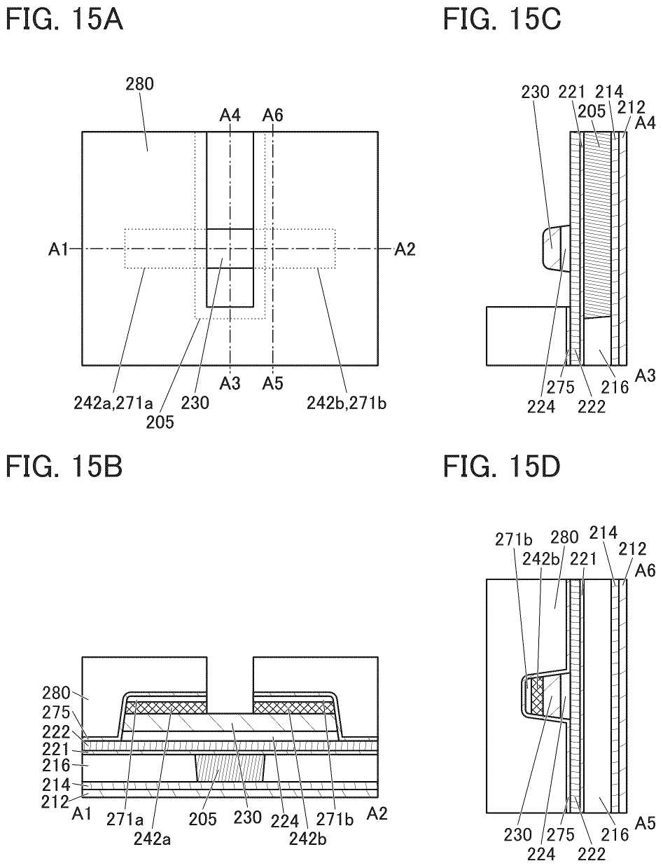

Next, the conductor 242A, the insulator 271A, the insulator 275, and the insulator 280 are processed by lithography to form an opening reaching the oxide semiconductor 230 and the insulator 222 (see FIGS. 15A to 15D). Here, the conductor 242A is divided into the conductors 242a and 242b and the insulator 271A is divided into the insulators 271a and 271b. The opening formed in the insulator 280 and the insulator 275 overlaps with the oxide semiconductor 230 and the conductor 205.

The above-described method can be used as appropriate as the lithography. In order to process the opening in the insulator 280 finely, an electron beam or short-wavelength light such as EUV light is preferably used for the lithography. For example, an opening can be formed in the insulator 280 and the conductors 242a and 242b can be formed by the method illustrated in FIGS. 16A1 to 16D2.

First, a coating film 277 is formed over the insulator 280, and a coating film 278 is formed thereover (see FIGS. 16A1 and 16A2). The coating films 277 and 278 may have a function of improving adhesion between a resist mask described later and the insulator 280. The coating films 277 and 278 may be formed by a spin coating method, for example. For the coating films 277 and 278, a non-photosensitive organic resin may be used.

Here, the coating film 278 functions as a mask in etching treatment for processing the coating film 277. Therefore, the etching rate of the coating film 278 is preferably lower than that of the coating film 277 under the etching conditions of the coating film 277. For example, the coating film 277 can be a film containing carbon, and the coating film 278 can be a film containing silicon and carbon. In this embodiment, an SOC film is formed as the coating film 277, and an SOG film is formed as the coating film 278.

Note that the coating films 277 and 278 each contain an organic solvent such as alcohol at the time of application, but such an organic substance contained may be reduced or removed in later steps or when the semiconductor device is completed. Note that the coating films may be provided as necessary, the coating films may be a single layer, or is not necessarily provided in the case where a desired function can be obtained only with a resist mask to be described later.

Next, a resist mask 279 having an opening is formed over the coating film 278 by a lithography method (see FIGS. 16A1 and 16A2). For example, the resist mask 279 can be formed by exposing the resist to e.g., KrF excimer laser light, ArF excimer laser light, or extreme ultraviolet (EUV) light. A liquid immersion technique may be employed in which a portion between a substrate and a projection lens is filled with a liquid (e.g., water) to perform light exposure. An electron beam or an ion beam may be used instead of the above-mentioned light. Note that a mask may be unnecessary in the case of using an electron beam or an ion beam in some cases.

Hereinafter, in the steps of FIGS. 16B1 to 16D2, the object to be processed is preferably processed by a dry etching method. The dry etching method enables anisotropic etching and thus is suitable for forming an opening with a high aspect ratio. In the case of performing anisotropic etching, reactive ion etching is preferably performed, for example. Note that the above description can be referred to for the conditions and an apparatus for the dry etching method. Note that the steps in FIGS. 16B1 to 16D2 are preferably performed successively without exposure to the air. For example, the processing may be performed with use of a multi-chamber etching apparatus without exposure to the air.

First, the coating film 278 is processed using the resist mask 279, so that the coating film 278 having an opening is formed. For example, in the case where an SOG film is used as the coating film 278, etching treatment can be performed using CF₄ as an etching gas with a DF-CCP etching apparatus.

Next, the coating film 277 is processed using the coating film 278 as a mask to form the coating film 277 having an opening (see FIGS. 16B1 and 16B2). For example, in the case where an SOC film is used as the coating film 277, etching treatment can be performed using H₂ and N₂ as etching gases with a DF-CCP etching apparatus. Here, an SOG film is used as the coating film 278, so that the coating film 278 can be prevented from disappearing in the etching step of the coating film 277.

The resist mask 279 is preferably removed during the processing of the coating film 277. Since an SOC film is used as the coating film 277, the resist mask 279 can be easily removed. In the case where the resist mask 279 remains after the formation of the coating film 277, the resist mask 279 is preferably removed.

Then, the insulator 280 is processed using the coating film 277 as a mask, so that the insulator 280 having an opening is formed. For example, in the case where a silicon oxide film is used as the insulator 280, etching treatment can be performed using C₄F₈, C₄F₆, O₂, and Ar as etching gases with a DF-CCP etching apparatus.

Furthermore, the insulator 275 and the insulator 271A are processed using the coating film 277 as a mask to form the insulators 275, 271a, and 271b having an opening (see FIGS. 16C1 and 16C2). For example, in the case where a silicon oxide film and a silicon nitride film are used as the insulators 275 and 271A, etching treatment can be performed using CH₂F₂, O₂, and Ar as etching gases with a DF-CCP etching apparatus. At this time, the conductor 242A and the insulator 222 can function as etching stoppers. The coating film 278 is preferably removed during the processing of the insulators 275 and 271A.

After the insulators 271a and 271b are formed, dry etching treatment such as ashing using oxygen plasma is preferably performed to remove the coating film 277. However, without limitation to this step, the coating film 277 may be removed after the conductors 242a and 242b are formed.

Next, a surface oxide film of the conductor 242A is preferably removed using the insulator 280 as a mask. In the case where tantalum nitride is used for the conductor 242A, etching can be performed using BCl₃ and Cl₂ as etching gases with an ICP etching apparatus, for example.

Furthermore, the conductor 242A is processed using the insulator 280 as a mask to form the conductors 242a and 242b (see FIGS. 16D1 and 16D2). In the case where a tantalum nitride film is used for the conductor 242A, etching can be performed using Cl₂ and Ar as etching gases with an ICP etching apparatus, for example. At this time, the oxide semiconductor 230 and the insulator 222 can function as etching stoppers. As illustrated in FIG. 16D2, a curved surface may be formed between the side and top surfaces of the oxide semiconductor 230 in a cross-sectional view in the channel width direction of the transistor 200. That is, an end portion of the side surface and an end portion of the top surface are rounded in some cases.

A depression is sometimes formed in a portion of the oxide semiconductor 230 that is exposed from the conductors 242a and 242b. In other words, in a top surface of the oxide semiconductor 230, the level of a region sandwiched between the conductors 242a and 242b is lower than the level of a region overlapping with the conductor 242a and the level of a region overlapping with the conductor 242b in some cases.

In the above manner, an opening can be formed in the insulators 275 and 280, and the insulators 271a and 271b and the conductors 242a and 242b can be formed.

Note that ashing treatment using oxygen plasma may be performed after the processing of the conductor 242A. Such oxygen plasma treatment can remove impurities generated by the etching and diffusing into the oxide semiconductor 230 or the like. The impurities are generated by a component of the object processed by the above etching and a component contained in a gas or the like used for the etching. Examples of the impurities include chlorine, fluorine, tantalum, silicon, and hafnium. Removal of impurities attached to the oxide semiconductor 230 in this manner can improve the electrical characteristics and reliability of the transistor.

The processing of the conductor 242A and the oxygen plasma treatment can be performed successively without exposure to the air. For example, the processing may be performed with use of a multi-chamber etching apparatus without exposure to the air.

In order to remove the impurities attached to the surface of the oxide semiconductor 230 in the etching step, cleaning treatment is preferably performed. Examples of the cleaning include wet cleaning using a cleaning solution or the like (also referred to as wet etching treatment), plasma treatment using plasma, and cleaning by heat treatment, and any of these cleanings may be performed in combination as appropriate. The cleaning treatment sometimes makes the groove deeper.

The wet cleaning may be performed using an aqueous solution in which one or more of oxalic acid, phosphoric acid, and hydrofluoric acid are diluted with carbonated water or pure water, for example. The wet cleaning may be performed using an aqueous solution in which ammonia water is diluted with carbonated water or pure water. The wet cleaning may be performed using pure water, carbonated water, or the like. Alternatively, ultrasonic cleaning using such an aqueous solution, pure water, or carbonated water may be performed. Further alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is preferably higher than or equal to 0.01% and lower than or equal to 5%, further preferably higher than or equal to 0.1% and lower than or equal to 0.5%. The concentration of hydrogen fluoride in the diluted hydrofluoric acid is preferably higher than or equal to 0.01 ppm and lower than or equal to 100 ppm, further preferably higher than or equal to 0.1 ppm and lower than or equal to 10 ppm.

A frequency greater than or equal to 200 kHz is preferably used for the ultrasonic cleaning, and a frequency greater than or equal to 900 kHz is further preferably used. Damage to the oxide semiconductor 230 and the like can be reduced with this frequency.

The cleaning treatment may be performed a plurality of times, and the cleaning solution may be changed in every cleaning treatment. For example, the first cleaning treatment may use diluted hydrofluoric acid or diluted ammonia water and the second cleaning treatment may use pure water or carbonated water.

In this embodiment, as the cleaning treatment, wet cleaning is performed with use of carbonated water. The cleaning treatment allows removing impurities that are attached onto the surfaces of the oxide semiconductor 230 and the like or diffused into the oxide semiconductor 230 and the like. Furthermore, the surface layer of the oxide semiconductor 230 that has been damaged by the above etching treatment can be removed.

After the etching or the cleaning, heat treatment is preferably performed. The heat treatment temperature is, for example, higher than or equal to 100° C. and lower than or equal to 650° C., preferably higher than or equal to 250° C. and lower than or equal to 600° C., further preferably higher than or equal to 300° C. and lower than or equal to 550° C., still further preferably higher than or equal to 350° C. and lower than or equal to 400° C. Note that the heat treatment is performed in a nitrogen gas atmosphere, an inert gas atmosphere, or an atmosphere containing an oxidizing gas at 10 ppm or more, 1% or more, or 10% or more. The heat treatment is preferably in an atmosphere containing oxygen. For example, the heat treatment is preferably performed at the nitrogen:oxygen gas flow rate ratio of 4:1 at a temperature of 350° C. for one hour. Accordingly, oxygen can be supplied to the oxide semiconductor 230 to reduce oxygen vacancies. In addition, the crystallinity of the oxide semiconductor 230 can be improved by the heat treatment. Furthermore, hydrogen remaining in the oxide semiconductor 230 reacts with supplied oxygen, so that the hydrogen can be removed as H₂O (dehydration). This can inhibit recombination of hydrogen remaining in the oxide semiconductor 230 with oxygen vacancies and formation of V_{O}H. Accordingly, a transistor including the oxide semiconductor 230 can have favorable electrical characteristics and high reliability. In addition, variations in electrical characteristics of transistors formed over the same substrate can be reduced. The heat treatment may be performed under a reduced pressure. Alternatively, the heat treatment may be performed as follows: heat treatment is performed in an oxygen atmosphere, and then another heat treatment is successively performed in a nitrogen atmosphere without exposure to the air. The heat treatment can also serve as the heat treatment described in Embodiment 1. Thus, the crystal region of the oxide semiconductor 230 grows through the heat treatment in some cases.

In the case where heat treatment is performed in a state where the oxide semiconductor 230 is in contact with the conductors 242a and 242b, the sheet resistance is sometimes reduced in each of a region of the oxide semiconductor 230 which overlaps with the conductor 242a and a region of the oxide semiconductor 230 which overlaps with the conductor 242b. In addition, the carrier concentration may be increased. Thus, the resistance of each of the region of the oxide semiconductor 230 which overlaps with the conductor 242a and the region of the oxide semiconductor 230 which overlaps with the conductor 242b can be lowered in a self-aligned manner.

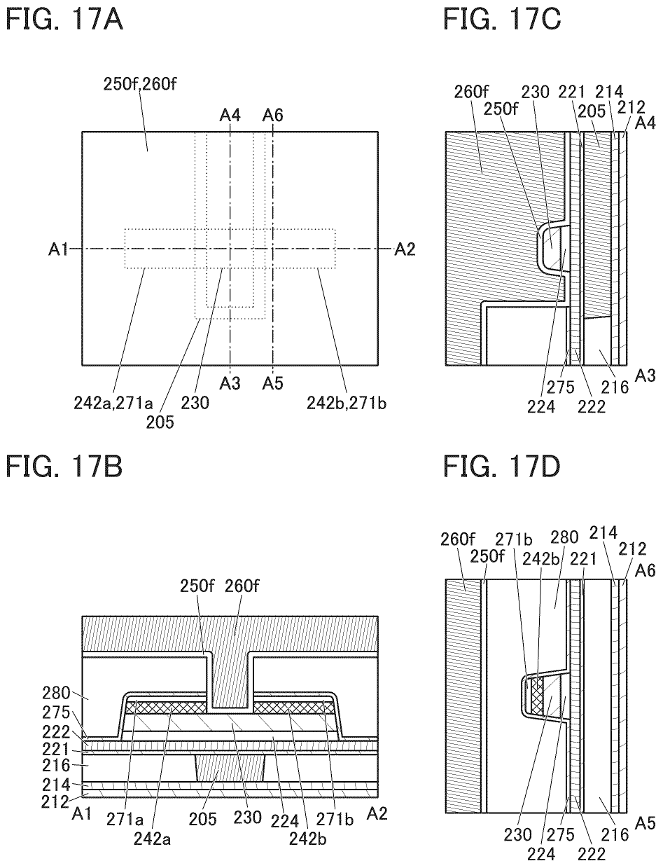

Next, an insulating film 250f to be the insulator 250 is formed to cover the opening formed in the insulator 280 and the like (see FIGS. 17A to 17D). Here, the insulating film 250f is formed along the opening of the insulators 280 and 275. Here, the insulating film 250f is in contact with the insulator 280, the conductors 242a and 242b, the insulators 222 and 224, and the oxide semiconductor 230.

The insulating film 250f can be formed by a sputtering method, a CVD method, an MBE method, a PLD method, an ALD method, or the like. For example, the insulating film 250f is preferably formed by an ALD method. As described above, it is preferable to form the insulating film 250f to have a small thickness, and an unevenness of the thickness needs to be reduced. In the ALD method, a precursor and a reactant (such as oxidizer) are alternately introduced to deposit a film, and the film thickness can be adjusted depending on the number of repetition times of the introduction steps; thus, accurate control of the film thickness is possible. In addition, the insulating film 250f needs to be formed on the bottom surface and the side surface of the opening so as to have good coverage. An atomic layer can be deposited one by one the bottom and side surfaces of the opening by the ALD method, whereby the insulating film 250f can be formed in the opening with good coverage.

When the insulating film 250f is deposited by an ALD method, ozone (O₃), oxygen (O₂), water (H₂O), or the like is used as the oxidizer. When an oxidizer without hydrogen, such as ozone (O₃) or oxygen (O₂), is used, the amount of hydrogen diffusing into the oxide semiconductor 230 can be reduced.

The insulator 250 can have a stacked-layer structure as illustrated in FIG. 8B and the like. A method of forming the insulating film 250f in the case where the insulator 250 has a four-layer structure of insulators 250a, 250b, 250d, and 250c as in FIG. 8B will be described below.

First, a film to be the insulator 250a is formed to cover the opening formed in the insulator 280 and the like, and a film to be the insulator 250b is formed over the film to be the insulator 250a and the like. In this embodiment, aluminum oxide is deposited as the film to be the insulator 250a by a thermal ALD method and silicon oxide is deposited as the film to be the insulator 250b by a PEALD method.

Next, microwave treatment is preferably performed in an oxygen-containing atmosphere. Here, the microwave treatment refers to, for example, treatment using an apparatus including a power source for generating high-density plasma using microwaves. Note that in this specification and the like, a microwave refers to an electromagnetic wave having a frequency higher than or equal to 300 MHz and lower than or equal to 300 GHz.

The microwave treatment is preferably performed with a microwave treatment apparatus including a power source for generating high-density plasma using microwaves, for example. Here, the frequency of the microwave treatment apparatus is preferably set to higher than or equal to 300 MHz and lower than or equal to 300 GHz, further preferably higher than or equal to 2.4 GHz and lower than or equal to 2.5 GHZ, and can be 2.45 GHz, for example. Oxygen radicals at a high density can be generated with high-density plasma. The electric power of the power source that applies microwaves of the microwave treatment apparatus is preferably set to higher than or equal to 1000 W and lower than or equal to 10000 W, further preferably higher than or equal to 2000 W and lower than or equal to 5000 W. A power source may be provided to the microwave treatment apparatus to apply RF to the substrate side. Furthermore, application of RF to the substrate side allows oxygen ions generated by the high-density plasma to permeate the oxide semiconductor 230 efficiently.

The microwave treatment is preferably performed under a reduced pressure, and the pressure is preferably higher than or equal to 10 Pa and lower than or equal to 1000 Pa, further preferably higher than or equal to 300 Pa and lower than or equal to 700 Pa. The treatment temperature is preferably lower than or equal to 750° C., further preferably lower than or equal to 500° C., and can be approximately 250° C., for example. The oxygen plasma treatment can be followed successively by heat treatment without exposure to the air. The heat treatment temperature is preferably, for example, higher than or equal to 100° C. and lower than or equal to 750° C., further preferably higher than or equal to 300° C. and lower than or equal to 500° C.

Furthermore, the microwave treatment can be performed using an oxygen gas and an argon gas, for example. Here, the oxygen flow rate ratio (O₂/O₂+Ar) is higher than 0% and lower than or equal to 100%. The oxygen flow rate ratio (O₂/O₂+Ar) is preferably higher than 0% and lower than or equal to 50%. The oxygen flow rate ratio (O₂/O₂+Ar) is further preferably higher than or equal to 10% and lower than or equal to 40%. The oxygen flow rate ratio (O₂/O₂+Ar) is still further preferably higher than or equal to 10% and lower than or equal to 30%. The carrier concentration of the region exposed from the oxide semiconductor 230 can be reduced by thus performing the microwave treatment in an atmosphere containing oxygen. In addition, the carrier concentrations in the oxide semiconductor 230 can be prevented from being excessively reduced by preventing an excessive amount of oxygen from being introduced into the chamber in the microwave treatment.

The microwave treatment in an atmosphere containing oxygen converts an oxygen gas into plasma using a high-frequency wave such as microwave or RF, and applies the oxygen plasma to a region of the oxide semiconductor 230 that is between the conductor 242a and the conductor 242b. By the effects of plasma, microwave, and the like, V_{O}H in the region can be divided into oxygen vacancies and hydrogen, and hydrogen can be removed from the region. Here, in the case of the structure illustrated in FIG. 8B and the like, an insulating film (e.g., aluminum oxide) having a function of capturing or fixing hydrogen is preferably used as the insulator 250a. With such a structure, hydrogen generated by the microwave treatment can be captured or fixed in the film to be the insulator 250a. In this manner, the amount of V_{O}H contained in the channel formation region can be reduced. As a result, oxygen vacancies and V_{O}H in the channel formation region can be reduced to lower the carrier concentration. In addition, oxygen radicals generated by the oxygen plasma can be supplied to oxygen vacancies formed in the channel formation region, thereby further reducing oxygen vacancies and lowering the carrier concentration in the channel formation region.

Oxygen supplied into the channel formation region has a variety of forms such as an oxygen atom, an oxygen molecule, an oxygen ion, and an oxygen radical (also referred to as O radical which is an atom, a molecule or an ion having an unpaired electron). The oxygen supplied to the channel formation region preferably has one or more of the above forms. An oxygen radical is particularly preferable. In addition, the insulator 250 can have improved film quality, which increases the reliability of the transistor.

In contrast, the oxide semiconductor 230 includes a region overlapping with the conductor 242a or 242b. The region can function as a source region or a drain region. Here, the conductors 242a and 242b preferably function as a blocking film preventing the effect of the microwave, the high-frequency wave such as RF, the oxygen plasma, or the like in the microwave treatment in an atmosphere containing oxygen. Therefore, the conductors 242a and 242b preferably have a function of blocking an electromagnetic wave greater than or equal to 300 MHz and less than or equal to 300 GHz, for example, greater than or equal to 2.4 GHz and less than or equal to 2.5 GHz.

Since the conductors 242a and 242b prevents the effect of the microwave, the high-frequency wave such as RF, the oxygen plasma, or the like, the effect does not reach the region of the oxide semiconductor 230 which overlaps with the conductor 242a or 242b. Hence, a reduction in V_{O}H and supply of an excessive amount of oxygen do not occur in the source and drain regions, preventing a decrease in carrier concentration.

In the above manner, oxygen vacancies and V_{O}H can be selectively removed from the channel formation region in the oxide semiconductor, whereby the channel formation region can be an i-type or substantially i-type region. Furthermore, supply of an excess amount of oxygen to the regions functioning as the source region and the drain region can be inhibited and the conductivity (low-resistance regions) before the microwave treatment can be maintained. As a result, a change in the electrical characteristics of the transistor can be inhibited, and thus variation in the electrical characteristics of the transistors in the substrate plane can be inhibited.

The microwave treatment improves the film qualities of the films to be insulators 250a and 250b, thereby inhibiting diffusion of hydrogen, water, impurities, and the like. Accordingly, hydrogen, water, impurities, and the like can be inhibited from diffusing into the oxide semiconductor 230 and the like through the insulator 250 in steps to be performed later, e.g., formation of a conductive film to be the conductor 260 or heat treatment. By improving the film quality of the insulator 250 as described above, the reliability of the transistor can be improved.

Next, a film to be the insulator 250d is formed over the film to be the insulator 250b. In this embodiment, hafnium oxide can be deposited by a thermal ALD method as the film to be the insulator 250d. After the film to be the insulator 250d is deposited, microwave treatment may be performed again.

Next, a film to be the insulator 250c is formed over the film to be the insulator 250d. In this embodiment, silicon nitride is deposited for the film to be the insulator 250c by a PEALD method. In this manner, the insulating film 250f including the films to be the insulators 250a to 250d can be formed.

Although an example in which microwave treatment is performed after the formation of the film to the insulator 250b and the formation of the film to be the insulator 250d is described above, the present invention is not limited to the example. After the formation of the film to be the insulator 250c, the microwave treatment can be performed. Alternatively, before the formation of the film to be the insulator 250a, the microwave treatment can be performed. Alternatively, microwave treatment may be performed three or more times. The microwave treatment can also serve as the heat treatment described in Embodiment 1 in some cases. Thus, the crystal region of the oxide semiconductor 230 grows through the microwave treatment in some cases.

After the microwave treatment, heat treatment may be performed with the reduced pressure being maintained. Such treatment enables hydrogen in the insulating film and the oxide semiconductor 230 to be removed efficiently. Alternatively, the step of performing microwave treatment and then performing heat treatment with the reduced pressure being maintained may be repeated a plurality of cycles. The repetition of the heat treatment enables hydrogen in the insulating film and the oxide semiconductor 230 to be removed more efficiently. Note that the temperature of the heat treatment is preferably higher than or equal to 300° C. and lower than or equal to 500° C. The heat treatment can also serve as the heat treatment described in Embodiment 1. Thus, the crystal region of the oxide semiconductor 230 grows through the heat treatment in some cases.

Next, a conductive film 260f to be the conductor 260 is formed (see FIGS. 17A to 17D). The conductive film 260f can be formed using any of the above conductive materials by a sputtering method, a CVD method, an MBE method, a PLD method, a plating method, an ALD method, or the like. For example, a titanium nitride film and a tungsten film can be stacked by a CVD method. As illustrated in FIG. 8A, the conductor 260 can have a stacked-layer structure of the conductor 260a of titanium nitride and the conductor 260b of tungsten. Note that the conductive film 260f may be formed while the substrate is being heated. The substrate heating can also serve as the heat treatment described in Embodiment 1. Thus, the crystal region of the oxide semiconductor 230 grows by the substrate heating in some cases.

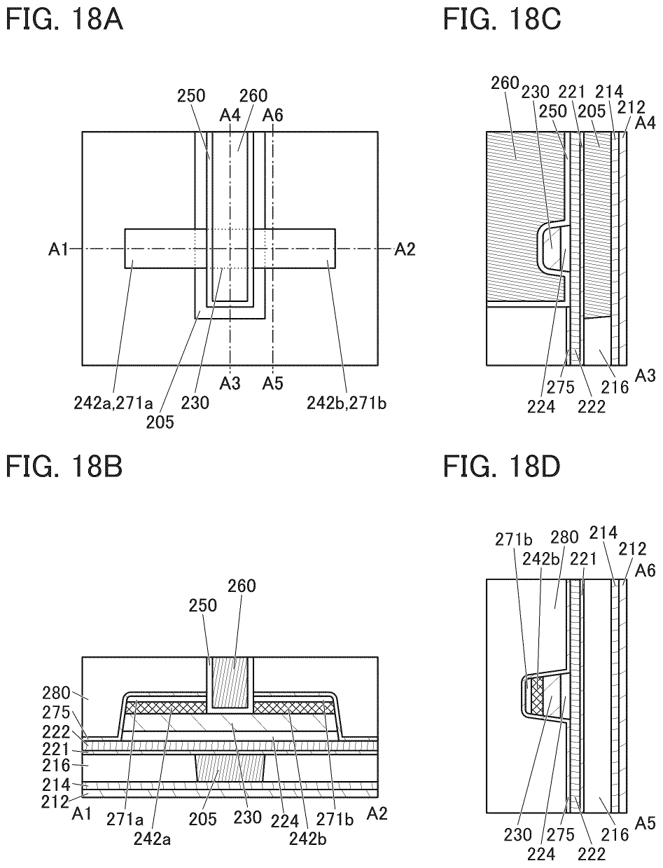

Then, the insulating film 250f and the conductive film 260f are polished by CMP treatment until the insulator 280 is exposed. That is, portions of the insulating film 250f and the conductive film 260f exposed from the opening are removed. Thus, the insulator 250 and the conductor 260 (the conductors 260a and 260b) are formed in the opening overlapping with the conductor 205 (see FIGS. 18A to 18D).

Thus, the insulator 250 is in contact with the conductors 242a and 242b, the oxide semiconductor 230, and the insulators 224 and 222 in the opening. The conductor 260 is positioned to fill the opening with the insulator 250 positioned therebetween. In this manner, the transistor 200 is formed.

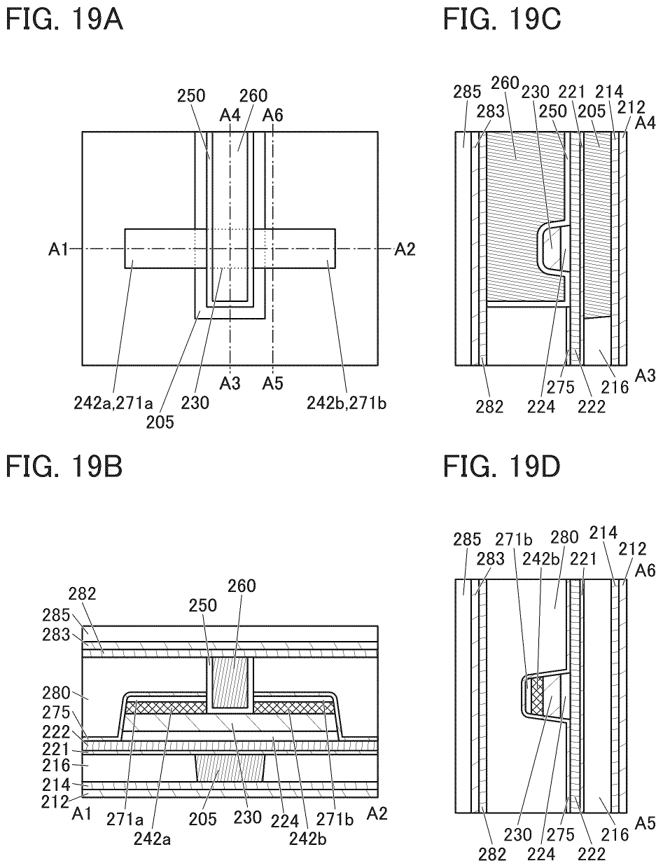

Next, the insulator 282 is formed over the insulator 250, the conductor 260, and the insulator 280 (see FIGS. 19A to 19D). The insulator 282 can be formed by a sputtering method, a CVD method, an MBE method, a PLD method, an ALD method, or the like. The insulator 282 is preferably formed by a sputtering method. Since a molecule containing hydrogen is not used as a deposition gas in the sputtering method, the concentration of hydrogen in the insulator 282 can be reduced.

As illustrated in FIG. 8A, the insulator 282 preferably has a stacked-layer structure of the insulators 282a and 282b. Here, the insulator 282a is preferably formed by an ALD method, and the insulator 282b is preferably formed by a sputtering method. In this embodiment, aluminum oxide can be deposited as the insulator 282a by a thermal ALD method. Furthermore, the thickness of the insulator 282a can be greater than or equal to 1 nm and less than or equal to 20 nm, preferably greater than or equal to 3 nm and less than or equal to 10 nm.

When the insulator 282a is formed by an ALD method, the insulator 282a can be formed without excessive damage to the formation surface. This can prevent excessive damage to the upper end portion of the insulator 250 and the top surface of the conductor 260, improving the electrical characteristics and reliability of the transistor 200.

When the insulator 282a is formed by an ALD method, the insulator 282a can be formed without adding oxygen to the insulator 280. In this manner, addition of an excess amount of oxygen to the insulator 280 can be inhibited. Thus, the reliability and electrical characteristics of the transistor 200 can be improved.

In this embodiment, aluminum oxide can be deposited as the insulator 282b by a sputtering method. Since a molecule containing hydrogen is not used as a deposition gas in the sputtering method, the concentration of hydrogen in the insulator 282 can be reduced.

Forming the insulator 282b in an atmosphere containing oxygen by a sputtering method can add oxygen to the insulator 280 during the formation. Thus, excess oxygen can be contained in the insulator 280. The formation of the insulator 282b is preferably performed while the substrate is heated. Here, when the insulator 282b is formed over the insulator 282a, oxygen is added through the insulator 282a; hence, the amount of oxygen supplied into the insulator 280 can be controlled. With a larger thickness of the insulator 282a, the addition of oxygen is more likely to be inhibited, and the amount of oxygen supplied into the insulator 280 is reduced. With a small thickness of the insulator 282a, the addition of oxygen is less likely to be inhibited and the amount of oxygen supplied into the insulator 280 is increased. For example, when the thickness of the insulator 282a is within the above range, an adequate amount of oxygen can be supplied to the oxide semiconductor 230, and an excessive amount of oxygen can be prevented from being supplied to the oxide semiconductor 230. Thus, the reliability and electrical characteristics of the transistor 200 can be improved. Note that in forming the insulator 282b, oxygen can be added not only to the insulator 280 but also to the upper end portion of the insulator 250.

When the insulator 282b is formed over the insulator 282a, the upper end portion of the insulator 250 and the top surface of the conductor 260 can be protected from an impact of ion collision caused by formation of the insulator 282b by sputtering.

The aluminum oxide is deposited using an aluminum target in an atmosphere containing an oxygen gas. The amount of oxygen supplied into the insulator 280 can be controlled depending on the amount of a bias power applied to the substrate in a sputtering method. For example, the amount of oxygen supplied into the insulator 280 is smaller as the bias power is lower, and the amount of oxygen is easily saturated even when the insulator 282b has a small thickness. Furthermore, as the bias power is higher, the amount of oxygen supplied into the insulator 280 increases. With lower bias power, the amount of oxygen supplied into the insulator 280 can be reduced. Note that in the case where the substrate bias is applied by an RF power source, the RF frequency is preferably higher than or equal to 10 MHz. The typical frequency is 13.56 MHz. The higher the RF frequency is, the less damage to the substrate can be.

Note that heat treatment may be performed before the formation of the insulator 282b. The heat treatment may be performed under a reduced pressure, and the insulator 282b may be successively formed without exposure to the air. Such treatment enables moisture and hydrogen adsorbed on the surface of the insulator 280 to be captured or fixed by the insulator 282a, so that the moisture concentration and the hydrogen concentration in the insulator 280 can be reduced. The temperature of the heat treatment is preferably higher than or equal to 100° C. and lower than or equal to 400° C. In this embodiment, the temperature of the heat treatment is 250° C.

Next, the insulator 283 is formed over the insulator 282 (see FIGS. 19A to 19D). The insulator 283 can be formed by a sputtering method, a CVD method, an MBE method, a PLD method, an ALD method, or the like. The insulator 283 is preferably formed by a sputtering method. Since a molecule containing hydrogen is not used as a deposition gas in the sputtering method, the concentration of hydrogen in the insulator 283 can be reduced. In this embodiment, silicon nitride is deposited as the insulator 283 by a sputtering method.

In this embodiment, silicon nitride is deposited as the insulator 283 by a sputtering method, and aluminum oxide is deposited as the insulator 282 by a thermal ALD method and a sputtering method. When silicon nitride having a function of inhibiting diffusion of hydrogen is used for the insulator 283 in this manner, diffusion of hydrogen from a layer above the transistor 200 can be inhibited. Furthermore, when aluminum oxide having a function of capturing or fixing hydrogen is used for the insulator 282, hydrogen contained in the insulator 280 or the like can be captured or fixed by the insulator 282. This reduces the hydrogen concentration in the oxide semiconductor 230 and in the vicinity thereof.

Next, the insulator 285 is formed over the insulator 283 (see FIGS. 19A to 19D). The insulator 285 can be formed by a sputtering method, a CVD method, an MBE method, a PLD method, an ALD method, or the like. The insulator 285 is preferably deposited by a sputtering method. Since a molecule containing hydrogen is not used for a deposition gas in the sputtering method, the concentration of hydrogen in the insulator 285 can be reduced. In this embodiment, silicon oxide is deposited as the insulator 285 by a sputtering method.

Here, it is preferable to form the insulators 282, 283, and 285 successively without exposure to the air. Film formation without exposure to the air can prevent attachment of impurities or moisture from the air onto the insulators 282, 283, and 285, so that an interface between the insulators 282 and 283, an interface between the insulators 283 and 285, and the vicinities of the interfaces can be kept clean.

Next, an opening reaching the conductor 242a is formed in the insulators 271a, 275, 280, 282, 283, and 285, and an opening reaching the conductor 242b is formed in the insulators 271b, 275, 280, 282, 283, and 285. The opening is formed by a lithography method. In the formation of the opening, an object to be processed is preferably processed by a dry etching method. Dry etching enables anisotropic etching and thus is suitable for forming an opening with a high aspect ratio. In the case of performing anisotropic etching, reactive ion etching is preferably performed, for example. Note that the above description can be referred to for the conditions and apparatus for the dry etching. Note that the shape of the opening in the top view can be a circular shape, an almost circular shape such as an elliptical shape, a polygonal shape such as a quadrangular shape, or a polygonal shape such as a quadrangular shape with rounded corners, for example.

Next, heat treatment is performed after the formation of the opening. The temperature of the heat treatment can be higher than or equal to 100° C. and lower than or equal to 600° C., preferably higher than or equal to 250° C. and lower than or equal to 550° C., further preferably higher than or equal to 350° C. and lower than or equal to 450° C. Note that the heat treatment is preferably performed in a nitrogen gas or inert gas atmosphere. The heat treatment is performed in a state where the conductors 242a and 242b are exposed, and thus the heat treatment is preferably performed in an atmosphere not containing an oxidizing gas or an oxygen gas. For example, heat treatment is preferably performed at 400° C. in a nitrogen gas atmosphere for one hour. The heat treatment may be performed under a reduced pressure. By the above heat treatment, oxygen contained in the insulator 280 can be supplied to the oxide semiconductor 230 through the insulator 250. Thus, oxygen vacancies in the channel formation region of the oxide semiconductor 230 can be reduced. The heat treatment can also serve as the heat treatment described in Embodiment 1. Thus, the crystal region of the oxide semiconductor 230 grows through the heat treatment in some cases.

Here, because the side surface of the insulator 280 is exposed in the opening, oxygen contained in the insulator 280 is diffused outwardly by the heat treatment, so that the amount of oxygen contained in the insulator 280 can be controlled. Meanwhile, since the insulators 282 and 283 each having a barrier property against oxygen are provided over the insulator 280, oxygen is not diffused outwardly from the top surface of the insulator 280. Accordingly, oxygen can be prevented from being excessively diffused from the insulator 280 outwardly and thus, oxygen vacancies can be prevented from being formed in the insulator 280. The oxide semiconductor 230 and the conductor 242a and 242b are covered with the insulator 275. This can prevent direct diffusion of an excess amount of oxygen from the insulator 280 to the oxide semiconductor 230 and the conductors 242a and 242b in the above heat treatment.

As described above, in the formation of the insulator 282b, oxygen is added to the insulator 280 through the insulator 282a, whereby the amount of oxygen added to the insulator 280 can be controlled. Furthermore, oxygen is diffused outwardly from the side surface of the insulator 280 by the heat treatment, whereby the amount of oxygen in the insulator 280 can be appropriate. In this manner, oxygen is supplied to the oxide semiconductor 230 from the insulator 280 whose amount of oxygen is adjusted, whereby an appropriate amount of oxygen can be supplied to the oxide semiconductor 230. Accordingly, oxygen vacancies in the oxide semiconductor 230 can be reduced, and an excess amount of oxygen can be prevented from being supplied to the oxide semiconductor 230. Thus, the reliability and electrical characteristics of the transistor 200 can be improved. Furthermore, a step of exposing the side surface of the insulator 280 can also serve as a step of forming an opening in which the conductors 240a and 240b are embedded; thus, the manufacturing process of the semiconductor device can be simplified.

By the heat treatment, hydrogen contained in the insulators 280 and 250 and the oxide semiconductor 230 moves to the insulator 282 and is captured in the insulator 282. In other words, hydrogen contained in the insulators 280 and 250 and the oxide semiconductor 230 diffuses into the insulator 282. Accordingly, the hydrogen concentration in the insulator 282 increases, whereas the hydrogen concentrations in the insulators 280 and 250 and the oxide semiconductor 230 decrease. Note that the insulator 283 is provided in contact with a top surface of the insulator 282, which can prevent entry of impurities such as moisture or hydrogen from a component above the insulator 283 in the heat treatment. By the heat treatment, hydrogen contained in the insulators 216 and 224 and the oxide semiconductor 230 moves to the insulator 222 and is captured in the insulator 222. In other words, hydrogen contained in the insulators 216 and 224 and the oxide semiconductor 230 diffuses into the insulator 222. Accordingly, the hydrogen concentration in the insulator 222 increases, whereas the hydrogen concentrations in the insulators 216 and 224 and the oxide semiconductor 230 decrease. Note that the insulator 221 is provided in contact with the bottom surface of the insulator 222 which can prevent entry of impurities such as moisture or hydrogen from a component below the insulator 221 in the heat treatment.

Next, an insulating film to be the insulators 241a and 241b is formed along the shape of the opening. The insulating film can be formed by a sputtering method, a CVD method, an MBE method, a PLD method, an ALD method, or the like. The insulating film to be the insulators 241a and 241b is formed in an opening having a high aspect ratio, and thus is preferably formed by an ALD method. The insulating film to be the insulators 241a and 241b preferably has a function of inhibiting the transmission of oxygen. For example, silicon nitride is preferably deposited by a PEALD method. Silicon nitride is preferable because it has high blocking property against hydrogen.

Next, the insulating film is etched anisotropically to form the insulators 241a and 241b. Here, the insulator 241a is formed to cover a sidewall of the opening over the conductor 242a, and the insulator 241b is formed to cover a sidewall of the opening over the conductor 242b. As an anisotropic etching for the insulating film to be the insulators 241a and 241b, a dry etching method may be performed, for example. For example, reactive ion etching is preferably performed. Providing the insulators 241a and 241b on the sidewall portion of the opening can inhibit entry of oxygen from the outside and can prevent oxidation of the conductors 240a and 240b formed in the next step. Furthermore, diffusion of impurities such as water or hydrogen contained in the insulator 280 or the like into the conductors 240a and 240b can be prevented. Note that a depressed portion is sometimes formed on part of the top surfaces of the conductors 242a and 242b by the anisotropic etching.

Next, a conductive film to be the conductors 240a and 240b is formed. The conductive film preferably has a stacked-layer structure including a conductor with a function of inhibiting passage of impurities such as water or hydrogen. For example, a stacked-layer structure of tantalum nitride, titanium nitride, or the like and tungsten, molybdenum, copper, or the like can be employed. The conductive film to be the conductors 240a and 240b can be formed by a sputtering method, a CVD method, an MBE method, a PLD method, an ALD method, or the like.

Next, the conductive film to be the conductors 240a and 240b is partly removed by CMP treatment to expose the top surface of the insulator 285. As a result, the conductive film remains only in the openings, whereby the conductors 240a and 240b having flat top surfaces can be formed (see FIGS. 7A to 7D). The CMP treatment may remove part of the top surface of the insulator 285.

Heat treatment may be further performed after the conductors 240a and 240b are formed. This heat treatment can be performed under the conditions similar to those for the above heat treatment. By the heat treatment, the amount of oxygen supplied to the oxide semiconductor 230 can be adjusted. Thus, the reliability and electrical characteristics of the transistor 200 can be improved.

Through the above steps, the semiconductor device illustrated in FIGS. 7A to 7D can be manufactured.

The semiconductor device of this embodiment includes an OS transistor. In this embodiment, when the oxide semiconductor layer of the OS transistor is formed using Axial Growth CAAC, a semiconductor device having favorable electrical characteristics can be provided. For example, the on-state current, the S value, the field-effect mobility, the frequency characteristics, and the like of the transistor can be improved. According to the above, a highly reliable semiconductor device can be provided.

This embodiment can be combined with any of the other embodiments as appropriate. In this specification, in the case where a plurality of structure examples are shown in one embodiment, the structure examples can be combined as appropriate.

### Embodiment 3

In this embodiment, a semiconductor device 900 of one embodiment of the present invention will be described. The semiconductor device 900 can function as a memory device.

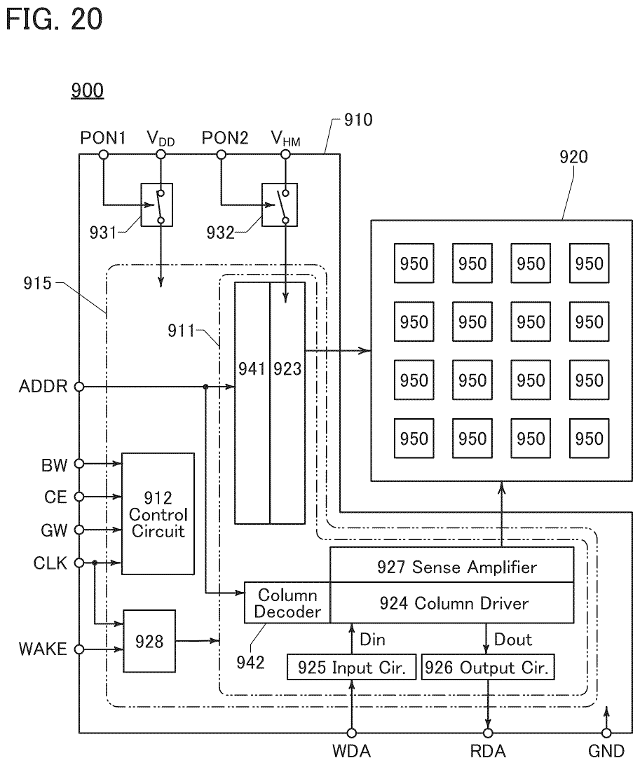

FIG. 20 is a block diagram illustrating a structure example of the semiconductor device 900. The semiconductor device 900 illustrated in FIG. 20 includes a driver circuit 910 and a memory array 920. The memory array 920 includes at least one memory cell 950. FIG. 20 illustrates an example in which the memory array 920 includes a plurality of memory cells 950 arranged in a matrix.

The transistor exemplified in Embodiment 2 can be used for the memory cell 950. With the use of the transistor, the operation speed of the memory device can be increased. This also enables further miniaturization or higher integration of the memory device. In addition, the capacity per area of the memory device can be increased.

The driver circuit 910 includes a power switch (PSW) 931, a PSW 932, and a peripheral circuit 915. The peripheral circuit 915 includes a peripheral circuit 911, a control circuit 912 (Control Circuit), and a voltage generator circuit 928.

In the semiconductor device 900, whether to provide or use each circuit, each signal, and each voltage can be selected as appropriate. Another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal. The signal GW is a global write enable signal. The signal BW is a byte write enable signal. The signal ADDR is an address signal. The signal WDA is a write data signal, and the signal RDA is a read data signal. The signals PON1 and PON2 are power gating control signals. Note that the signals PON1 and PON2 may be generated in the control circuit 912.

The control circuit 912 is a logic circuit having a function of controlling the overall operation of the semiconductor device 900. For example, the control circuit 912 performs logical operation on the signals CE, GW, and BW to determine the operating mode (e.g., write operation or read operation) of the semiconductor device 900. The control circuit 912 generates a control signal for the peripheral circuit 911 so that the operating mode is executed.

The voltage generator circuit 928 has a function of generating a negative voltage. The signal WAKE has a function of controlling the input of the signal CLK to the voltage generator circuit 928. For example, when an H-level signal is applied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941 (Row Decoder), a column decoder 942 (Column Decoder), a row driver 923 (Row Driver), a column driver 924 (Column Driver), an input circuit 925 (Input Cir.), an output circuit 926 (Output Cir.), and a sense amplifier 927 (Sense Amplifier).

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, reading data from the memory cell 950, and retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling the supply of V_{DD} to the peripheral circuit 915. The PSW 932 has a function of controlling the supply of V_{HM} to the row driver 923. Here, in the semiconductor device 900, a high power supply voltage is V_{DD} and a low power supply voltage is GND (ground potential). In addition, V_{HM} is a high power supply voltage used for setting a word line to a high level, and is higher than V_{DD}. The on/off state of the PSW 931 is controlled by the signal PON1, and the on/off state of the PSW 932 is controlled by the signal PON2. The number of power domains to which V_{DD} is supplied is one in the peripheral circuit 915 in FIG. 20 but can be more than one. In that case, a power switch is provided for each power domain.

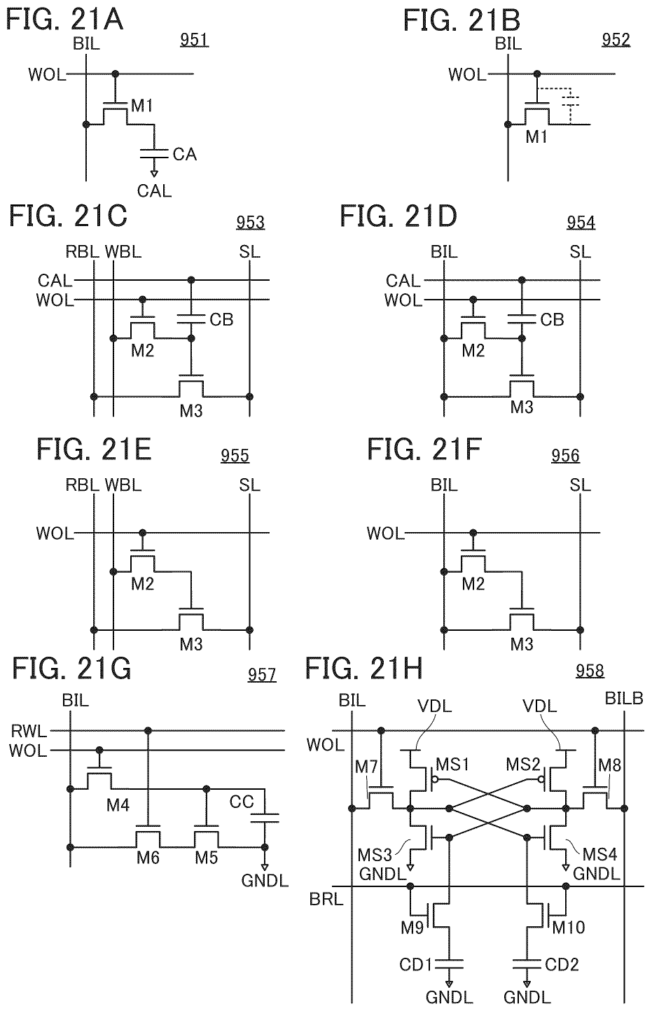

Structure examples of other memory cells each of which can be used as the memory cell 950 are described with reference to FIGS. 21A to 21H.

### [DOSRAM]

FIG. 21A illustrates a circuit structure example of a memory cell for a DRAM. In this specification and the like, a DRAM using an OS transistor is referred to as a dynamic oxide semiconductor random access memory (DOSRAM). A memory cell 951 includes the transistor M1 and the capacitor CA.

Note that the transistor M1 may include a front gate (simply referred to as a gate in some cases) and a back gate. The back gate may be connected to a wiring supplied with a constant potential or a signal. The front gate and the back gate may be connected to each other.

A first terminal of the transistor M1 is connected to a first terminal of the capacitor CA. A second terminal of the transistor M1 is connected to a wiring BIL. The gate of the transistor M1 is connected to a wiring WOL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. At the time of data writing and reading, a low-level potential (also referred to as a reference potential in some cases) is preferably applied to the wiring CAL.

Data writing and data reading are performed as follows: a high-level potential is applied to the wiring WOL to turn on the transistor M1, and thus the wiring BIL is connected to the first terminal of the capacitor CA.

The memory cell that can be used as the memory cell 950 is not limited to the memory cell 951, and the circuit structure can be changed. For example, the structure of a memory cell 952 illustrated in FIG. 21B may be employed. The memory cell 952 is an example including neither the capacitor CA nor the wiring CAL. The first terminal of the transistor M1 is in an electrically floating state.

In the memory cell 952, a potential written through the transistor M1 is retained in a capacitor (also referred to as parasitic capacitance) between the first terminal and the gate, which is shown by a dashed line. Thus, the structure of the memory cell can be greatly simplified.

Note that the OS transistor described in Embodiment 2 is preferably used as the transistor M1. With the use of the OS transistor described in Embodiment 2, the operation speed of the memory device can be increased. Furthermore, the area occupied by the memory cell can be reduced. An OS transistor has a characteristic of an extremely low off-state current. The use of an OS transistor as the transistor M1 enables an extremely low leakage current of the transistor M1. That is, with the use of the transistor M1, written data can be retained for a long time, and thus the frequency of refresh operation for the memory cell can be lowered. Alternatively, refresh operation for the memory cell can be unnecessary. In addition, owing to an extremely low leakage current, multilevel data or analog data can be retained in the memory cells 951 and 952.

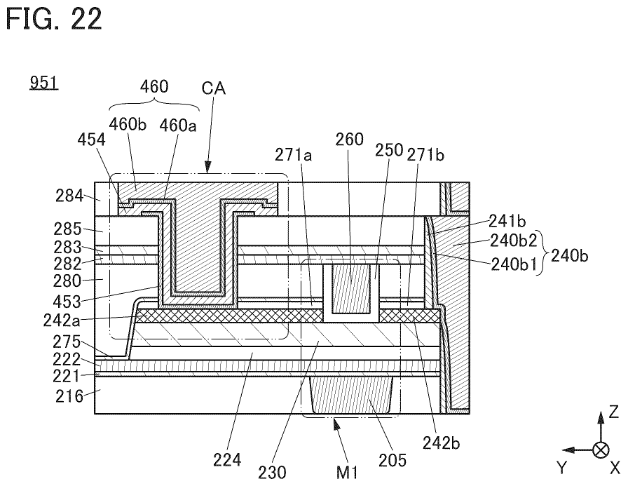

Here, an example of the structure of a DOSRAM is described with reference to FIG. 22. In FIG. 22, the X direction is parallel to the channel width direction of a transistor, the Y direction is perpendicular to the X direction, and the Z direction is perpendicular to the X direction and the Y direction.

As illustrated in FIG. 22, the memory cell 951 includes the transistor M1 and the capacitor CA. An insulator 284 is provided over the transistor M1. Any of the insulators that can be used as the insulator 216 is used as the insulator 284. Note that the transistor M1 has the same structure as the transistor 200 described in the Embodiment 2, and the same components may be denoted by the same reference numerals.

Embodiment 2 can be referred to for the details of the transistor 200. The conductor 240b (conductors 240b1 and 240b2) is provided in contact with one of a source electrode and a drain electrode (the conductor 242b) of the transistor M1. The conductor 240b extends in the Z direction and functions as the wiring BIL. The conductor 260 of the transistor 200 is provided to extend in the X direction and functions as the wiring WOL.

The capacitor CA includes a conductor 453 over the conductor 242a, an insulator 454 over the conductor 453, and a conductor 460 (conductors 460a and 460b) over the insulator 454.

At least parts of the conductor 453, the insulator 454, and the conductor 460 are positioned inside the opening portion formed in the insulators 271a, 275, 280, 282, 283, and 285. End portions of the conductor 453, the insulator 454, and the conductor 460 are positioned at least over the insulator 283, and preferably positioned over the insulator 285. The insulator 454 is provided to cover the end portion of the conductor 453. This enables the conductors 453 and 460 to be electrically insulated from each other.

The deeper the depth of the opening portion formed in the insulators 271a, 275, 280, 282, 283, and 285 is (i.e., the larger the thickness of at least one of the insulators 271a, 275, 280, 282, 283, and 285 is), the larger the electrostatic capacitance of the capacitor CA can be. Increasing the electrostatic capacitance per unit area of the capacitor CA enables further miniaturization and higher integration of the memory device.

The conductor 453 includes a region functioning as the one electrode (a lower electrode) of the capacitor CA. The insulator 454 includes a region functioning as a dielectric of the capacitor CA. The conductor 460 includes a region functioning as the other electrode (an upper electrode) of the capacitor CA. An upper portion of the conductor 460 can be extended to function as the wiring CAL. The capacitor CA forms a metal-insulator-metal (MIM) capacitor.

The conductor 242a provided to overlap the oxide semiconductor 230 functions as an electrode that is electrically connected to the lower electrode of the capacitor CA.

Each of the conductors 453 and 460 included in the capacitor CA can be formed with any conductor that can be used for the conductor 205 or the conductor 260. The conductors 453 and 460 are preferably deposited by a formation method that enables excellent coverage, such as an ALD method or a CVD method. For example, titanium nitride or tantalum nitride deposited by an ALD method or a CVD method can be used for the conductor 453.

The top surface of the conductor 242a is in contact with the bottom surface of the conductor 453. Here, the contact resistance between the conductor 453 and the conductor 242a can be reduced when the conductor 242a is formed with a conductive material with high conductivity.

Titanium nitride deposited by an ALD method or a CVD method can be used for the conductor 460a, and tungsten deposited by a CVD method can be used for the conductor 460b. In the case where the adhesion of tungsten to the insulator 454 is sufficiently high, the conductor 460 may have a single-layer structure of tungsten deposited by a CVD method.

For the insulator 454 included in the capacitor CA, the high dielectric constant (high-k) material described in the above embodiment is preferably used. Using such a high-k material allows the insulator 454 to be thick enough to inhibit a leakage current and a sufficiently high capacitance of the capacitor CA to be retained. The insulator 454 is preferably deposited by a formation method that enables excellent coverage, such as an ALD method or a CVD method.

It is preferable to use stacked insulators each formed of any of the above-described materials. A stacked-layer structure including a high dielectric constant (high-k) material and a material having higher dielectric strength than the high dielectric constant (high-k) material is preferably used. For example, as the insulator 454, an insulator in which zirconium oxide, aluminum oxide, and zirconium oxide are stacked in this order can be used. For another example, an insulator in which zirconium oxide, aluminum oxide, zirconium oxide, and aluminum oxide are stacked in this order can be used. For another example, an insulator in which hafnium zirconium oxide, aluminum oxide, hafnium zirconium oxide, and aluminum oxide are stacked in this order can be used. The stacking of such an insulator having relatively high dielectric strength, such as aluminum oxide, can increase the dielectric strength and inhibit electrostatic breakdown of the capacitor CA.

Alternatively, a material that can show ferroelectricity described later may be used for the insulator 454. Examples of the material that can show ferroelectricity include metal oxides such as hafnium oxide, zirconium oxide, and HfZrO_{X} (X is a real number greater than 0). Examples of the material that can show ferroelectricity also include a material in which an element J1 (the element J1 here is one or more of zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 can be, for example, 1:1 or the neighborhood thereof. Examples of the material that can show ferroelectricity also include a material in which an element J2 (the element J2 here is one or more of hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 can be, for example, 1:1 or the neighborhood thereof. As the material that can show ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can show ferroelectricity also include a metal nitride containing an element M1, an element M2, and nitrogen. Here, the element M1 is one or more of aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen shows ferroelectricity in some cases even though the metal oxide does not contain the element M2. Examples of the material that can show ferroelectricity also include the above metal nitride to which an element M3 is added. Note that the element M3 is one or more of magnesium, calcium, strontium, zinc, cadmium, and the like. Here, the atomic ratio between the element M1, the element M2, and the element M3 can be set as appropriate.

Examples of the material that can show ferroelectricity also include perovskite-type oxynitrides such as SrTaO₂N and BaTaO₂N; and GaFeO₃ with a K-alumina-type structure.

The metal oxides and metal nitrides described above as example are non-limiting examples. For example, a metal oxynitride in which nitrogen is added to any of the above-described metal oxides, a metal nitride oxide in which oxygen is added to any of the above-described metal nitrides, or the like may be used.

As the material that can show ferroelectricity, a mixture or compound containing a plurality of materials selected from the above-listed materials can be used, for example. Alternatively, the insulator 454 can have a stacked-layer structure of a plurality of materials selected from the above-listed materials. Since the above-listed materials and the like may change their crystal structures (characteristics) according to a variety of processes and the like as well as deposition conditions, a material that exhibits ferroelectricity is referred to not only as a ferroelectric but also as a material that can show ferroelectricity in this specification and the like.

The ferroelectric refers to an insulator having a property of causing internal polarization by application of an electric field from the outside and maintaining the polarization even after the electric field is made zero. Thus, with the use of a capacitor that contains this material as a dielectric (hereinafter, such a capacitor is sometimes referred to as a ferroelectric capacitor), a nonvolatile memory element can be formed. A nonvolatile memory element including a ferroelectric capacitor is sometimes referred to as a ferroelectric random access memory (FeRAM), a ferroelectric memory, or the like. For example, a ferroelectric memory includes a transistor and a ferroelectric capacitor, and one of a source and a drain of the transistor is electrically connected to one terminal of the ferroelectric capacitor. Thus, in the case of using a ferroelectric capacitor as the capacitor CA, the memory device described in this embodiment functions as a ferroelectric memory.

Note that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulator 454 can exhibit ferroelectricity, the insulator 454 needs to include a crystal. It is particularly preferable that the insulator 454 include a crystal having an orthorhombic crystal structure, in which case ferroelectricity is exhibited. A crystal included in the insulator 454 may have one or more of crystal structures selected from cubic, tetragonal, orthorhombic, monoclinic, and hexagonal crystal structures. Alternatively, the insulator 454 may have an amorphous structure. In that case, the insulator 454 may have a composite structure including an amorphous structure and a crystal structure.

The deeper the depth of the opening portion formed in the insulators 271a, 275, 280, 282, 283, and 285 is (i.e., the larger the thickness of at least one of the insulators 271a, 275, 280, 282, 283, and 285 is), the larger the electrostatic capacitance of the capacitor CA can be. For example, the electrostatic capacitance of the capacitor CA can be set by adjusting the thickness of the insulator 285. Specifically, the thickness of the insulator 285 can be set within the range from 50 nm to 250 nm, and the depth of the opening portion is approximately greater than or equal to 150 nm and less than or equal to 350 nm. When the capacitor CA is formed within the above range, the capacitor CA can have adequate electrostatic capacitance, and the height of one layer can be prevented from being excessively large in a semiconductor device in which a plurality of memory cells are stacked in layers. Note that capacitors in memory cells in each layer of stacked layers may have different electrostatic capacitance. In the case of this structure, the insulators 285 provided in the layers of the memory cells may have different thicknesses, for example.

In the opening portion formed in the insulator 285 and the like where the capacitor CA is formed, a sidewall of the opening portion may be perpendicular or substantially perpendicular to the top surface of the insulator 222 or may have a tapered shape. The tapered shape of the sidewall can improve the coverage with the conductor 453 and the like provided in the opening formed in the insulator 285 and the like; as a result, the number of defects such as voids can be reduced.

The conductor 242b provided over the oxide semiconductor 230 functions as a wiring electrically connected to the conductor 240b. For example, in FIG. 22, a top surface and a side end portion of the conductor 242b are electrically connected to the conductor 240b extending the Z direction.

When the conductor 240b is directly in contact with at least one of the top surface and the side end portion of the conductor 242b, a separate electrode for connection does not need to be provided, so that the area occupied by memory arrays can be reduced. In addition, the integration degree of the memory cell can be heightened and the memory capacity of the memory device can be increased. Note that the conductor 240b is preferably in contact with a part of the top surface and the side end portion of the conductor 242b. When the conductor 240b is in contact with a plurality of surfaces of the conductor 242b, the contact resistance between the conductors 240b and 242b can be reduced.

The conductor 240b is provided in an opening formed in the insulators 216, 221, 222, 224, 271b, 275, 280, 282, 283, 285, and 284.

As illustrated in FIG. 22, the insulator 241b is preferably provided in contact with a side surface of the conductor 240b. Specifically, the insulator 241b is provided in contact with an inner wall of the opening portion formed in the insulators 216, 221, 222, 224, 271b, 275, 280, 282, 283, 285, and 284. The insulator 241b is formed also on the side surface of the oxide semiconductor 230 protruding in the opening. Note that at least part of the conductor 242b is exposed from the insulator 241b and is in contact with the conductor 240b. That is, the conductor 240b is provided to fill the opening portion with the insulator 241b between the inner wall of the opening portion and the conductor 240b.

Note that as illustrated in FIG. 22, an uppermost portion of the insulator 241b formed below the conductor 242b is preferably positioned below the top surface of the conductor 242b. With such a structure, the conductor 240b can be in contact with at least part of the side end portion of the conductor 242b. The insulator 241b formed below the conductor 242b preferably includes a region in contact with the side surface of the oxide semiconductor 230. This structure can inhibit impurities contained in the insulator 280 and the like, such as water and hydrogen, from entering the oxide semiconductor 230 through the conductor 240b.

In the opening portion where the conductor 240b and the insulator 241b are provided, the sidewall of the opening may be perpendicular or substantially perpendicular to the top surface of the insulator 222 or may have a tapered shape. The tapered sidewall can improve the coverage with the insulator 241b and the like provided in the opening portion.

### [NOSRAM]

FIG. 21C illustrates a circuit structure example of a gain-cell memory cell including two transistors and one capacitor. A memory cell 953 includes transistors M2, and M3 and a capacitor CB. In this specification and the like, a memory device including a gain-cell memory cell using an OS transistor as the transistor M2 is referred to as a nonvolatile oxide semiconductor RAM (NOSRAM).

A first terminal of the transistor M2 is connected to a first terminal of the capacitor CB. A second terminal of the transistor M2 is connected to the wiring WBL. The gate of the transistor M2 is connected to the wiring WOL. A second terminal of the capacitor CB is connected to the wiring CAL. A first terminal of the transistor M3 is connected to the wiring RBL. A second terminal of the transistor M3 is connected to the wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In the time of data writing, data retention, and data reading, a low-level potential (sometimes referred to as a ground potential) is preferably applied to the wiring CAL.

Data writing is performed in such a manner that a high-level potential is applied to the wiring WOL to turn on the transistor M2, and thus the wiring WBL is connected to the first terminal of the capacitor CB. Specifically, when the transistor M2 is on, a potential corresponding to data to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. A current flowing between the source and the drain of the transistor M3 and the potential of the first terminal of the transistor M3 are determined by the potential of the gate of the transistor M3 and the potential of the second terminal of the transistor M3. Accordingly, by reading a potential of the wiring RBL connected to the first terminal of the transistor M3, a potential retained in the first terminal of the capacitor CB (or the gate of the transistor M3) can be read. That is, data written to the memory cell can be read on the basis of the potential retained in the first terminal of the capacitor CB (or the gate of the transistor M3).

As another example, one wiring BIL may be provided instead of the wiring WBL and the wiring RBL. A circuit structure example of the memory cell is illustrated in FIG. 21D. In a memory cell 954, one wiring BIL is provided instead of the wiring WBL and the wiring RBL in the memory cell 953, and the second terminal of the transistor M2 and the first terminal of the transistor M3 are electrically connected to the wiring BIL. In other words, one wiring BIL operates as both the write bit line and the read bit line in the memory cell 954.

A memory cell 955 illustrated in FIG. 21E is an example in which the capacitor CB and the wiring CAL in the memory cell 953 are not provided. A memory cell 956 illustrated in FIG. 21F is an example in which the capacitor CB and the wiring CAL in the memory cell 954 are not provided. Such structures enable higher integration of memory cells.

Note that the OS transistor described in Embodiment 2 is preferably used as at least the transistor M2. It is particularly preferable to use the OS transistors described in Embodiment 2 as the transistor M2 and the transistor M3. With the use of the OS transistor described in Embodiment 2, the operation speed of the memory device can be increased. Furthermore, the area occupied by the memory cell can be reduced.

Because the OS transistor has a characteristic of an extremely low off-state current, written data can be retained for a long time with the use of the transistor M2, and thus the frequency of refresh operation for the memory cell can be lowered. Alternatively, refresh operation for the memory cell can be unnecessary. In addition, owing to an extremely low leakage current, multilevel data or analog data can be retained in the memory cells 953, 954, 955, and 956.

The memory cells 953, 954, 955, and 956 each using the OS transistor as the transistor M2 are each one mode of a NOSRAM.

Note that a Si transistor may be used as the transistor M3. The Si transistor can have high field-effect mobility and can be formed as a p-channel transistor, so that circuit design flexibility can be increased.

When the OS transistor is used as the transistor M3, the memory cell can be configured with the transistors having the same conductivity type.

FIG. 21G illustrates an example of a gain memory cell 957 including three transistors and one capacitor. The memory cell 957 includes transistors M4 to M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is electrically connected to a first terminal of the transistor M5 and a wiring GNDL. A second terminal of the transistor M5 is connected to a first terminal of the transistor M6, and a gate of the transistor M5 is connected to the first terminal of the capacitor CC. A second terminal of the transistor M6 is electrically connected to the wiring BIL. A gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed as follows: a high-level potential is applied to the wiring WOL to turn on the transistor M4, and thus the wiring BIL is connected to the first terminal of the capacitor CC. Specifically, when the transistor M4 is on, a potential corresponding to data to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data is read by precharging the wiring BIL to a predetermined potential, and then making the wiring BIL in an electrically floating state, and applying a high-level potential to the wiring RWL. When the wiring RWL has the high-level potential, the transistor M6 is turned on, so that the wiring BIL is electrically connected to the second terminal of the transistor M5. At this time, the potential of the wiring BIL is applied to the second terminal of the transistor M5; the potential of the second terminal of the transistor M5 and the potential of the wiring BIL change depending on the potential held in the first terminal of the capacitor CC (or the gate of the transistor M5). Here, the potential retained in the first terminal of the capacitor CC (or the gate of the transistor M5) can be read by reading the potential of the wiring BIL. That is, data written to the memory cell can be read on the basis of the potential retained in the first terminal of the capacitor CC (or the gate of the transistor M5).

Note that the OS transistor described in Embodiment 2 is preferably used as at least the transistor M4. With use of the OS transistor described in Embodiment 2, the area occupied by a memory cell can be reduced.

Note that Si transistors may be used as the transistors M5 and M6. As described above, a Si transistor may have higher field-effect mobility than the OS transistor depending on the crystal state of silicon used in a semiconductor layer, for example.

When OS transistors are used as the transistors M5 and M6, the memory cell can be configured with the transistors having the same conductivity type.

### [OS-SRAM]

FIG. 21H illustrates an example of a static random access memory (SRAM) using an OS transistor. In this specification and the like, an SRAM using an OS transistor is referred to as an oxide semiconductor SRAM (OS-SRAM). A memory cell 958 illustrated in FIG. 21H is a memory cell of an SRAM capable of backup operation.

The memory cell 958 includes transistors M7 to M10, transistors MS1 to MS4, and capacitors CD1 and CD2. The transistors MS1 and MS2 are p-channel transistors, and the transistors MS3 and MS4 are n-channel transistors.

A first terminal of the transistor M7 is connected to the wiring BIL. A second terminal of the transistor M7 is connected to a first terminal of the transistor MS1, a first terminal of the transistor MS3, a gate of the transistor MS2, a gate of the transistor MS4, and a first terminal of the transistor M10. A gate of the transistor M7 is connected to the wiring WOL. A first terminal of the transistor M8 is connected to a wiring BILB. A second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is electrically connected to a wiring VDL. A second terminal of the transistor MS2 is electrically connected to the wiring

VDL. A second terminal of the transistor MS3 is electrically connected to the wiring GNDL. A second terminal of the transistor MS4 is electrically connected to the wiring GNDL.

A second terminal of the transistor M9 is connected to a first terminal of the capacitor CD1. A gate of the transistor M9 is connected to a wiring BRL. A second terminal of the transistor M10 is connected to a first terminal of the capacitor CD2. A gate of the transistor M10 is connected to the wiring BRL.

A second terminal of the capacitor CD1 is connected to the wiring GNDL. A second terminal of the capacitor CD2 is connected to the wiring GNDL.

The wiring BIL and the wiring BILB function as bit lines. The wiring WOL functions as a word line. The wiring BRL controls the on/off states of the transistors M9 and M10.

The wiring VDL supplies a high-level potential. The wiring GNDL supplies a low-level potential.

Data writing is performed by applying high-level potentials to the wiring WOL and the wiring BRL. Specifically, when the transistor M10 is on, a potential corresponding to data to be stored is applied to the wiring BIL, and the potential is written to the second terminal side of the transistor M10.

In the memory cell 958, the transistors MS1 and MS2 form an inverter loop; hence, an inversion signal of a data signal corresponding to the potential is input to the second terminal side of the transistor M8. When the transistor M8 is on, an inversion signal of the potential that has been applied to the wiring BIL (i.e., the signal that has been input to the wiring BIL) is output to the wiring BILB. Since the transistors M9 and M10 are on, the potential of the second terminal of the transistor M7 is retained in the first terminal of the capacitor CD2, and the potential of the second terminal of the transistor M8 is retained in the first terminal of the capacitor CD1. After that, low-level potentials are applied to the wiring WOL and the wiring BRL to turn off the transistors M7 to M10, whereby the potential of the first terminal of the capacitor CDI and the potential of the first terminal of the capacitor CD2 are retained.

Data reading is performed as follows: the wiring BIL and the wiring BILB are precharged with a predetermined potential, and then high-level potentials are applied to the wiring WOL and the wiring BRL, whereby the potential of the first terminal of the capacitor CD1 is refreshed by the inverter loop in the memory cell 958 and output to the wiring BILB. Furthermore, the potential of the first terminal of the capacitor CD2 is refreshed by the inverter loop in the memory cell 958 and output to the wiring BIL. Since the potentials of the wiring BIL and the wiring BILB are changed from the precharged potentials to the potentials of the first terminal of the capacitor CD2 and the first terminal of the capacitor CD1, the potential retained in the memory cell can be read on the basis of the potentials of the wiring BIL and the wiring BILB.

Note that the transistors M7 to M10 are preferably OS transistors. In this case, with the use of the transistors M7 to M10, written data can be retained for a long time, and thus the frequency of refresh operation for the memory cell can be decreased. Alternatively, refresh operation for the memory cell can be unnecessary. When the OS transistor described in Embodiment 2 is used as each of the transistors M7 to M10, the operation speed of the memory device can be increased. Furthermore, the area occupied by the memory cell can be reduced.

Note that the transistors MS1 to MS4 may be Si transistors.

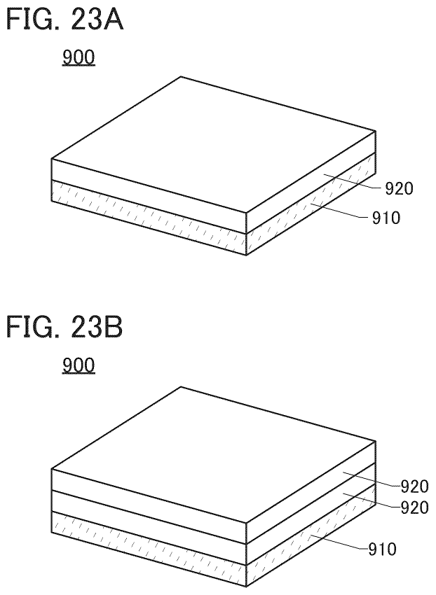

The driver circuit 910 and the memory array 920 included in the semiconductor device 900 may be provided on the same plane. Alternatively, as illustrated in FIG. 23A, the driver circuit 910 and the memory array 920 may be provided to overlap with each other, which can shorten a signal propagation distance. As illustrated in FIG. 23B, a plurality of memory arrays 920 may be stacked over the driver circuit 910.

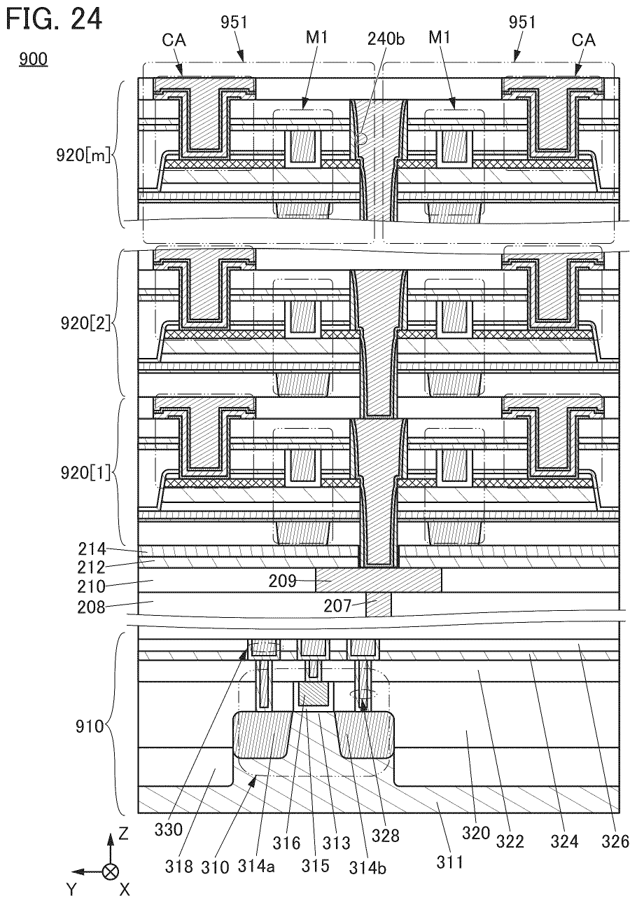

Here, a structure example of the semiconductor device 900 in which a plurality of memory arrays 920 are stacked is described with reference to FIG. 24.

The semiconductor device 900 illustrated in FIG. 24 includes a driver circuit 910 that is a layer including the transistor 310 and the like and memory arrays 920[1] to 920[m] over the driver circuit 910. Here, FIG. 24 illustrates a memory array 920[1] as the layer provided in the first layer (the bottom layer), a memory array 920[2] as the layer provided in the second layer, and a memory array 920[m] as the layer provided in the m-th layer (the top layer). In other words, the memory device of one embodiment of the present invention may include a plurality of layers including memory cells and have a structure in which the plurality of layers are stacked.

FIG. 24 illustrates an example of the transistor 310 included in the driver circuit 910. The transistor 310 is provided on a substrate 311 and includes a conductor 316 functioning as a gate, an insulator 315 functioning as a gate insulator, a semiconductor region 313 that includes a part of the substrate 311, and a low-resistance region 314a and a low-resistance region 314b each functioning as a source region or a drain region. An element isolation layer 318 is preferably provided between adjacent transistors 310. The transistor 310 may be a p-channel transistor or an n-channel transistor. As the substrate 311, a single crystal silicon substrate can be used, for example.

In the transistor 310, the semiconductor region 313 (part of the substrate 311) where a channel is formed has a protruding shape. Furthermore, the conductor 316 is provided to cover the side and top surfaces of the semiconductor region 313 with the insulator 315 therebetween. Note that the conductor 316 may be formed using a material for adjusting the work function. The transistor 310 is also referred to as a FIN-type transistor because it utilizes a protruding portion of a semiconductor substrate. An insulator functioning as a mask for forming the projecting portion may be provided in contact with the top surface of the projecting portion. Although the case where the projecting portion is formed by processing part of the semiconductor substrate is described here, a semiconductor film having a projecting shape may be formed by processing an SOI substrate.

Note that the transistor 310 illustrated in FIG. 24 is an example and the structure is not limited thereto; an appropriate transistor can be used in accordance with a circuit structure or a driving method.

Wiring layers including an interlayer film, a wiring, a plug, and the like may be provided between the structures. A plurality of wiring layers can be provided in accordance with the design. Note that a plurality of conductors functioning as plugs or wirings are collectively denoted by the same reference numeral in some cases. Furthermore, in this specification and the like, a wiring and a plug electrically connected to the wiring may be a single component. That is, in some cases, part of a conductor functions as a wiring or part of a conductor functions as a plug.

For example, an insulator 320, an insulator 322, an insulator 324, and an insulator 326 are sequentially stacked over the transistor 310 as interlayer films. A conductor 328 or the like is embedded in the insulator 320 and the insulator 322. A conductor 330 or the like is embedded in the insulator 324 and the insulator 326. Note that the conductor 328 and the conductor 330 function as contact plugs or wirings.

The insulator functioning as an interlayer film may function as a planarization film that covers a roughness thereunder. For example, the top surface of the insulator 322 may be planarized by planarization treatment using a CMP method or the like to improve the planarity.

Examples of an insulator that can be used as an interlayer film include an insulating oxide, an insulating nitride, an insulating oxynitride, an insulating nitride oxide, an insulating metal oxide, an insulating metal oxynitride, and an insulating metal nitride oxide.

For example, when a material having a low dielectric constant is used for the insulator functioning as an interlayer film, the parasitic capacitance between wirings can be reduced. Thus, a material is preferably selected depending on the function of an insulator.

An insulator 208 is provided over the driver circuit 910, and a conductor 207 is provided in an opening formed in the insulator 208. An insulator 210 is provided over the insulator 208, and a conductor 209 is provided in an opening formed in the insulator 210. Moreover, an insulator 212 is provided over the insulator 210, and an insulator 214 is provided over the insulator 212. A part of the conductor 240b provided in the memory array 920[1] is embedded in an opening formed in the insulator 212 and the insulator 214. Here, for the insulators 208 and 210, an insulator that can be used for the insulator 216 can be used.

The conductor 207 functions as a wiring electrically connected to the driver circuit 910. A top surface of the conductor 207 is provided in contact with a bottom surface of the conductor 209. A top surface of the conductor 209 is provided in contact with a bottom surface of the conductor 240b provided in the memory array 920[1]. With this structure, the conductor 240b corresponding to the wiring BIL can be electrically connected to the driver circuit 910.

Each of the memory arrays 920[1] to 920[m] includes the plurality of memory cells 951. The conductor 240b of each of the memory cells 951 is electrically connected to the conductor 240b in a layer above and to the conductor 240b in a layer below.

As illustrated in FIG. 24, the conductor 240b is shared between the adjacent memory cells 951. The structures of the adjacent memory cells 951 are symmetrical with respect to the conductor 240b.

In the above memory array 920, the plurality of memory arrays 920[1] to 920[m] can be stacked. The memory arrays 920[1] to 920[m] included in the memory array 920 are provided in a direction perpendicular to a surface of substrate on which the driver circuit 910 is provided, in which case the memory density of the memory cells 951 can be increased. The memory arrays 920 can be formed by repeating the same manufacturing process in the vertical direction. For the semiconductor device 900, the manufacturing cost of the memory array 920 can be reduced.

Next, description is made on an example of an arithmetic processing device that can include the semiconductor device like the memory device described above.

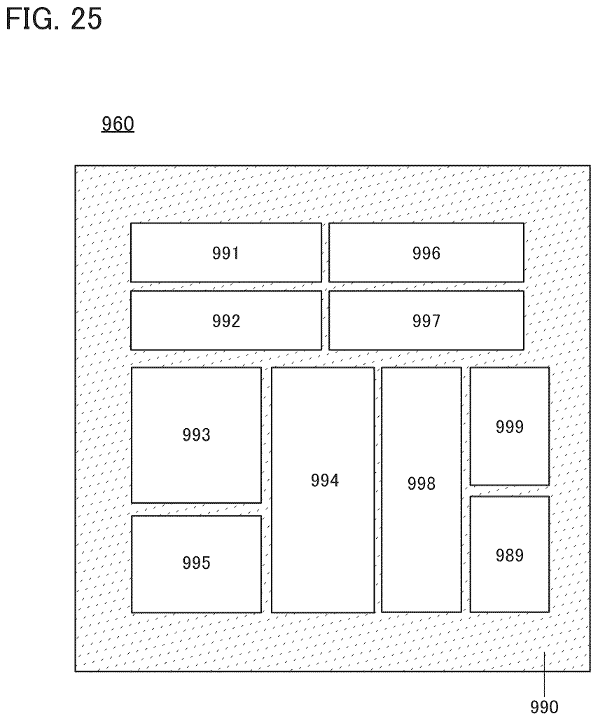

FIG. 25 is a block diagram of an arithmetic device 960. The arithmetic device 960 illustrated in FIG. 25 can be used for a central processing unit (CPU), for example. The arithmetic device 960 can also be used for a processor including a larger number of (several tens to several hundreds of) processor cores capable of parallel processing than a CPU, such as a graphics processing unit (GPU), a tensor processing unit (TPU), or a neural processing unit (NPU).

The arithmetic device 960 illustrated in FIG. 25 includes, over a substrate 990, an arithmetic logic unit (ALU) 991, an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in this case, the driver circuit 910 is preferably included in part of the cache interface 989.

Note that it is also possible that the cache 999 is not provided and only the memory array 920 is used as a cache.

The arithmetic device 960 illustrated in FIG. 25 is only an example with a simplified configuration, and the actual arithmetic device 960 has a variety of configurations depending on the application. For example, what is called a multicore configuration is preferably employed in which a plurality of cores each including the arithmetic device 960 in FIG. 25 operate in parallel. A larger number of cores can further enhance the arithmetic performance. The number of cores is preferably larger; for example, the number is preferably 2, further preferably 4, further preferably 8, further preferably 12, further preferably 16 or larger. For application requiring extremely high arithmetic performance, e.g., a server, it is preferable to employ the multicore configuration including 16 or more, preferably 32 or more, further preferably 64 or more cores. The number of bits that the arithmetic device 960 can handle with an internal arithmetic circuit, a data bus, or the like can be 8, 16, 32, or 64, for example.

An instruction input to the arithmetic device 960 through the bus interface 998 is input to the instruction decoder 993 and decoded, which is then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. The interrupt controller 994 processes an interrupt request from an external input/output device, a peripheral circuit, or the like by making a determination based on its priority, a mask state, or the like while the arithmetic device 960 is executing a program. The register controller 997 generates the address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above circuits.

In the arithmetic device 960 in FIG. 25, the register controller 997 selects operation of retaining data in the register 996 in accordance with an instruction from the ALU 991. That is, the register controller 997 selects whether data is retained by a flip-flop or by a capacitor in a memory cell included in the register 996. When data retention by the flip-flop is selected, power supply voltage is supplied to the memory cell in the register 996. When data retention by the capacitor is selected, the data is rewritten into the capacitor, and supply of power supply voltage to the memory cell in the register 996 can be stopped.

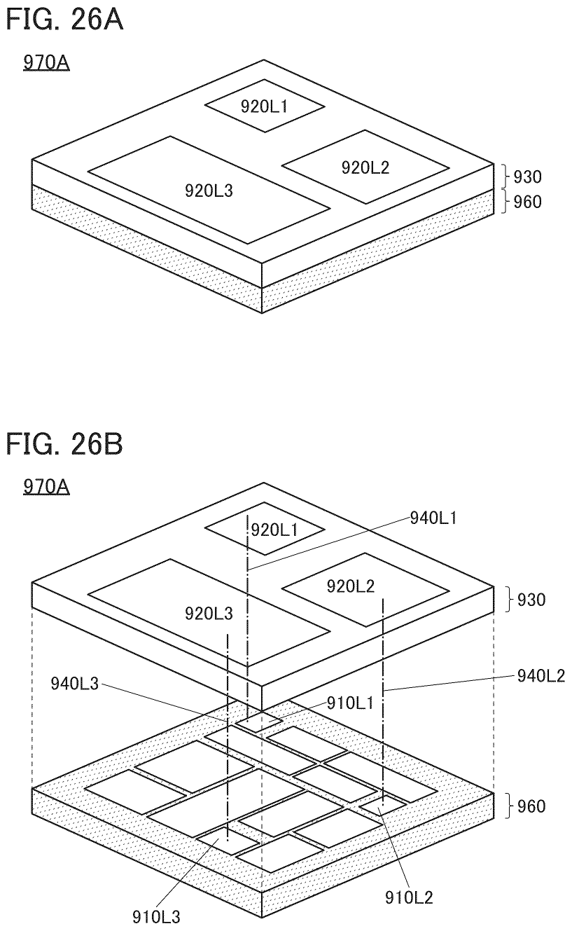

The memory array 920 and the arithmetic device 960 can be provided to overlap with each other. FIGS. 26A and 26B are perspective views of a semiconductor device 970A. The semiconductor device 970A includes a layer 930 provided with memory arrays over the arithmetic device 960. Memory arrays 920L1, 920L2, and 920L3 are provided in the layer 930. The arithmetic device 960 and each of the memory arrays overlap with each other. For easy understanding of the structure of the semiconductor device 970A, the arithmetic device 960 and the layer 930 are separately illustrated in FIG. 26B.

When the arithmetic device 960 and the layer 930 including the memory arrays are provided to overlap with each other, the connection distance therebetween can be shortened. Accordingly, the communication speed therebetween can be increased. Moreover, a short connection distance leads to lower power consumption.

As a method for stacking the layer 930 including the memory arrays and the arithmetic device 960, either of the following methods may be employed: a method in which the layer 930 including the memory arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are electrically connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory arrays 920L1, 920L2, and 920L3 provided in the layer 930 are each used as a cache. In this case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 26B, driver circuits 910L1, 910L2, and 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

In this example, the three memory arrays function as caches; however, the number of memory arrays may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuits 910L2 and 910L3 may function as part of the cache interface 989 or be connected thereto.

Whether the memory array 920 functions as the cache or the main memory is determined by the control circuit 912 included in each of the driver circuits 910. The control circuit 912 can make some of the memory cells 950 in the semiconductor device 900 function as RAMs in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

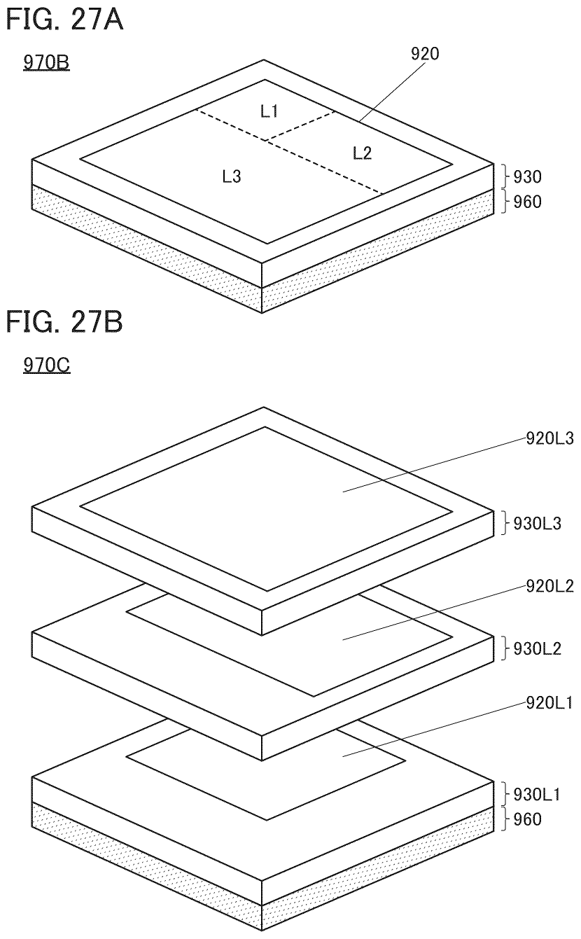

The layer 930 including one memory array 920 may be provided to overlap with the arithmetic device 960. FIG. 27A is a perspective view of a semiconductor device 970B.

In the semiconductor device 970B, one memory array 920 can be divided into a plurality of areas having different functions. FIG. 27A illustrates an example in which a region L1, a region L2, and a region L3 are used as the L1 cache, the L2 cache, and the L3 cache, respectively.

In the semiconductor device 970B, the capacity of each of the regions L1 to L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 27B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

Note that this embodiment can be combined with any of the other embodiments in this specification as appropriate.

### Embodiment 4

In this embodiment, application examples of the memory device of one embodiment of the present invention are described.

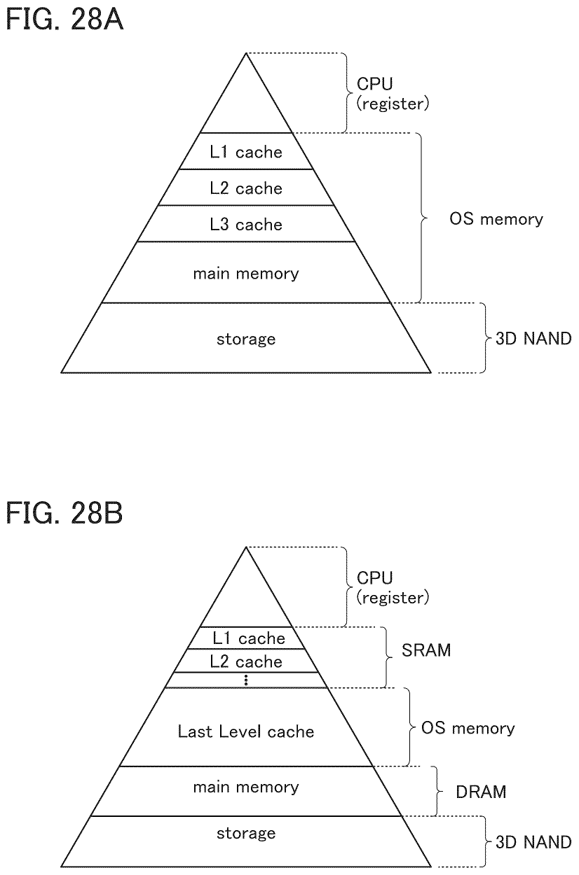

In general, a variety of memory devices are used in semiconductor devices such as computers in accordance with the intended use. FIG. 28A illustrates the hierarchy of various memory devices used in a semiconductor device. The memory devices at the upper levels require a higher operating speed, whereas the memory devices at the lower levels require a larger memory capacity and a higher memory density. FIG. 28A illustrates, for example, a memory included as a register in an arithmetic processing device such as a CPU, an L1 cache, an L2 cache, an L3 cache, a main memory, and a storage in this order from the uppermost layer. Although the caches up to the L3 cache are included in this example, a lower-level cache may be further included.

The memory included as the register in the arithmetic processing device such as a CPU is used for temporary storage of arithmetic operation results, for example, and thus is very frequently accessed by the arithmetic processing device. Accordingly, the memory requires rapid operation rather than the memory capacity. The register also has a function of retaining settings of the arithmetic processing device, for example.

The cache has a function of duplicating and retaining part of data retained in the main memory. Duplicating frequently used data and retaining the duplicated data in the cache facilitates rapid data access. The cache requires a smaller memory capacity than the main memory but a higher operating speed than the main memory. Data that is rewritten in the cache is duplicated, and the duplicated data is supplied to the main memory.

The main memory has a function of retaining a program and data that are read from the storage, for example.

The storage has a function of retaining data that needs to be stored for a long time and programs used in the arithmetic processing device, for example. Therefore, the storage requires a large memory capacity and a high memory density rather than operating speed. For example, a high-capacity nonvolatile memory device such as a 3D NAND memory device can be used.

The memory device including an oxide semiconductor (the OS memory) of one embodiment of the present invention can operate at high speed and retain data for a long time. Thus, as illustrated in FIG. 28A, the memory device of one embodiment of the present invention can be suitably used for devices at both the levels of the caches and the level of the main memory. The memory device of one embodiment of the present invention can also be used for devices at the level of the storage.

FIG. 28B illustrates an example in which SRAMs are used as some of the caches and the OS memory of one embodiment of the present invention is used as the other cache.

The lowest-level cache of the caches can be referred to as a last level cache (LLC). The LLC does not require a higher operation speed than higher-level caches, but desirably has large memory capacity. The OS memory of one embodiment of the present invention can operate at high speed and retain data for a long time, and thus can be suitably used as the LLC. Note that the OS memory of one embodiment of the present invention can also be used as a final level cache (FLC).

For example, as illustrated in FIG. 28B, SRAMs can be used as the higher-level caches (the L1 cache, the L2 cache, and the like), and the OS memory of one embodiment of the present invention can be used as the LLC. Moreover, instead of the OS memory, a DRAM can be used as the main memory as illustrated in FIG. 28B.

Note that this embodiment can be combined with any of the other embodiments in this specification as appropriate.

### Embodiment 5

This embodiment describes an electronic component, an electronic device, a large computer, space equipment, and a data center (also referred to as DC) that can include any of the semiconductor devices described in the above embodiments. An electronic device, a large computer, space equipment, and a data center each employing the semiconductor device of one embodiment of the present invention are effective in improving performance, for example, reducing power consumption.

### [Electronic Device]

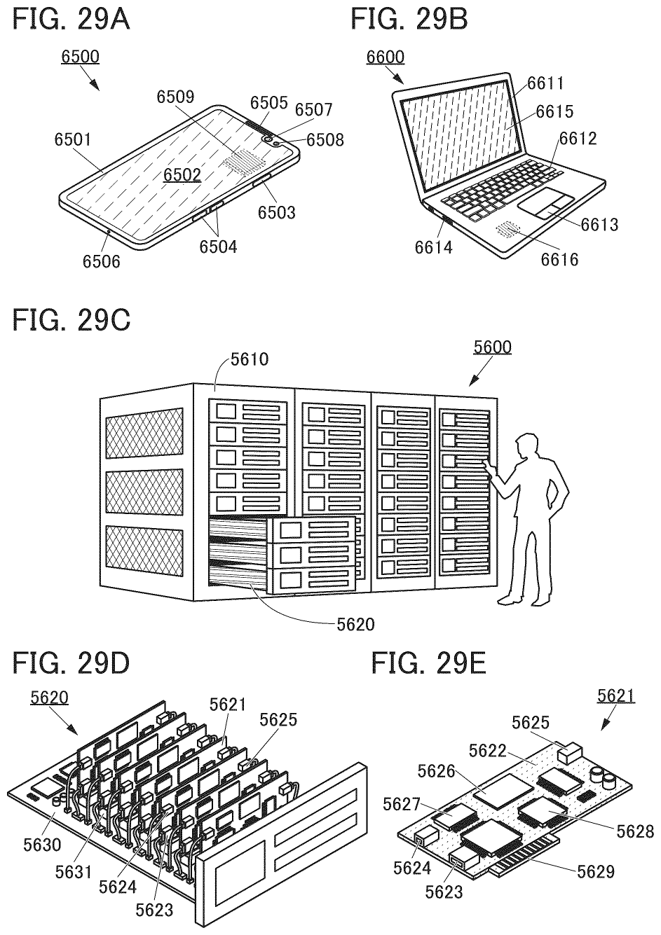

FIG. 29A is a perspective view of an electronic device 6500. The electronic device 6500 in FIG. 29A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. Note that as the control device 6509, for example, one or more selected from a CPU, a GPU, and a memory device are included. The semiconductor device of one embodiment of the present invention can be used for the display portion 6502, the control device 6509, and the like.

An electronic device 6600 illustrated in FIG. 29B is an information terminal that can be used as a laptop personal computer. The electronic device 6600 includes a housing 6611, a keyboard 6612, a pointing device 6613, an external connection port 6614, a display portion 6615, a control device 6616, and the like. Note that as the control device 6616, for example, one or more selected from a CPU, a GPU, and a memory device are included. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

Next, FIG. 29C is a perspective view of a large computer 5600. In the large computer 5600 illustrated in FIG. 29C, a plurality of rack mount computers 5620 are stored in a rack 5610. Note that the large computer 5600 may be referred to as a supercomputer.

The computer 5620 can have a structure illustrated in a perspective view in FIG. 29D, for example. In FIG. 29D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 29E is an example of a processing board provided with a CPU, a GPU, a memory device, and the like. The PC card 5621 includes a board 5622. The board 5622 includes the connection terminals 5623, 5624, and 5625, semiconductor devices 5626, 5627, and 5628, and a connection terminal 5629. FIG. 29E also illustrates semiconductor devices other than the semiconductor devices 5626, 5627, and 5628, and the following description of the semiconductor devices 5626, 5627, and 5628 can be referred to for these semiconductor devices.

The connection terminal 5629 has a shape enabling insertion of the connection terminal 5629 into the slot 5631 of the motherboard 5630, and the connection terminal 5629 functions as an interface for connecting the PC card 5621 and the motherboard 5630. An example of the standard for the connection terminal 5629 is PCIe.

The connection terminals 5623, 5624, and 5625 can serve as, for example, interfaces for performing power supply, signal input, or the like to the PC card 5621. In another example, they can serve as interfaces for outputting signals calculated by the PC card 5621. Examples of the standards for the connection terminals 5623, 5624, and 5625 include Universal Serial Bus (USB), Serial ATA (SATA), and Small Computer System Interface (SCSI). In the case where video signals are output from the connection terminals 5623, 5624, and 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings on the board 5622, the semiconductor device 5627 and the board 5622 can be electrically connected to each other. Examples of the semiconductor device 5627 include an FPGA, a GPU, and a CPU.

The semiconductor device 5628 includes a plurality of terminals, and when the terminals are reflow-soldered, for example, to wirings on the board 5622, the semiconductor device 5628 and the board 5622 can be electrically connected to each other. An example of the semiconductor device 5628 is a memory device or the like.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used for space equipment, such as devices processing and storing information.

The semiconductor device of one embodiment of the present invention can include an OS transistor. A change in electrical characteristics of the OS transistor due to exposure to radiation is small. That is, the OS transistor is highly resistant to radiation, and thus can be suitably used even in an environment where radiation can enter. For example, the OS transistor can be suitably used in outer space.

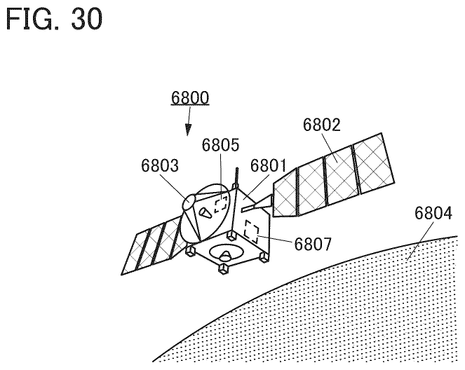

FIG. 30 illustrates an artificial satellite 6800 as an example of space equipment. The artificial satellite 6800 includes a body 6801, a solar panel 6802, an antenna 6803, a secondary battery 6805, and a control device 6807. In FIG. 30, a planet 6804 in outer space is illustrated. Note that outer space refers to, for example, space at an altitude above 100 km, and the outer space in this specification may also include thermosphere, mesosphere, and stratosphere.

Although not illustrated in FIG. 30, a battery management system (also referred to as BMS) or a battery control circuit may be provided in the secondary battery 6805. The battery management system or the battery control circuit preferably includes an OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is illuminated by sunlight, electric power required for operation of the artificial satellite 6800 is generated. However, for example, in the situation where the solar panel is not illuminated by sunlight or the situation where the solar panel is illuminated with a slight amount of sunlight, the amount of generated electric power is small. Accordingly, a sufficient amount of electric power required for operation of the artificial satellite 6800 may be difficult to generate. In order to operate the artificial satellite 6800 even with a small amount of generated electric power, the artificial satellite 6800 is preferably provided with the secondary battery 6805. Note that such a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device of one embodiment of the present invention is suitably used for the control device 6807. A change in electrical characteristics of the OS transistor due to exposure to radiation is smaller than a change in electrical characteristics of a Si transistor. Accordingly, the OS transistor has high reliability and thus can be suitably used even in an environment that is subject to radiation exposure.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of the space equipment in this embodiment, one embodiment of the present invention is not limited to this example. The semiconductor device of one embodiment of the present invention can be suitably used for space equipment such as a spacecraft, a space capsule, or a space probe, for example.

As described above, an OS transistor has excellent effects of a wide memory bandwidth and high resistant to radiation as compared with a Si transistor.

### [Data Center]

The semiconductor device of one embodiment of the present invention can be suitably used for, for example, a storage system in a data center or the like. Data center is required to perform long-term management of data such as guarantee of data immutability. In the case where data is managed for a long term, it is necessary to increase the scale of data center facility for installation of storages and servers for storing an enormous amount of data, stable electric power for data retention, cooling equipment for data retention, or the like.

With use of the semiconductor device of one embodiment of the present invention for a storage system in a data center, electric power used for retaining data can be reduced and a semiconductor device for retaining data can be reduced in size. Accordingly, reductions in sizes of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be improved.

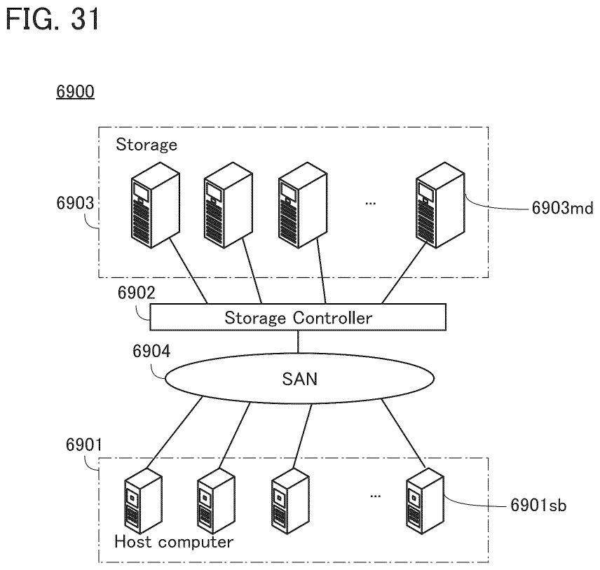

FIG. 31 illustrates a storage system that can be used in a data center. A storage system 6900 illustrated in FIG. 31 includes a plurality of servers 6901sb as a host 6901 (Host computer in the diagram). The storage system 6900 includes a plurality of memory devices 6903md as a storage 6903 (Storage in the diagram). In the illustrated example, the host 6901 and the storage 6903 are connected to each other through a storage area network 6904 (SAN in the diagram) and a storage control circuit 6902 (Storage Controller in the diagram).

The host 6901 corresponds to a computer which accesses data stored in the storage 6903. The host 6901 may be connected to another host 6901 through a network.

The data access speed, i.e., the time taken for storing and outputting data, of the storage 6903 is shortened by using a flash memory, but is still considerably longer than the data access speed of a DRAM that can be used as a cache memory in the storage. In the storage system, in order to solve the problem of low access speed of the storage 6903, a cache memory is normally provided in the storage to shorten the time taken for data storage and output.

The above-described cache memory is used in the storage control circuit 6902 and the storage 6903. The data transmitted between the host 6901 and the storage 6903 is stored in the cache memories in the storage control circuit 6902 and the storage 6903 and then output to the host 6901 or the storage 6903.

The use of an OS transistor as a transistor for storing data in the cache memory to retain a potential corresponding to data can reduce the frequency of refreshing, so that power consumption can be reduced. Furthermore, downscaling is possible by stacking memory cell arrays.

The use of the semiconductor device of one embodiment of the present invention for one or more selected from an electronic component, an electronic device, a large computer, space equipment, and a data center will produce an effect of reducing power consumption. Although there is a growing demand for more energy accompanying with higher performance and higher integration degree of semiconductor devices, the use of the semiconductor device of one embodiment of the present invention can thus reduce the emission amount of greenhouse gas typified by carbon dioxide (CO₂). Furthermore, the semiconductor device of one embodiment of the present invention has low power consumption and thus is effective as a global warming countermeasure.

The configurations, structures, methods, and the like described in this embodiment can be used in an appropriate combination with any of the configurations, structures, methods, and the like described in the other embodiments and the like.

This application is based on Japanese Patent Application Serial No. 2023-111667 filed with Japan Patent Office on Jul. 6, 2023, the entire contents of which are hereby incorporated by reference.

What is claimed is:

1. A semiconductor device comprising:
an oxide semiconductor layer over a substrate,
wherein the oxide semiconductor layer comprises indium,
wherein the oxide semiconductor layer is formed in parallel or substantially in parallel with a surface of the substrate,
wherein the oxide semiconductor layer comprises:
a first region; and
a second region over the first region,
wherein, in a direction substantially perpendicular to a formation surface of the oxide semiconductor layer, the first region is provided within a range of greater than or equal to 0 nm to less than or equal to 3 nm from the formation surface of the oxide semiconductor layer, and
wherein, in a cross-sectional observation of the oxide semiconductor layer using a transmission electron microscope, bright spots arranged in a layered manner in a direction parallel to the formation surface of the oxide semiconductor layer are observed in each of the first region and the second region.

2. The semiconductor device according to claim 1,
wherein the second region comprises zinc,
wherein the second region comprises a crystal, and
wherein a c-axis of the crystal is substantially parallel to a normal direction of the formation surface of the oxide semiconductor layer.

3. The semiconductor device according to claim 1,
wherein a c-axis alignment proportion in the second region is higher than a c-axis alignment proportion in the first region.

4. The semiconductor device according to claim 1,
wherein the oxide semiconductor layer further comprises a third region over the second region,
wherein a c-axis alignment proportion in the third region is higher than a c-axis alignment proportion in the first region, and
wherein, in the cross-sectional observation of the oxide semiconductor layer using the transmission electron microscope, bright spots arranged in a layered manner in the direction parallel to the formation surface of the oxide semiconductor layer are observed in the third region.

5. The semiconductor device according to claim 1,
wherein the oxide semiconductor layer further comprises a third region over the second region,
wherein a content of indium in the first region is higher than a content of indium in the second region,
wherein a content of indium in the third region is higher than the content of indium in the second region, and
wherein, in the cross-sectional observation of the oxide semiconductor layer using the transmission electron microscope, bright spots arranged in a layered manner in the direction parallel to the formation surface of the oxide semiconductor layer are observed in the third region.

6. The semiconductor device according to claim 1,
wherein the oxide semiconductor layer is formed over an insulator, and
wherein the insulator is amorphous.

7. A semiconductor device comprising:
a first insulator over a substrate;
an oxide semiconductor layer over the first insulator;
a second insulator over the oxide semiconductor layer; and
a conductor over the second insulator,
wherein the first insulator and the oxide semiconductor layer are formed in parallel with or substantially in parallel with a surface of the substrate,
wherein the oxide semiconductor layer comprises indium,
wherein the oxide semiconductor layer comprises:
a first region; and
a second region over the first region,
wherein, in a direction substantially perpendicular to a formation surface of the oxide semiconductor layer, the first region is provided within a range of greater than or equal to 0 nm to less than or equal to 3 nm from the formation surface of the oxide semiconductor layer, and
wherein, in a cross-sectional observation of the oxide semiconductor layer using a transmission electron microscope, bright spots arranged in a layered manner in a direction parallel to the formation surface of the oxide semiconductor layer are observed in each of the first region and the second region.

8. The semiconductor device according to claim 7,
wherein the second region comprises zinc,
wherein the second region comprises a crystal, and
wherein a c-axis of the crystal is substantially parallel to a normal direction of the formation surface of the oxide semiconductor layer.

9. The semiconductor device according to claim 7,
wherein a c-axis alignment proportion in the second region is higher than a c-axis alignment proportion in the first region.

10. The semiconductor device according to claim 7,
wherein the oxide semiconductor layer further comprises a third region over the second region,
wherein a c-axis alignment proportion in the third region is higher than a c-axis alignment proportion in the first region, and
wherein, in the cross-sectional observation of the oxide semiconductor layer using the transmission electron microscope, bright spots arranged in a layered manner in the direction parallel to the formation surface of the oxide semiconductor layer are observed in the third region.

11. The semiconductor device according to claim 7,
wherein the oxide semiconductor layer further comprises a third region over the second region,
wherein a content of indium in the first region is higher than a content of indium in the second region,
wherein a content of indium in the third region is higher than the content of indium in the second region, and
wherein, in the cross-sectional observation of the oxide semiconductor layer using the transmission electron microscope, bright spots arranged in a layered manner in the direction parallel to the formation surface of the oxide semiconductor layer are observed in the third region.

12. The semiconductor device according to claim 7,
wherein the first insulator is amorphous.

13. The semiconductor device according to claim 12, further comprising a third insulator covering the first insulator and the oxide semiconductor layer,
wherein an opening reaching the oxide semiconductor layer is formed in the third insulator, and
wherein the second insulator and the conductor are provided in the opening.

14. The semiconductor device according to claim 7, further comprising a third insulator covering the first insulator and the oxide semiconductor layer,
wherein an opening reaching the oxide semiconductor layer is formed in the third insulator,
wherein the first insulator is amorphous,
wherein the second insulator and the conductor are provided in the opening,
wherein the oxide semiconductor layer further comprises a third region over the second region,
wherein the second insulator is in contact with the third region, and
wherein, in the cross-sectional observation of the oxide semiconductor layer using the transmission electron microscope, bright spots arranged in a layered manner in the direction parallel to the formation surface of the oxide semiconductor layer are observed in the third region.

15. A method for manufacturing a semiconductor device comprising the steps of:
forming a first insulator over a substrate;
forming an oxide semiconductor layer over the first insulator;
performing a heat treatment on the oxide semiconductor layer;
processing the first insulator and the oxide semiconductor layer into island shapes;
forming a second insulator to cover the first insulator and the oxide semiconductor layer;
forming an opening reaching the oxide semiconductor layer in the second insulator;
forming a third insulator in the opening of the second insulator; and
forming a conductor over the third insulator in the opening of the second insulator,
wherein the formation of the oxide semiconductor layer comprises the steps of:
forming a first metal oxide;
forming a second metal oxide over the first metal oxide; and
forming a third metal oxide over the second metal oxide,
wherein each of the first metal oxide and the third metal oxide is formed by an atomic layer deposition method using a precursor comprising indium and an oxidizer, and
wherein the second metal oxide is formed by a sputtering method using a sputtering target comprising indium.

16. The method for manufacturing a semiconductor device according to claim 15,
wherein the sputtering target comprises zinc, and
wherein the sputtering method is performed in an atmosphere containing oxygen.

17. The method for manufacturing a semiconductor device according to claim 15,
wherein, in the atomic layer deposition method, the substrate is heated at a temperature of higher than or equal to 100° C. and lower than or equal to 350° C.

18. The method for manufacturing a semiconductor device according to claim 15,
wherein, in a cross-sectional observation of the oxide semiconductor layer using a transmission electron microscope, bright spots arranged in a layered manner in a direction parallel to a formation surface of the oxide semiconductor layer are observed in each of the first metal oxide, the second metal oxide, and the third metal oxide.

19. The method for manufacturing a semiconductor device according to claim 15,
wherein a clear boundary is not observed between the first metal oxide and the second metal oxide, and
wherein a clear boundary is not observed between the second metal oxide and the third metal oxide.

20. The method for manufacturing a semiconductor device according to claim 15,
wherein a temperature of the heat treatment is higher than or equal to 350° C. and lower than or equal to 550° C.
